(19) United States
(12) Patent Application Publication
(10) Pub. No.: US 2025/0102572 A1
(43) Pub. Date: Mar. 27, 2025

(54) CIRCUIT CONVERSION METHOD, LATCH CIRCUIT, AND C-ELEMENT CIRCUIT

(71) Applicant: Sony Semiconductor Solutions Corporation, Kanagawa (JP)

(72) Inventors: Yuji Kaba, Kanagawa (JP); Tadaaki Tanimoto, Kanagawa (JP)

(21) Appl. No.: 18/728,225

(22) PCT Filed: Dec. 27, 2022
(86) PCT No.: PCT/JP22/48260

§ 371 Date: Jul. 11, 2024

(30) Foreign Application Priority Data
Feb. 17, 2022 (JP) 2022-023217

(51) Int. Cl. G01R 31/3177; H03K 3/037

(52) U.S. Cl. CPC G01R 31/3177; H03K 3/037

(57) ABSTRACT

A circuit conversion method according to an embodiment of the present disclosure includes: setting a processing target path in an asynchronous logic circuit; first processing for determining whether or not a glitch occurs in each of a plurality of logic cells in the processing target path; second processing for performing conversion processing, the conversion processing being for converting one or more logic cells in which a glitch is determined to occur in the first processing into one or more glitch suppression logic cells, the one or more glitch suppression logic cells that are configured to suppress glitches, and perform same logical operation as the one or more logic cells; and, third processing for determining whether or not a glitch occurs in a subsequent-stage circuit in the processing target path after the second processing.

### TECHNICAL FIELD

The present disclosure relates to a circuit conversion method to be performed on an asynchronous logic circuit, and a latch circuit and a C-element circuit that are used in such a circuit conversion method.

### BACKGROUND ART

Logic circuits include a synchronous logic circuit and an asynchronous logic circuit. For example, PTL 1 discloses a circuit conversion method to be performed on an asynchronous logic circuit.

### CITATION LIST

### Patent Literature

PTL 1: Japanese Unexamined Patent Application Publication No. H11-007427

### SUMMARY OF THE INVENTION

In asynchronous logic circuits, it is desired to be able to suppress glitches, and it is expected to further suppress glitches.

It is desirable to provide a circuit conversion method, a latch circuit, and a C-element circuit that make it possible to suppress glitches.

A circuit conversion method according to an embodiment of the present disclosure includes: setting a processing target path in an asynchronous logic circuit; first processing for determining whether or not a glitch occurs in each of a plurality of logic cells in the processing target path; second processing for performing conversion processing, the conversion processing being for converting one or more logic cells in which a glitch is determined to occur in the first processing into one or more glitch suppression logic cells, the one or more glitch suppression logic cells that are configured to suppress glitches, and perform same logical operation as the one or more logic cells, and, third processing for determining whether or not a glitch occurs in a subsequent-stage circuit in the processing target path after the second processing.

A latch circuit according to an embodiment of the present disclosure includes a first inverter, first to eighth transistors, a NOR circuit, ninth to twelfth transistors, a second inverter, and a third inverter. The first inverter has an input terminal coupled to an input node, and an output terminal. The first transistor is a P-type transistor having a gate coupled to the output terminal of the first inverter, a source coupled to a power supply node, and a drain led to an first node. The second transistor is a P-type transistor having a gate to which a clock signal is to be inputted, a source coupled to the power supply node, and a drain led to the first node. The third transistor is an N-type transistor having a gate to which the clock signal is to be inputted, a drain led to the first node, and a source. The fourth transistor is an N-type transistor having a gate coupled to the output terminal of the first inverter, a drain coupled to the source of the third transistor, and a source coupled to a ground node. The fifth transistor is a P-type transistor having a gate coupled to the first node, a source coupled to the power supply node, and a drain led to a second node. The sixth transistor is an N-type transistor having a gate to which the clock signal is to be inputted, a drain led to the second node, and a source. The seventh transistor is an N-type transistor having a gate coupled to the input node, a drain coupled to the source of the sixth transistor, and a source. The eighth transistor is an N-type transistor having a gate coupled to the first node, a drain coupled to the source of the seventh transistor, and a source coupled to the ground node. The NOR circuit has a first input terminal to which a reset signal is to be inputted, a second input terminal coupled to the second node, and an output terminal coupled to a third node. The ninth transistor is a P-type transistor provided in a path coupling the power supply node and the second node, and having a gate coupled to the third node, a source, and a drain. The tenth transistor is a P-type transistor provided in a path coupling the power supply node and the second node, and having a gate to which the clock signal is to be inputted, a source, and a drain. The eleventh transistor is an N-type transistor provided in a path coupling the second node and the ground node, and having a gate coupled to the first node, a drain, and a source. The twelfth transistor is an N-type transistor provided in a path coupling the second node and the ground node, and having a gate coupled to the third node, a drain, and a source. The second inverter has an input terminal coupled to the third node, and an output terminal. The third inverter has an input terminal led to the output terminal of the second inverter, and an output terminal coupled to an output node.

A C-element circuit according to an embodiment of the present disclosure includes nineteenth to twenty-sixth transistors, a NOR circuit, a fourth inverter, a fifth inverter, and one or more transistors. The nineteenth transistor is a P-type transistor having a gate coupled to a first input node, a source coupled to a power supply node, and a drain. The twentieth transistor is a P-type transistor having a gate coupled to a second input node, a source coupled to the drain of the nineteenth transistor, and a drain led to a fourth node. The twenty-first transistor is an N-type transistor having a gate coupled to the second input node, a drain coupled to the fourth node, and a source. The twenty-second transistor is an N-type transistor having a gate coupled to the first input node, a drain coupled to the source of the twenty-first transistor, and a source coupled to a ground node. The twenty-third transistor is a P-type transistor having a gate coupled to the second input node, a source coupled to the power supply node, and a drain. The twenty-fourth transistor is a P-type transistor having a gate, a source coupled to the drain of the twenty-third transistor, a drain led to the fourth node. The twenty-fifth transistor is an N-type transistor having a gate, a drain led to the fourth node, and a source. The twenty-sixth transistor is an N-type transistor having a gate coupled to the second input node, a drain coupled to the source of the twenty-fifth transistor, and a source coupled to the ground node. The NOR circuit has a first input terminal to which a reset signal is to be inputted, a second input terminal coupled to the fourth node, and an output terminal coupled to a fifth node. The fourth inverter has an input terminal coupled to the fifth node, and an output terminal. The fifth inverter has an input terminal led to the output terminal of the fourth inverter, and an output terminal coupled to an output node. The one or more transistors is provided in one or more of a sixth path, a seventh path, an eighth path, a ninth path, and a tenth path. The sixth path couples the drain of the twentieth transistor and the fourth node. The seventh path couples the fourth node and the drain of the twenty-first transistor. The eighth path couples the drain of the twenty-fourth transistor and the fourth node. The ninth path couples the fourth node and the drain of the twenty-fifth transistor. The tenth path couples the output terminal of the fourth inverter and the input terminal of the fifth inverter.

In the circuit conversion method according to the embodiment of the present disclosure, the processing target path is set in the asynchronous logic circuit. The first processing is performed for determining whether or not a glitch occurs in each of the plurality of logic cells in the processing target path. The second processing for performing the conversion processing is performed. The conversion processing is for converting one or more logic cells in which a glitch is determined to occur in this first processing into one or more glitch suppression logic cells that are configured to suppress glitches and perform the same logical operation as the one or more logic cells. Thereafter, after this second processing, the third processing is performed for determining whether or not a glitch occurs in the subsequent-stage circuit in the processing target path.

### BRIEF DESCRIPTION OF DRAWINGS

FIG. 1 is a block diagram illustrating a configuration example of an asynchronous logic circuit according to a first embodiment of the present disclosure.

FIG. 2 is a circuit diagram illustrating a configuration example of a control circuit illustrated in FIG. 1.

FIG. 3 is a timing waveform diagram illustrating an operation example of the control circuit illustrated in FIG. 2.

FIG. 4 is a circuit diagram illustrating a specific example of a C-element illustrated in FIG. 2.

FIG. 5 is a circuit diagram illustrating another specific example of the C-element illustrated in FIG. 2.

FIG. 6 is an explanatory diagram illustrating an example of circuit coupling.

FIG. 7 is an explanatory diagram illustrating another example of circuit coupling.

FIG. 8 is a block diagram illustrating a specific example of the coupling illustrated in FIG. 6.

FIG. 9 is a block diagram illustrating a specific example of the coupling illustrated in FIG. 7.

FIG. 10 is a circuit diagram illustrating a specific example of an asynchronous logic circuit according to the first embodiment.

FIG. 11 is another circuit diagram illustrating a specific example of the asynchronous logic circuit according to the first embodiment.

FIG. 12A is a flowchart illustrating an example of a circuit change method according to the first embodiment.

FIG. 12B is another flowchart illustrating the example of the circuit change method according to the first embodiment.

FIG. 12C is another flowchart illustrating the example of the circuit change method according to the first embodiment.

FIG. 13 is a flowchart illustrating an example of conversion processing according to the first embodiment.

FIG. 14 is a circuit diagram illustrating a configuration example of a glitch suppression cell.

FIG. 15 is a circuit diagram illustrating a configuration example of another glitch suppression cell.

FIG. 16 is a circuit diagram illustrating a configuration example of another glitch suppression cell.

FIG. 17 is a circuit diagram illustrating a configuration example of another glitch suppression cell.

FIG. 18 is a circuit diagram illustrating a configuration example of another glitch suppression cell.

FIG. 19 is a circuit diagram illustrating a configuration example of another glitch suppression cell.

FIG. 20 is a circuit diagram illustrating a configuration example of another glitch suppression cell.

FIG. 21 is a circuit diagram illustrating a configuration example of another glitch suppression cell.

FIG. 22 is a circuit diagram illustrating a configuration example of another glitch suppression cell.

FIG. 23 is a circuit diagram illustrating a configuration example of another glitch suppression cell.

FIG. 24 is a circuit diagram illustrating a configuration example of another glitch suppression cell.

FIG. 25 is a circuit diagram illustrating a configuration example of another glitch suppression cell.

FIG. 26 is a circuit diagram illustrating a configuration example of another glitch suppression cell.

FIG. 27 is a circuit diagram illustrating a configuration example of another glitch suppression cell.

FIG. 28 is a circuit diagram illustrating a configuration example of another glitch suppression cell.

FIG. 29 is a circuit diagram illustrating a configuration example of another glitch suppression cell.

FIG. 30A is a flowchart illustrating an example of a circuit change method according to a modification example of the first embodiment.

FIG. 30B is another flowchart illustrating the example of the circuit change method according to the modification example of the first embodiment.

FIG. 31A is a flowchart illustrating an example of conversion processing according to the modification example of the first embodiment.

FIG. 31B is another flowchart illustrating the example of the conversion processing according to the modification example of the first embodiment.

FIG. 32 is a block diagram illustrating a configuration example of an asynchronous logic circuit according to a second embodiment.

FIG. 33 is a circuit diagram illustrating a configuration example of an SDI logic cell.

FIG. 34 is a circuit diagram illustrating a configuration example of another SDI logic cell.

FIG. 35 is a circuit diagram illustrating a configuration example of another SDI logic cell.

FIG. 36 is a circuit diagram illustrating a configuration example of another SDI logic cell.

FIG. 37 is a circuit diagram illustrating a configuration example of another SDI logic cell.

FIG. 38 is a circuit diagram illustrating a configuration example of another SDI logic cell.

FIG. 39 is a circuit diagram illustrating a configuration example of another SDI logic cell.

FIG. 40 is a circuit diagram illustrating a configuration example of another SDI logic cell.

FIG. 41 is a circuit diagram illustrating an example of a 1-wire logic circuit.

FIG. 42 is a circuit diagram illustrating an example of an SDI logic circuit.

FIG. 43 is a circuit diagram illustrating a configuration example of an SDI register and a completion detection circuit illustrated in FIG. 32.

FIG. 44 is a circuit diagram illustrating a specific example of the asynchronous logic circuit according to the second embodiment.

FIG. 45 is another circuit diagram illustrating a specific example of the asynchronous logic circuit according to the second embodiment.

FIG. 46A is a flowchart illustrating an example of a circuit change method according to the second embodiment.

FIG. 46B is another flowchart illustrating the example of the circuit change method according to the second embodiment.

FIG. 46C is another flowchart illustrating the example of the circuit change method according to the second embodiment.

FIG. 47 is a flowchart illustrating an example of conversion processing according to the second embodiment.

FIG. 48A is a flowchart illustrating an example of a circuit change method according to a modification example of the second embodiment.

FIG. 48B is another flowchart illustrating the example of the circuit change method according to the modification example of the second embodiment.

FIG. 49A is a flowchart illustrating an example of conversion processing according to a modification example of the second embodiment.

FIG. 49B is another flowchart illustrating the example of the conversion processing according to the modification example of the second embodiment.

FIG. 50 is a circuit diagram illustrating a specific example of an asynchronous logic circuit according to a modification example of the second embodiment.

### MODES FOR CARRYING OUT THE INVENTION

Some embodiments of the present disclosure are described below in detail with reference to the drawings. It is to be noted that description is given in the following order.
1. First Embodiment (An application example to a bundled-data logic circuit)
2. Second Embodiment (An application example to a 2-wire SDI circuit)

### 1. First Embodiment

### Configuration Example

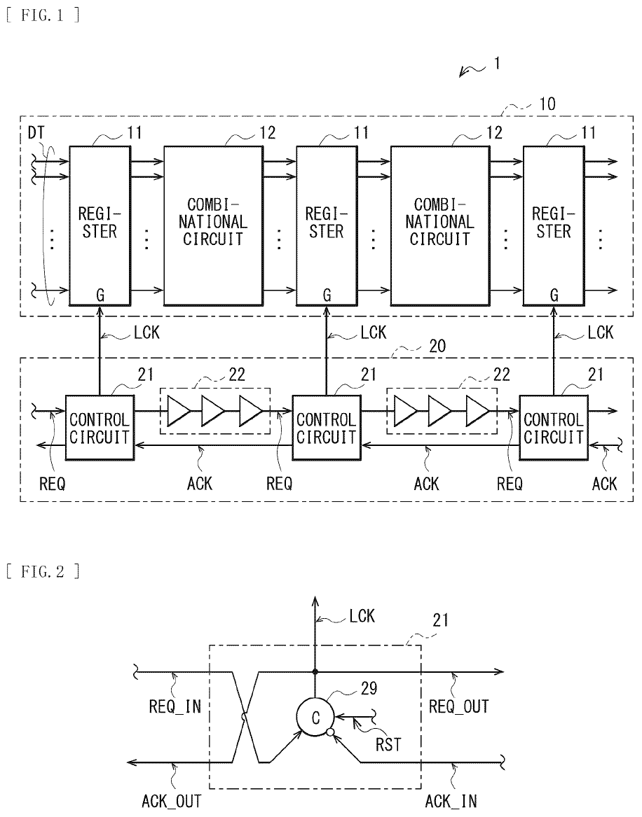

FIG. 1 illustrates a configuration example of an asynchronous logic circuit 1 to which a circuit conversion method according to a first embodiment is applied. The asynchronous logic circuit 1 is what is called a bundled-data asynchronous logic circuit. The asynchronous logic circuit 1 illustrated in FIG. 1 is an example of a most basic configuration. In actuality, as described later, the asynchronous logic circuit 1 may be more complicated than this circuit configuration. The asynchronous logic circuit 1 includes a data-path circuit 10 and a handshake circuit 20.

The data-path circuit 10 is configured to perform processing on a piece of data DT. The piece of data DT is supplied from the left to the right in FIG. 1. The data-path circuit 10 includes a plurality of registers 11 and a plurality of combinational circuits 12. In this example, the registers 11 and the combinational circuits 12 are alternately disposed. The register 11 includes, for example, a plurality of latch circuits, and is configured to latch the piece of data DT supplied from the combinational circuit 12 in a preceding stage, on the basis of a signal LCK that is a local clock. The combinational circuit 12 is configured to perform a logical operation on the piece of data DT supplied from the register 11 in a preceding stage and supply a thus-obtained piece of data DT to the register 11 in a subsequent stage.

The handshake circuit 20 is configured to generate a plurality of signals LCK on the basis of a signal REQ and a signal ACK and supply the plurality of signals LCK generated to the plurality of respective registers 11 in the data-path circuit 10. The signal REQ is supplied from the left to the right in FIG. 1. The handshake circuit 20 includes a plurality of control circuits 21 and a plurality of delay circuits 22.

The control circuit 21 is configured to generate the signal LCK that is a local clock, and the signals REQ and ACK on the basis of the supplied signal REQ and the supplied signal ACK. Specifically, the control circuit 21 is supplied with the signal REQ from the control circuit 21 in a preceding stage through the delay circuit 22, and is supplied with the signal ACK from the control circuit 21 in a subsequent stage, and generates the signals LCK, REQ, and ACK on the basis of these signals REQ and ACK. Thereafter, the control circuit 21 supplies the generated signal LCK to the register 11, supplies the generated signal REQ to the control circuit 21 in the subsequent stage through the delay circuit 22, and supplies the generated signal ACK to the control circuit 21 in the preceding stage. The signal REQ is supplied from the left to the right in FIG. 1; therefore, the plurality of control circuits 21 issues the signal ACK in order from the control circuit 21 on the left.

FIG. 2 illustrates a configuration example of the control circuit 21. In FIG. 2, the signal REQ to be inputted to the control circuit 21 is represented by a signal REQ_IN, and the signal REQ to be outputted from the control circuit 21 is represented by a signal REQ_OUT. In addition, the signal ACK to be inputted to the control circuit 21 is represented by a signal ACK_IN, and the signal ACK to be outputted from the control circuit 21 is represented by a signal ACK_OUT.

The control circuit 21 includes a C-element 29. The C-element 29 is what is called a waiting circuit, and has two input terminals, a reset terminal, and an output terminal. The signal REQ_IN and an inverted signal of the signal ACK_IN are inputted to the two input terminals. A reset signal RST is inputted to the reset terminal. The C-element 29 changes the signal LCK at the output terminal to a high level in a case where both the signal REQ_IN and the inverted signal of the signal ACK_IN are at the high level, changes the signal LCK at the output terminal to a low level in a case where both the signal REQ_IN and the inverted signal of the signal ACK_IN are at the low level, and maintains the signal LCK at the output terminal in other cases. In addition, the C-element 29 changes the signal LCK at the output terminal to the low level on the basis of the reset signal RST. It is to be noted that, the reset terminal is provided in this example, but the reset terminal may not be provided. In this case, signals having the same levels as each other are inputted to the two input terminals of the C-element 29, thereby making it possible to determine the signal at the output terminal to the low level or the high level.

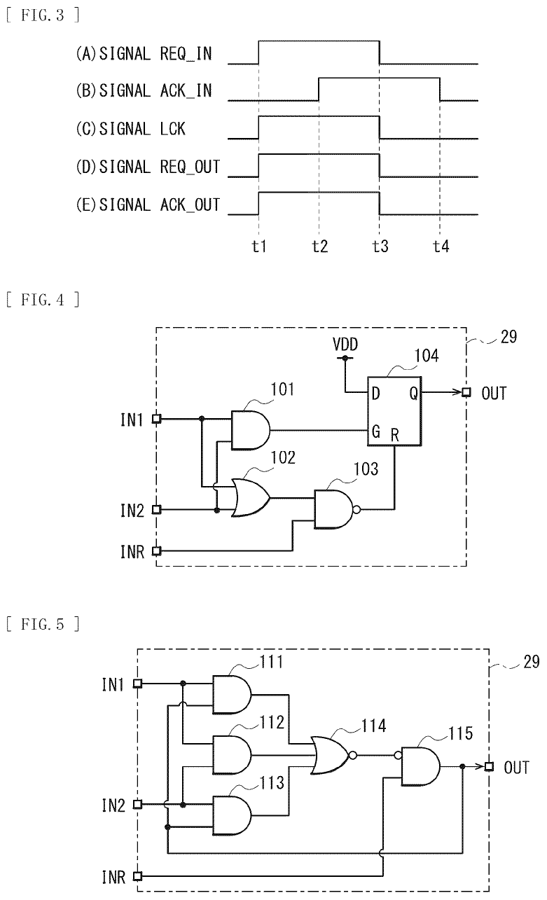

FIG. 3 illustrates an operation example of the control circuit 21, where (A) indicates a waveform of the signal REQ_IN, (B) indicates a waveform of the signal ACK_IN, (C) indicates a waveform of the signal LCK, (D) indicates a waveform of the signal REQ_OUT, and (E) indicates a waveform of the signal ACK_OUT.

At a timing t1, the signal REQ_IN changes from the low level to the high level ((A) of FIG. 3). At this time, the signal ACK_IN is at the low level ((B) of FIG. 3); therefore, the inverted signal of the signal ACK_IN is at the high level. Accordingly, both the signal REQ_IN and the inverted signal of the signal ACK_IN are changed to the high level, which causes the C-element 29 to change the signal LCK from the low level to the high level ((C) of FIG. 3) and similarly change the signals REQ_OUT and ACK_OUT from the low level to the high level ((D) and (E) of FIG. 3).

Next, at a timing t2, the signal ACK_IN changes from the low level to the high level ((B) of FIG. 3). In other words, the inverted signal of the signal ACK_IN changes from the high level to the low level. At this time, the signal REQ_IN is at the high level ((A) of FIG. 3). Accordingly, the signals LCK, REQ_OUT, and ACK_OUT are unchanged and maintained at the high level ((C) to (E) of FIG. 3).

Next, at a timing t3, the signal REQ_IN changes from the high level to the low level ((A) of FIG. 3). At this time, the signal ACK_IN is at the high level ((B) of FIG. 3); therefore, the inverted signal of the signal ACK_IN is at the low level. Accordingly, both the signal REQ_IN and the inverted signal of the signal ACK_IN are changed to the low level, which causes the C-element 29 to change the signal LCK from the high level to the low level ((C) of FIG. 3) and similarly change the signals REQ_OUT and ACK_OUT from the high level to the low level ((D) and (E) of FIG. 3).

Next, at a timing t4, the signal ACK_IN changes from the high level to the low level ((B) of FIG. 3). In other words, the inverted signal of the signal ACK_IN changes from the low level to the high level. At this time, the signal REQ_IN is at the low level ((A) of FIG. 3). Accordingly, the signals LCK, REQ_OUT, and ACK_OUT are unchanged and maintained at the low level ((C) to (E) of FIG. 3).

As described above, the control circuit 21 performs an operation on the basis of the signals REQ_IN and ACK_IN that are four-phase signals to thereby generate the signals LCK, REQ_OUT, and ACK_OUT.

Next, a specific circuit example of the C-element 29 is described with reference to some examples.

FIG. 4 illustrates a configuration example of the C-element 29. The C-element 29 includes two input terminals IN1 and IN2, a reset terminal INR, an output terminal OUT, a logical AND (AND) circuit 101, a logical OR (OR) circuit 102, a negative AND (NAND) circuit 103, and a latch circuit 104. The AND circuit 101 is configured to find AND of a signal at the input terminal IN1 and a signal at the input terminal IN2. The OR circuit 102 is configured to find OR of the signal at the input terminal IN1 and the signal at the input terminal IN2. The NAND circuit 103 is configured to find NAND of an output signal of the OR circuit 102 and a signal at the reset terminal INR. The latch circuit 104 is a D-latch, and has a terminal D coupled to a power supply node of a power supply voltage VDD, a terminal G to be supplied with an output signal of the AND circuit 101, and a terminal R to be supplied with an output signal of the NAND circuit 103. The latch circuit 104 has a terminal Q coupled to the output terminal OUT.

FIG. 5 illustrates another configuration example of the C-element 29. In this example, the C-element 29 is configured with use of what is called a majority gate. The C-element 29 includes two input terminals IN1 and IN2, the reset terminal INR, the output terminal OUT, AND circuits 111 to 113, a negative OR (NOR) circuit 114, and an AND circuit 115. The AND circuit 111 is configured to find AND of a signal at the input terminal IN1 and an output signal of the AND circuit 115. The AND circuit 112 is configured to find AND of the signal at the input terminal IN1 and a signal at the input terminal IN2. The AND circuit 113 is configured to find AND of the signal at the input terminal IN2 and the output signal of the AND circuit 115. The NOR circuit 114 is configured to find NOR of output signals of the AND circuits 111 to 113. The AND circuit 115 is configured to find AND of an inverted signal of an output signal of the NOR circuit 114 and a signal at the reset terminal NR. The AND circuit 115 has an output terminal coupled to the output terminal OUT.

As described above, it is possible to configure the C-element 29 with use of the latch circuit 104, for example, as illustrated in FIG. 4, or it is possible to configure the C-element 29 with use of the majority gate, for example, as illustrated in FIG. 5.

The delay circuit 22 (FIG. 1) is provided in a supply path of the signal REQ, and is configured to delay the signal REQ. A delay amount of the delay circuit 22 is set to a maximum value of a delay amount in a corresponding combinational circuit 12.

With this configuration, in the asynchronous logic circuit 1, the combinational circuit 12 supplies the piece of data DT to the register 11. The delay circuit 22 delays the signal REQ, and supplies the delayed signal REQ to the control circuit 21. This control circuit 21 generates the signal LCK on the basis of the delayed signal REQ, and the register 11 latches the piece of data DT supplied from the combinational circuit 12 on the basis of this signal LCK. Thereafter, the control circuit 21 supplies the signal ACK to the control circuit 21 in the preceding stage. In a case where the delay amount in the combinational circuit 12 is small, the delay amount in the delay circuit 22 is also set to a small value, and in a case where the delay amount in the combinational circuit 12 is large, the delay amount in the delay circuit 22 is set to a large value.

In the example in FIG. 1, the control circuit 21 is coupled one-to-one to the control circuit 21 in the preceding stage through the delay circuit 22, and is coupled one-to-one to the control circuit 21 in the subsequent stage through the delay circuit 22. Likewise, the register 11 is coupled one-to-one to the register 11 in the preceding stage with the combinational circuit 12 interposed therebetween, and is coupled one-to-one to the register 11 in the subsequent stage with the combinational circuit 12 interposed therebetween. However, this is not limitative, and the control circuit 21 may be coupled to one-to-multiple to a plurality of control circuits 21. In addition, the register 11 may be coupled to one-to-multiple to a plurality of registers 11. Hereinafter, description is given of one-to-two coupling as an example.

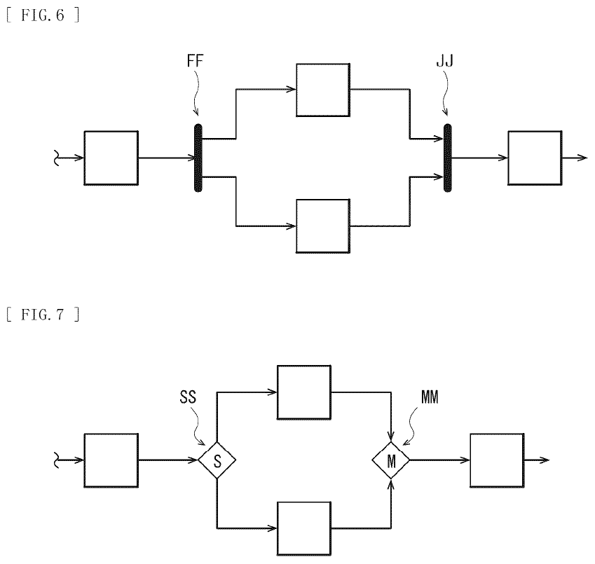

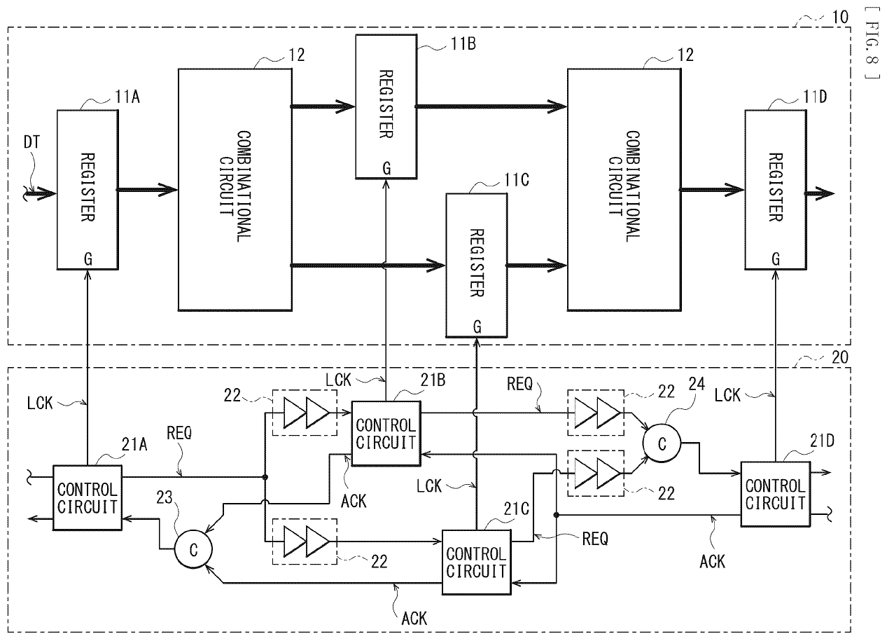

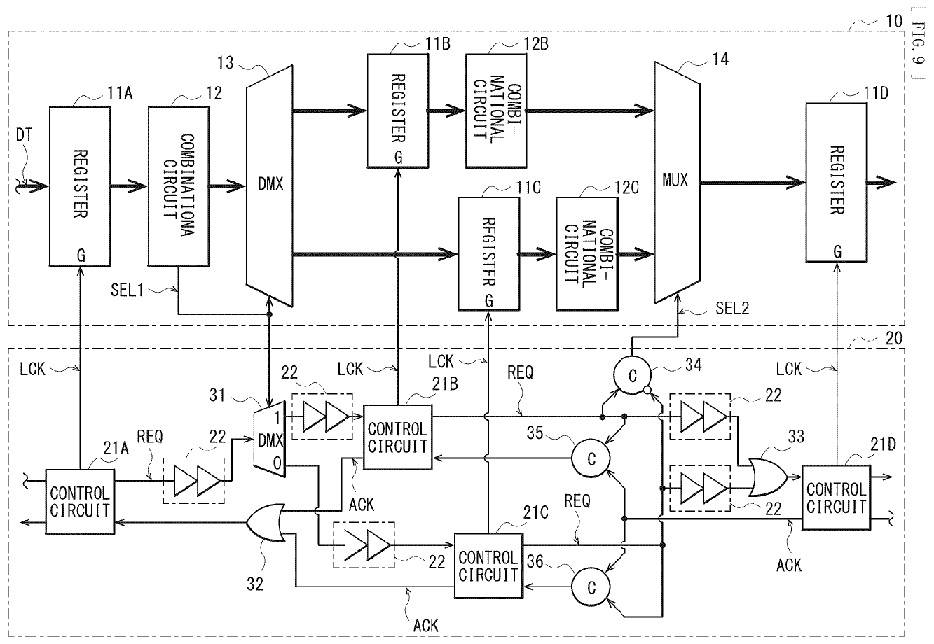

FIG. 6 schematically illustrates an example of one-to-two coupling. A symbol FF indicates fork coupling in which a signal from one circuit is split into two, and a symbol JJ indicates join coupling in which two signals from two circuits are joined into one. In the fork coupling, the signal from one circuit is supplied to both of two circuits, and in the join coupling, both of two signals from two circuits are supplied to one circuit.

FIG. 7 schematically illustrates another example of one-to-two coupling. A symbol SS indicates split coupling in which a signal from one circuit is split into two, and a symbol MM indicates merge coupling in which two signals from two circuits are joined into one. In the split coupling, a signal from one circuit is supplied to one of two circuits, and in the merge coupling, one of two signals from two circuits is supplied to one circuit.

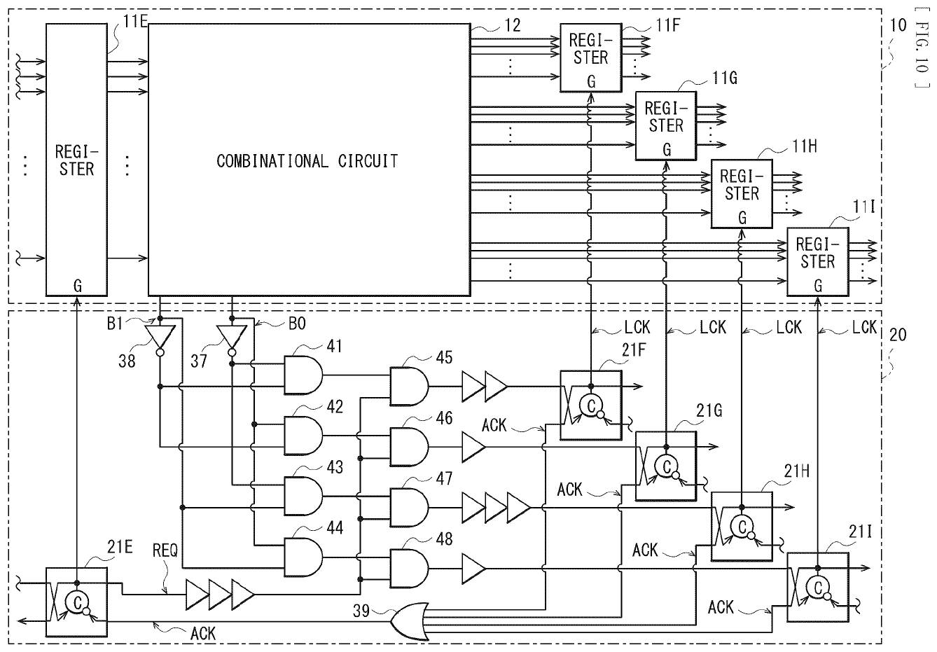

FIG. 8 schematically illustrates a specific example of the fork coupling and the join coupling illustrated in FIG. 6. In FIG. 8, a path of a piece of data DT is indicated by a thick line. A left half in FIG. 8 indicates the fork coupling, and a right half in FIG. 8 indicates the join coupling.

First, the fork coupling is described. In the fork coupling, the handshake circuit 20 includes a C-element 23.

In the data-path circuit 10, the register 11 (a register 11A) supplies a piece of data DT to the combinational circuit 12. The combinational circuit 12 performs a logical operation on the basis of this piece of data DT to thereby generate two pieces of data DT, and supplies these two pieces of data DT to respective two registers 11 (registers 11B and 11C).

In the handshake circuit 20, the control circuit 21 (a control circuit 21A) supplies the signal REQ to two control circuits (control circuits 21B and 21C) through respective two delay circuits 22. The control circuit 21B supplies the signal ACK to the C-element 23, and the control circuit 21C supplies the signal ACK to the C-element 23. The C-element 23 generates the signal ACK on the basis of two signals ACK supplied from the control circuits 21B and 21C, and supplies the generated signal ACK to the control circuit 21A.

With this configuration, the combinational circuit 12 performs a logical operation on the basis of the piece of data DT supplied from the register 11A to thereby generate two pieces of data DT, and supplies these two pieces of data DT to respective two registers 11B and 11C. The control circuit 21B generates the signal LCK on the basis of the signal REQ supplied from the control circuit 21A through the delay circuit 22, and supplies the generated signal LCK to the register 11B. The register 11B latches the piece of data DT supplied from the combinational circuit 12 on the basis of this signal LCK. Thereafter, the control circuit 21B supplies the signal ACK to the C-element 23. Likewise, the control circuit 21C generates the signal LCK on the basis of the signal REQ supplied from the control circuit 21A through the delay circuit 22, and supplies the generated signal LCK to the register 11C. The register 11C latches the piece of data DT supplied from the combinational circuit 12 on the basis of the signal LCK. The control circuit 21C supplies the signal ACK to the C-element 23. When both of two signals ACK supplied from the control circuits 21B and 21C are changed to the high level, the C-element 23 changes the signal ACK to be supplied to the control circuit 21A to the high level.

Next, the join coupling is described. In the join coupling, the handshake circuit 20 includes a C-element 24.

In the data-path circuit 10, the register 11B supplies a piece of data DT to the combinational circuit 12, and the register 11C supplies a piece of data DT to the combinational circuit 12. The combinational circuit 12 performs a logical operation on the basis of two pieces of data DT supplied from the registers 11B and 11C to thereby generate a piece of data DT, and supplies this piece of data DT to the register 11 (a register 11D).

In the handshake circuit 20, the control circuit 21B supplies the signal REQ to the C-element 24 through the delay circuit 22, and the control circuit 21C supplies the signal REQ to the C-element 24 through the delay circuit 22. The C-element 24 generates the signal REQ on the basis of two signals REQ supplied from the control circuits 21B and 21C, and supplies the generated signal REQ to the control circuit 21D. The control circuit 21D supplies the signal ACK to each of two control circuits 21B and 21C.

With this configuration, the combinational circuit 12 performs a logical operation on the basis of two pieces of data DT supplied from the registers 11B and 11C to thereby generate a piece of data DT, and supplies this piece of data DT to the register 11D. When both of two signals REQ supplied from the control circuits 21B and 21C are changed to the high level, the C-element 24 changes the signal REQ to be supplied to the control circuit 21D to the high level. The control circuit 21D generates the signal LCK on the basis of this signal REQ, and supplies the generated signal LCK to the register 11D. The register 11D latches the piece of data DT supplied from the combinational circuit 12 on the basis of this signal LCK. Thereafter, the control circuit 21D supplies the signal ACK to the control circuits 21B and 21C.

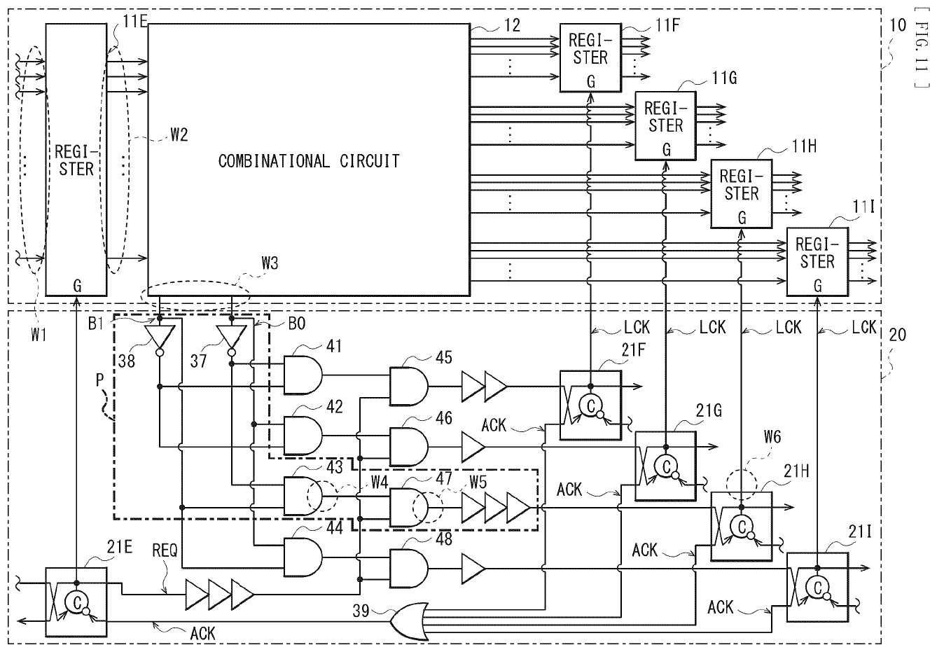

FIG. 9 illustrates a specific example of the split coupling and the merge coupling illustrated in FIG. 7. A left half in FIG. 9 illustrates the split coupling, and a right half in FIG. 9 illustrates the merge coupling.

First, the split coupling is described. In the split coupling, the data-path circuit 10 includes a demultiplexer (DMX) 13, and the handshake circuit 20 includes a demultiplexer (DMX) 31 and an OR circuit 32.

In the data-path circuit 10, the register 11 (the register 11A) supplies a piece of data DT to the combinational circuit 12. The combinational circuit 12 performs a logical operation on the basis of this piece of data DT to thereby generate a piece of data DT and generate a selection signal SELL. The demultiplexer 13 supplies the piece of data supplied from the combinational circuit 12 to the resister 11 corresponding to the selection signal SEL1 of two registers 11 (the registers 11B and 11C).

In the handshake circuit 20, the control circuit 21 (the control circuit 21A) supplies the signal REQ to the demultiplexer 31. The demultiplexer 31 supplies the signal REQ supplied from the control circuit 21A to the control circuit 21 corresponding to the selection signal SEL1 of two control circuits 21 (the control circuits 21B and 21C). The control circuit 21B supplies the signal ACK to the OR circuit 32, and the control circuit 21C supplies the signal ACK to the OR circuit 32. The OR circuit 32 finds OR of two signals ACK supplied from the control circuits 21B and 21C to thereby generate the signal ACK, and supplies the generated signal ACK to the control circuit 21A.

With this configuration, the combinational circuit 12 performs a logical operation to thereby generate the selection signal SEL1. For example, in a case where the selection signal SEL1 is at the high level, the demultiplexer 13 supplies the piece of data DT supplied from the combinational circuit 12 to the register 11B, and the demultiplexer 31 supplies the signal REQ supplied from the control circuit 21A to the control circuit 21B through the delay circuit 22. The control circuit 21B generates the signal LCK on the basis of this signal REQ, and supplies the generated signal LCK to the register 11B. Accordingly, the register 11B latches the piece of data DT supplied from the demultiplexer 13 on the basis of the signal LCK supplied from the control circuit 21B. Thereafter, the control circuit 21B supplies the signal ACK to the control circuit 21A through the OR circuit 32.

For example, in a case where the selection signal SEL1 is at the low level, the demultiplexer 13 supplies the piece of data DT supplied from the combinational circuit 12 to the register 11C, and the demultiplexer 31 supplies the signal REQ supplied from the control circuit 21A to the control circuit 21C through the delay circuit 22. The control circuit 21C generates the signal LCK on the basis of this signal REQ, and supplies the generated signal LCK to the register 11C. Accordingly, the register 11C latches the piece of data DT supplied from the demultiplexer 13 on the basis of the signal LCK supplied from the control circuit 21C. Thereafter, the control circuit 21C supplies the signal ACK to the control circuit 21A through the OR circuit 32.

Next, the merge coupling is described. In the merge coupling, the data-path circuit 10 includes a multiplexer (MUX) 14, and the handshake circuit 20 includes an OR circuit 33 and C-elements 34 to 36.

In the data-path circuit 10, the register 11B supplies the piece of data DT to the combinational circuit 12 (a combinational circuit 12B) subsequent to the register 11B, and the register 11C supplies the piece of data DT to the combinational circuit 12 (a combinational circuit 12C) subsequent to the register 11C. The combinational circuit 12B performs a logical operation on the basis of the piece of data DT supplied from the register 11B to thereby generate a piece of data DT, and supplies this piece of data DT to the multiplexer 14. The combinational circuit 12C performs a logical operation on the basis of the piece of data DT supplied from the register 11C to thereby generate a piece of data DT, and supplies this piece of data DT to the multiplexer 14. The multiplexer 14 selects one of two pieces of data DT supplied from the combinational circuits 12B and 12C on the basis of a selection signal SEL2 supplied from the handshake circuit 20, and supplies the selected piece of data DT to the register 11 (a register 11D).

In the handshake circuit 20, the control circuit 21B supplies the signal REQ to the OR circuit 33 through the delay circuit 22, and the control circuit 21C supplies the signal REQ to the OR circuit 33 through the delay circuit 22. The OR circuit 33 finds OR of two signals REQ supplied from the control circuits 21B and 21C to thereby generate the signal REQ, and supplies the generated signal REQ to the control circuit 21D. The C-element 34 generates the selection signal SEL2 on the basis of the signal REQ supplied from the control circuit 21B and an inverted signal of the signal REQ supplied from the control circuit 21C. In a case where the signal REQ supplied from the control circuit 21B is at the high level and the signal REQ supplied from the control circuit 21C is at the low level, the C-element 34 changes the selection signal SEL2 to the high level. In addition, in a case where the signal REQ supplied from the control circuit 21B is at the low level and the signal REQ supplied from the control circuit 21C is at the high level, the C-element 34 changes the selection signal SEL2 to the low level. The control circuit 21D supplies the signal ACK to two C-elements 35 and 36. The C-element 35 generates the signal ACK on the basis of the signal REQ supplied from the control circuit 21B and the signal ACK supplied from the control circuit 21D. The C-element 36 generates the signal ACK on the basis of the signal REQ supplied from the control circuit 21C and the signal ACK supplied from the control circuit 21D.

With this configuration, the C-element 34 generates the selection signal SEL2 on the basis of the signal REQ supplied from the control circuit 21B and the inverted signal of the signal REQ supplied from the control circuit 21C. For example, in a case where the signal REQ supplied from the control circuit 21B is at the high level and the signal REQ supplied from the control circuit 21C is at the low level, the C-element 34 changes the selection signal SEL2 to the high level. In this case, the multiplexer 14 supplies the piece of data DT supplied from the combinational circuit 12B to the register 11D. The control circuit 21D generates the signal LCK on the basis of the signal REQ supplied from the control circuit 21B, and supplies the generated signal LCK to the register 11D. Accordingly, the register 11D latches the piece of data DT supplied from the multiplexer 14 on the basis of the signal LCK supplied from the control circuit 21D. Thereafter, the control circuit 21D supplies the signal ACK to the C-element 35. The signal REQ supplied from the control circuit 21B is at the high level; therefore, the C-element 35 supplies the signal ACK supplied from the control circuit 21D to the control circuit 21B.

For example, in a case where the signal REQ supplied from the control circuit 21B is at the low level and the signal REQ supplied from the control circuit 21C is at the high level, the C-element 34 changes the selection signal SEL2 to the low level. In this case, the multiplexer 14 supplies the piece of data DT supplied from the combinational circuit 12C to the register 11D. The control circuit 21D generates the signal LCK on the basis of the signal REQ supplied from the control circuit 21C, and supplies the generated signal LCK to the register 11D. Accordingly, the register 11D latches the piece of the data DT supplied from the multiplexer 14 on the basis of the signal LCK supplied from the control circuit 21D. Thereafter, the control circuit 21D supplies the signal ACK to the C-element 35. The signal REQ supplied from the control circuit 21C is at the high level; therefore, the C-element 35 supplies the signal ACK supplied from the control circuit 21D to the control circuit 21C.

FIG. 10 illustrates an example of one-to-four split coupling. In this example, the handshake circuit 20 includes control circuits 21E to 21I, inverters 37 and 38, AND circuits 41 to 48, and an OR circuit 39.

In the data-path circuit 10, the register 11 (a register 11E) supplies a piece of data DT to the combinational circuit 12. The combinational circuit 12 performs a logical operation on the basis of this piece of data DT to thereby generate a piece of data DT, and supplies this piece of data DT to one of four registers 11 (registers 11F to 11I) in a subsequent stage. The combinational circuit 12 generates selection signals B1 and B0. The combinational circuit 12 sets the selection signals B1 and B0 to “00” in a case of supplying the piece of data DT to the register 11F, sets the selection signals B1 and B0 to “01” in a case of supplying the piece of data DT to the register 11G, sets the selection signals B1 and B0 to “10” in a case of supplying the piece of data DT to the register 11H, and sets the selection signals B1 and B0 to “11” in a case of supplying the piece of data DT to the register 11I.

In the handshake circuit 20, the inverter 37 inverts the selection signal B0, and the inverter 38 inverts the selection signal B1. The AND circuit 41 finds AND of an output signal of the inverter 37 and an output signal of the inverter 38. The AND circuit 42 finds AND of the selection signal B0 and the output signal of the inverter 38. The AND circuit 43 finds AND of the output signal of the inverter 37 and the selection signal B1. The AND circuit 44 finds AND of the selection signal B0 and the selection signal B1. The AND circuit 45 finds AND of an output signal of the AND circuit 41 and the signal REQ supplied from the control circuit 21E through the delay circuit, and supplies a thus-obtained signal to the control circuit 21F through the delay circuit. The AND circuit 46 finds AND of an output signal of the AND circuit 42 and the signal REQ supplied from the control circuit 21E through the delay circuit, and supplies a thus-obtained signal to the control circuit 21G through the delay circuit. The AND circuit 47 finds AND of an output signal of the AND circuit 43 and the signal REQ supplied from the control circuit 21E through the delay circuit, and supplies a thus-obtained signal to the control circuit 21H through the delay circuit. The AND circuit 48 finds AND of an output signal of the AND circuit 44 and the signal REQ supplied from the control circuit 21E through the delay circuit, and supplies a thus-obtained signal to the control circuit 21I through the delay circuit.

With this configuration, the combinational circuit 12 performs a logical operation to thereby generate the selection signals B1 and B0. For example, in a case where the selection signals B1 and B0 are “00”, the combinational circuit 12 supplies the piece of data DT to the register 11F. In a case where the selection signals B1 and B0 are “00” in such a manner, the output signal of the AND circuit 41 is changed to the high level, and the signal REQ generated by the control circuit 21E is supplied to the control circuit 21F through the AND circuit 45. The control circuit 21F generates the signal LCK on the basis of this signal REQ, and supplies the generated signal LCK to the register 11F. The register 11F latches the piece of data DT supplied from the combinational circuit 12 on the basis of this signal LCK. Thereafter, the control circuit 21F supplies the signal ACK to the control circuit 21E through the OR circuit 39.

Likewise, for example, in a case where the selection signals B1 and B0 are “01”, the combinational circuit 12 supplies the piece of data DT to the register 11G. In a case where the selection signals B1 and B0 are “01” in such a manner, the output signal of the AND circuit 42 is changed to the high level, and the signal REQ generated by the control circuit 21E is supplied to the control circuit 21G through the AND circuit 46. The control circuit 21G generates the signal LCK on the basis of this signal REQ, and supplies the generated signal LCK to the register 11G. The register 11G latches the piece of data DT supplied from the combinational circuit 12 on the basis of this signal LCK. Thereafter, the control circuit 21G supplies the signal ACK to the control circuit 21E through the OR circuit 39.

Likewise, for example, in a case where selection signals B1 and B0 are “10”, the combinational circuit 12 supplies the piece of data DT to the register 11H. In a case where selection signals B1 and B0 are “10” in such a manner, the output signal of the AND circuit 43 is changed to the high level, and the signal REQ generated by the control circuit 21E is supplied to the control circuit 21H through the AND circuit 47. The control circuit 21H generates the signal LCK on the basis of this signal REQ, and supplies the generated signal LCK to the register 11H. The register 11H latches the piece of data DT supplied from the combinational circuit 12 on the basis of this signal LCK. Thereafter, the control circuit 21H supplies the signal ACK to the control circuit 21E through the OR circuit 39.

Likewise, for example, in a case where selection signals B1 and B0 are “11”, the combinational circuit 12 supplies the piece of data DT to the register 11I. In a case where selection signals B1 and B0 are “11” in such a manner, the output signal of the AND circuit 44 is changed to the high level, and the signal REQ generated by the control circuit 21E is supplied to the control circuit 21I through the AND circuit 48. The control circuit 21I generates the signal LCK on the basis of this signal REQ, and supplies the generated signal LCK to the register 11I. The register 11I latches the piece of data DT supplied from the combinational circuit 12 on the basis of this signal LCK. Thereafter, the control circuit 21I supplies the signal ACK to the control circuit 21E through the OR circuit 39.

Incidentally, in recent years, a semiconductor process size has been further reduced, and a power supply voltage has been further lowered. In such a situation, glitches easily occur. In the asynchronous logic circuit 1, using a four-phase signal as illustrated in FIG. 3 makes it possible to hinder glitches from occurring. However, when the semiconductor process size is further reduced and the power supply voltage is further lowered as described above, the variation tendency of a delay amount in a logic cell may become more complicated. For example, variations in delay amounts of a plurality of logic cells provided in one signal path in one semiconductor chip may vary differently from each other. Accordingly, even in a case where the four-phase signal as illustrated in FIG. 3 is used, glitches may occur.

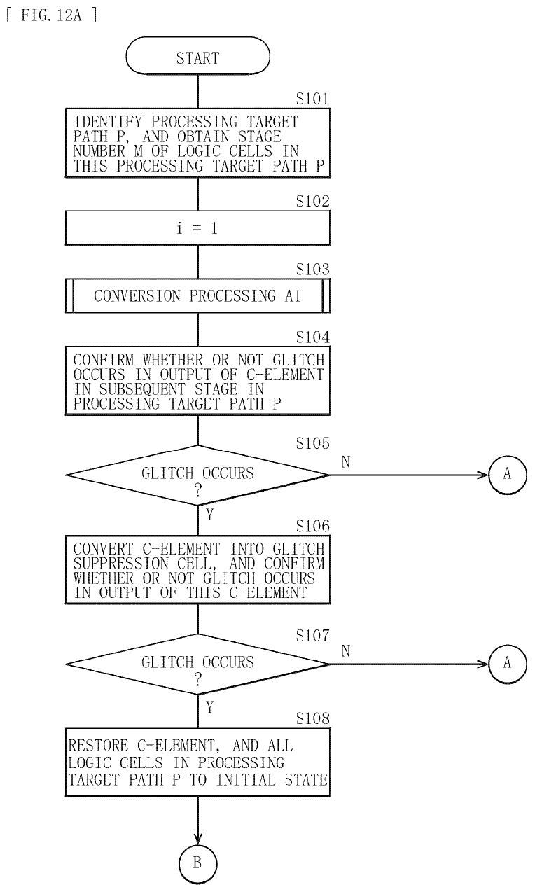

FIG. 11 illustrates an example of occurrence of glitches. This example focuses on a path (a processing target path P) including the inverters 37 and 38 and the AND circuits 43 and 47. For example, there is a possibility that a glitch occurs in a piece of data DT (a reference sign W1) generated by a circuit preceding to the register 11E. This glitch may propagate to an output signal (a reference sign W2) of the register 11E. In addition, there is a possibility that glitches occur in the selection signals B1 and B0 (a reference sign W3) generated by the combinational circuit 12. This glitch may propagate to an output signal (a refence sign W4) of the AND circuit 43. Thereafter, this glitch may further propagate to an output signal (a reference sign W5) of the AND circuit 47. Thereafter, this glitch may further propagate to an output signal (a reference sign W6) of a C-element of the control circuit 21H. In this case, glitches occur in the signals LCK, REQ, and ACK generated by this control circuit 21, which causes a circuit malfunction.

In a case where the glitches occur as described above, a circuit malfunction easily occurs. In addition, in a case where glitches occur, power consumption is increased by switching. Accordingly, it is desirable to suppress glitches.

In the present technology, when the asynchronous logic circuit 1 is designed, a circuit is converted on the basis of design data of the asynchronous logic circuit 1 so as to hinder glitches from occurring. Specifically, in this circuit conversion method, for example, in a case where a predetermined condition is satisfied, a logic cell to which a plurality of signals are to be inputted in the processing target path P is converted into a glitch suppression cell that is configured to suppress glitches. The glitch suppression cell is a logic cell that hinders glitches from occurring or hinders glitches from propagating. Specifically, the glitch suppression cell is a logic cell in which a delay amount in this logic cell is larger than a time difference between transition timings of a plurality of signals to be inputted. In addition, in this circuit conversion method, in a case where the predetermined condition is satisfied, a logic cell in the processing target path P is converted into a QDI (Quasi-Delay Insensitive) logic cell. This QDI logic cell is a 2-wire logic cell, and is configured to hinder glitches from occurring. In the present technology, such a circuit conversion method makes it possible to impalement the asynchronous logic circuit 1 in which glitches are suppressed.

### [Operation and Workings]

Next, description is given of an operation and workings of the asynchronous logic circuit 1 according to the present embodiment.

### (Overview of Overall Operation)

First, description is given of an overview of an overall operation of the asynchronous logic circuit 1 with reference to FIG. 1. The data-path circuit 10 performs processing on the piece of data DT. The register 11 includes, for example, a plurality of latch circuits, and latches the piece of data DT supplied from the combinational circuit 12 in a preceding stage on the basis of the signal LCK that is a local clock. The combinational circuit 12 performs a logical operation on the piece of data DT supplied from the register 11 in a preceding stage, and supplies the obtained piece of data DT to the register 11 in a subsequent stage. The handshake circuit 20 generates a plurality of signals LCK on the basis of the signal REQ and the signal ACK, and supplies the plurality of signals LCK generated to the plurality of respective registers 11 in the data-path circuit 10.

### (About Circuit Conversion Method)

A circuit conversion method that implements the asynchronous logic circuit 1 in which glitches are suppressed is described in detail below. In this circuit conversion method, a computer executes a program to thereby convert a circuit on the basis of the design data of the asynchronous logic circuit 1 so as to hinder glitches from occurring.

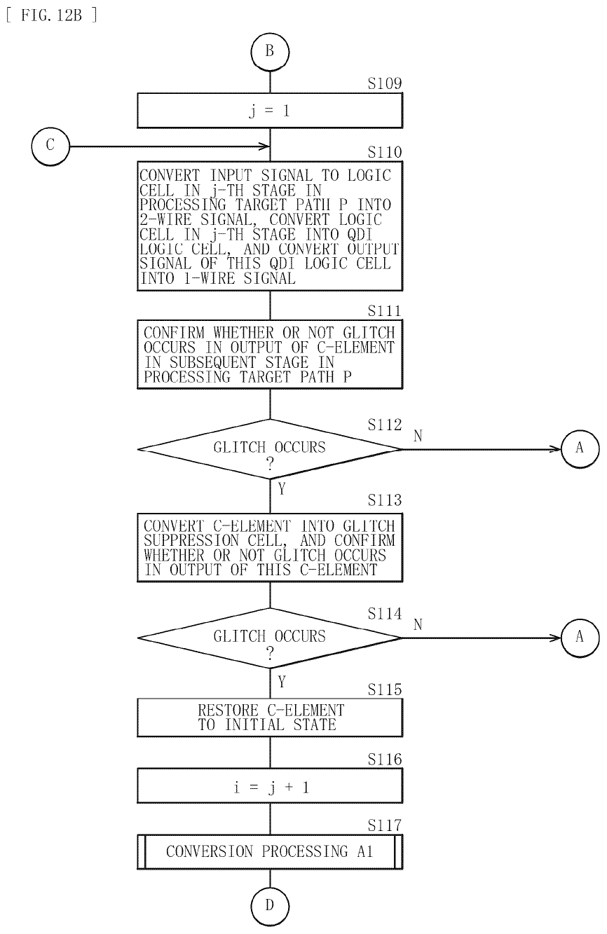

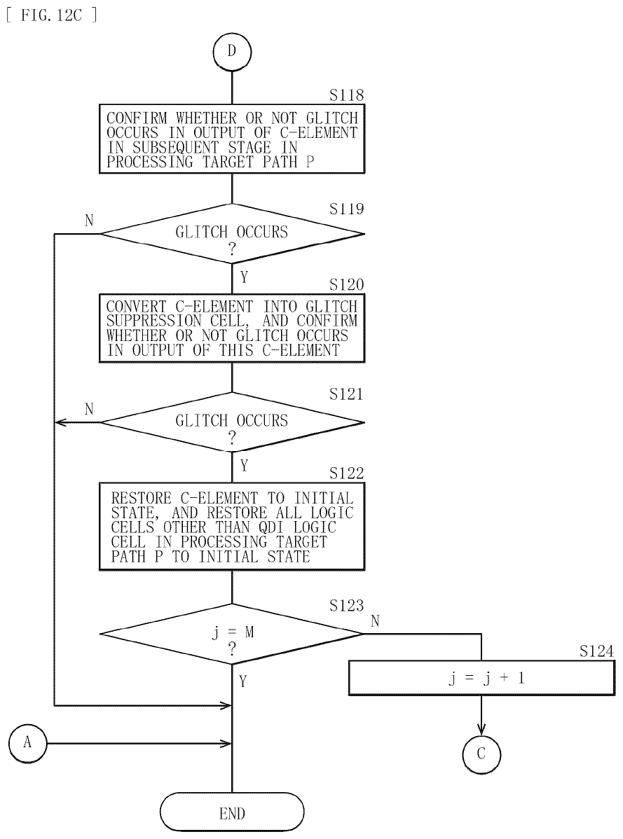

FIGS. 12A to 12C illustrate an example of the circuit conversion method by the computer.

First, the computer identifies the processing target path P where circuit conversion is to be performed, and obtains the stage number M of logic cells in the processing target path P (step S101). In the design data of the asynchronous logic circuit 1, the data-path circuit 10 and the handshake circuit 20 are defined as modules different from each other. The computer is able to identify a port of a signal to be inputted from the combinational circuit 12 of the data-path circuit 10 to the handshake circuit 20, on the basis of such design data, and is able to identify a signal path from this port to the input terminal of the control circuit 21 in the handshake circuit 20. The computer identifies such a signal path as the processing target path P. In the example in FIG. 11, the computer identifies a path including the inverters 37 and 38 and the AND circuits 43 and 47 as the processing target path P. Thereafter, the computer obtains the stage number (the stage number M) of logic cells in this processing target path P.

Next, the computer sets a variable i to “1” (i=1) (step S102), and performs conversion processing A1 (step S103). In this conversion processing A1, the computer sets all logic cells in i-th and subsequent stages in the processing target path P as processing targets. In this example, the variable i is set to “1” in step S102; therefore, the computer sets all logic cells in “1”st and subsequent stages in the processing target path P as processing targets of the conversion processing A1.

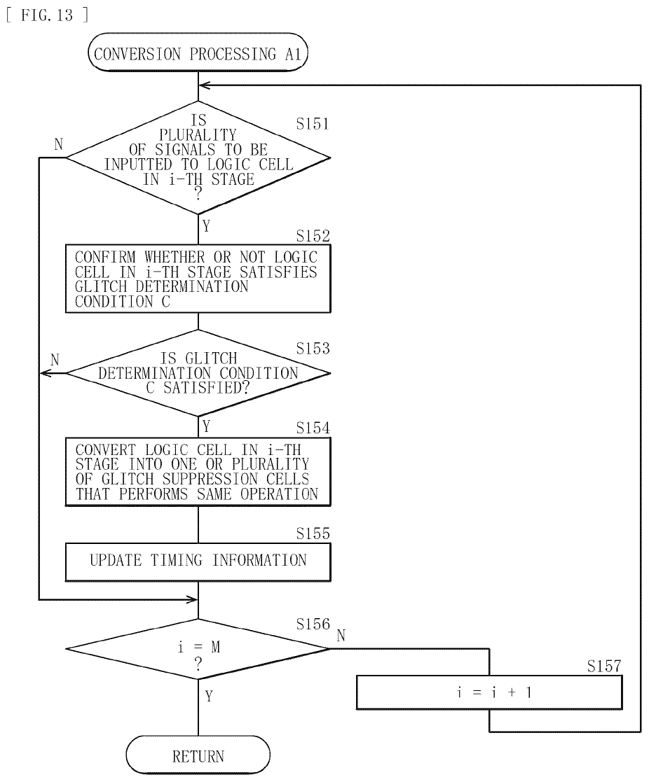

FIG. 13 illustrates an example of a subroutine of the conversion processing A1. In this conversion processing A1, the computer converts each of all logic cells in which a glitch possibly occurs out of all the logic cells in the i-th stage (the first stage in this example) and subsequent stages in the processing target path P into one or a plurality of glitch suppression cells. This operation is described in detail below.

The computer confirms whether or not a plurality of signals is to be inputted to the logic cell in the i-th stage in the processing target path P (step S151). In a case where one signal is to be inputted to the logic cell in the i-th stage (“N” in step S151), the processing proceeds to step S156.

In step S151, in a case where a plurality of signals is to be inputted to the logic cell in the i-th stage (step S151), the computer confirms whether or not the logic cell in the i-th stage satisfies a glitch determination condition C (step S152). The glitch determination condition C is a condition for determining whether or not a glitch possibly occurs in the logic cell. Specifically, the glitch determination condition C is that a delay amount in the logic cell is less than or equal to a time difference between transition timings of the plurality of signals to be inputted. In a case where this logic cell does not satisfy the glitch determination condition C (“N” in step S153), the computer determines that no glitch occurs in this logic cell, and the processing proceeds to step S156.

In a case where this logic cell satisfies the glitch determination condition C in step S152 (“Y” in step S153), the computer determines that a glitch possibly occurs in this logic cell, and converts this logic cell into one or a plurality of glitch suppression cells that performs the same operation (step S154). The glitch suppression cell is a logic cell that performs the same logical operation as the original logic cell, and has a delay amount larger than that of the original logic cell. For example, it is possible to prepare a circuit library, in which various glitch suppression cells are registered, in advance. In this case, the computer obtains a glitch suppression cell corresponding to an i-th logic cell from this circuit library, and converts the i-th logic cell into the obtained glitch suppression cell. Specifically, for example, in a case where the logic cell in the i-th stage is an AND circuit, the computer obtains a glitch suppression cell of an AND circuit having a delay amount larger than that of this AND circuit, and converts the logic cell (the AND circuit) in the i-th stage into this glitch suppression cell. For example, there is a possibility that an AND circuit to which two signals are to be inputted is prepared in the circuit library, but an AND circuit to which three signals are to be inputted is not prepared in the circuit library. In this case, in a case where the logic cell in the i-th stage is an AND circuit to which three signals are to be inputted, the computer first converts this AND circuit to which three signals are to be inputted into, for example, a logic circuit including two AND circuits to which two signals are to be inputted, and converts the two AND circuits into two glitch suppression cells.

Thereafter, the computer updates timing information in the design data (step S155). That is, the computer has converted the logic cell into one or a plurality of glitch suppression cells in step S154; therefore, the delay amount in this logic cell has been changed. Accordingly, the computer updates the timing information in the design data.

Next, the computer confirms whether or not the variable i is equal to the stage number M (i=M) (step S156). In a case where the variable i is smaller than the stage number M (“N” in step S156), the computer increments the variable i (step S157), and the processing returns to step S151. The computer repeats processing in steps S151 to S157 until the variable i becomes equal to the stage number M. Thus, out of all the logic cells in the first and subsequent stages in the processing target path P, each of all the logic cells in which a glitch possibly occurs is converted into one or a plurality of glitch suppression cells.

In a case where the variable i is equal to the stage number M in step S156 (“Y” in step S156), the computer ends the subroutine of the conversion processing A1.

Next, the computer confirms whether or not a glitch occurs in an output of a C-element in a subsequent stage in the processing target path P (step S104). In the example in FIG. 11, the computer confirms whether or not a glitch occurs in an output of a C-element in the control circuit 21H in a subsequent stage in the processing target path P. In a case where no glitch occurs (“N” in step S105), this processing ends.

In a case where a glitch occurs in step S104 (“Y” in step S105), the computer converts this C-element into a glitch suppression cell, and confirms whether or not a glitch occurs in an output of this C-element (step S106). In a case where no glitch occurs (“N” in step S107), this processing ends.

In a case where a glitch occurs in step S106 (“Y” in step S107), the computer restores the C-element converted in step S106, and all logic cells converted in step S103 in the processing target path P to an initial state (step S108).

Next, the computer sets a variable j to “1” (j=1) (step S109).

Next, the computer converts an input signal to the logic cell in a j-th stage in the processing target path P into a 2-wire signal, converts the logic cell in the j-th stage into a QDI logic cell, and converts an output signal of this QDI logic cell into a 1-wire signal (step S110). This causes the output signal of this QDI logic cell to be inputted to the logic cell in a stage subsequent to the QDI logic cell (in a j+1-th stage). It is to be noted that in a case where the logic cell in a stage (a j−1-th stage) preceding to the logic cell in the j-th stage is a QDI logic cell, a 2-wire signal outputted from the logic cell in the j−1-th stage is supplied as it is to the logic cell in the j-th stage. A method of converting a logic cell into a QDI logic cell is described in the following literature, for example. Kouki Uchida, “Studies on Testing QDI Asynchronous Circuits”, Master's Thesis, Nara Institute of Science and Technology, Nakashima Laboratory, 2012

Next, the computer confirms whether or not a glitch occurs in an output of a C-element in a subsequent stage in the processing target path P (step S111). In a case where no glitch occurs (“N” in step S112), this processing ends.

In a case where a glitch occurs in step S11 (“Y” in step S112), the computer converts this C-element into a glitch suppression cell, and confirms whether or not a glitch occurs in an output of this C-element (step S113). In a case where no glitch occurs (“N” in step S114), this processing ends.

In a case where a glitch occurs in step S113 (“Y” in step S114), the computer restores the C-element converted in step S113 to the initial state (step S115).

Next, the computer sets the variable i to “j+1” (i=j+1) (step S116), and performs the conversion processing A1 (step S117). In the conversion processing A1, as illustrated in FIG. 13, the computer converts each of all logic cells in which a glitch possibly occurs out of all logic cells in the i-th stage (a j+1-th stage in this example) and subsequent stages in the processing target path P into one or a plurality of glitch suppression cells.

Next, the computer confirms whether or not a glitch occurs in an output of a C-element in a subsequent stage in the processing target path P (step S118). In a case where no glitch occurs (“N” in step S119), this processing ends.

In a case where a glitch occurs in step S118 (“Y” in step S119), the computer converts this C-element into a glitch suppression cell, and confirms whether or not a glitch occurs in an output of this C-element (step S120). In a case where no glitch occurs (“N” in step S121), this processing ends.

In a case where a glitch occurs in step S120 (“Y” in step S121), the computer restores the C-element converted in step S120 to the initial state, and restores all logic cells other than the QDI logic cell in the processing target path P to the initial state (step S122). Thus, all the logic cells converted in step S117 in the processing target path P are restored to the initial state.

Next, the computer confirms whether or not the variable j is equal to the stage number M (j=M) (step S123). In a case where the variable j is smaller than the stage number M (“N” in step S123), the computer increments the variable j (step S124), and the processing returns to step S110. Thus, the computer converts the logic cell in the j+l-th stage into a QDI logic cell in step S110. By this operation, the computer converts logic cells into QDI logic cells in order from the logic cell in the first stage, and the number of QDI logic cells is increased by one. The computer repeats operations in steps S110 to S124 until no glitch occurs.

In a case where the variable j is equal to the stage number M in step S123 (“Y” in step S123), the computer ends this processing.

Thus, this flow ends.

Using this circuit conversion method makes it possible to suppress glitches in one or more of the AND circuit 43 (the reference sign W4), and the AND circuit 47 (the reference sign W5) in the processing target path P illustrated in FIG. 11, for example, and the C-element (the reference sign W6) of the control circuit 21H in the subsequent stage in the processing target path P. In addition, similar circuit conversion is performed also on the circuit preceding to the register 11E, thereby making it possible to suppress glitches in the circuit preceding to the register 11E (the reference sign W1). In this circuit conversion method, in the asynchronous logic circuit 1, various processing target paths P are set, and processing is performed on each of these processing target paths P. As a result, in the asynchronous logic circuit 1, it is possible to suppress glitches.

### (About Glitch Suppression Cell)

The glitch suppression cell is a logic cell that hinders glitches from occurring or hinders glitches from propagating. Specifically, the glitch suppression cell is a logic cell that performs the same logical operation as the original logic cell, and has a delay amount larger than that of the original logic cell. Glitch suppression cells of various logic cells are described below.

### (Glitch Suppression Cell of Negative AND (NAND) Circuit)

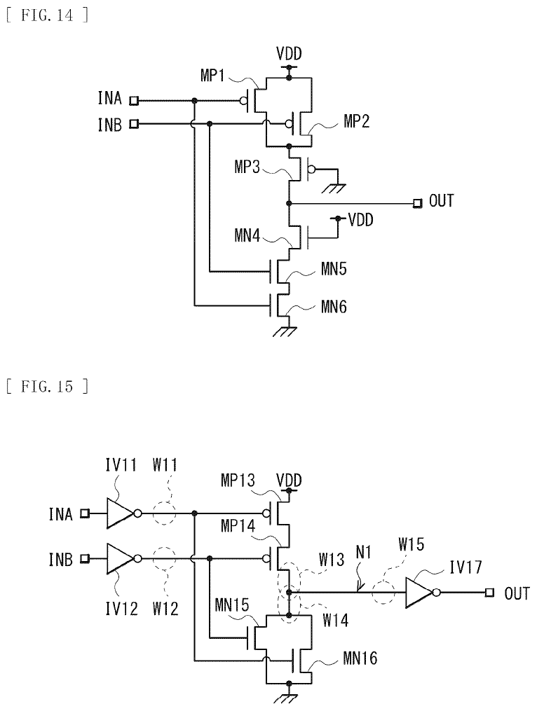

FIG. 14 illustrates an example of a glitch suppression cell of a NAND circuit. This circuit includes transistors MP1 to MP3 and MN4 to MN6. The transistors MP1 to MP3 are P-type MOS (Metal Oxide Semiconductor) transistors, and the transistors MN4 to MN6 are N-type MOS transistors.

The transistor MP1 has agate coupled to an input terminal INA, a source coupled to the power supply node of the power supply voltage VDD, a drain coupled to a drain of the transistor MP2 and a source of the transistor MP3. The transistor MP2 has a gate coupled to an input terminal INB, a source coupled to the power supply node of the power supply voltage VDD, and the drain coupled to the drain of the transistor MP1 and the source of the transistor MP3. The transistor MP3 has a gate coupled to the ground node, the source coupled to the drains of the transistors MP1 and MP2, and a drain coupled to the output terminal OUT. The transistor MN4 has a gate coupled to the power supply node of the power supply voltage VDD, a drain coupled to the output terminal OUT, and a source coupled to a drain of the transistor MN5. The transistor MN5 has agate coupled to the input terminal INB, a drain coupled to the source of the transistor MN4, and a source coupled to a drain of the transistor MN6. The transistor MN6 has a gate coupled to the input terminal INA, the drain coupled to the source of the transistor MN5, and a source coupled to the ground node.

In the NAND circuit illustrated in FIG. 14, the transistors MP3 and MN4 are provided. The transistors MP3 and MN4 function as resistor elements and also function as rectifier elements. This makes it possible to increase a delay amount and rectify a signal. As a result, it is possible for this NAND circuit to suppress glitches, as compared with a case where the transistors MP3 and MN4 are not provided.

FIG. 15 illustrates another example of the glitch suppression cell of the NAND circuit. This circuit includes inverters IV11 and IV12, transistors MP13, MP14, MN15, and MN16, and an inverter IV17. The transistors MP13 and MP14 are P-type MOS transistors, and the transistors MN15 and MN16 are N-type MOS transistors.

The inverter IV11 has an input terminal coupled to the input terminal INA, and an output terminal led to gates of the transistors MP13 and MN16. The inverter IV12 has an input terminal coupled to the input terminal INB, and an output terminal led to gates of MP14 and MN15. The transistor MP13 has the gate led to the output terminal of the inverter IV11, a source coupled to the power supply node of the power supply voltage VDD, and a drain coupled to a source of the transistor MP14. The transistor MP14 has the gate led to the output terminal of the inverter IV12, the source coupled to the drain of the transistor MP13, and a drain led to the node N1. The transistor MN15 has the gate led to the output terminal of the inverter IV12, a drain led to the node N1, and a source coupled to the ground node. The transistor MN16 has the gate led to the output terminal of the inverter IV11, a drain led to the node N1, and a source coupled to the ground node. The inverter IV17 has an input terminal led to the node N1, and an output terminal coupled to the output terminal OUT.

In this NAND circuit, for example, it is possible to provide a transistor in one or more of a path (a path W11) coupling the output terminal of the inverter IV11 and the gates of the transistors MP13 and MN16, a path (a path W12) coupling the output terminal of the inverter IV12 and the gates of the transistors MP14 and MN15, a path (a path W13) coupling the drain of the transistor MP14 and the node N1, a path (a path W14) coupling the node N1 and the drains of the transistors MN15 and MN16, and a path (a path W15) coupling the node N1 and the input terminal of the inverter IV17.

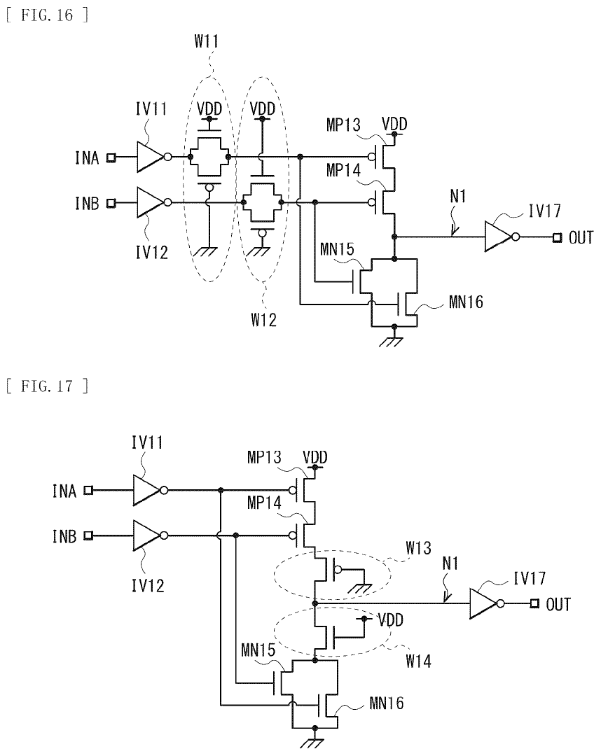

FIG. 16 is an example in which transistors are provided in the paths W11 and W12. An N-type MOS transistor and a P-type MOS transistor are provided in the path W11. The N-type MOS transistor has a gate coupled to the power supply node of the power supply voltage VDD, and the P-type MOS transistor has a gate coupled to the ground node. Likewise, an N-type MOS transistor and a P-type MOS transistor are provided in the path W12. The N-type MOS transistor has a gate coupled to the power supply node of the power supply voltage VDD, and the P-type MOS transistor has a gate coupled to the ground node.

FIG. 17 is an example in which transistors are provided in the paths W13 and W14. A P-type MOS transistor is provided in the path W13. The P-type MOS transistor has a gate coupled to the ground node, a source coupled to the drain of the transistor MP14, and a drain coupled to the node N1. An N-type MOS transistor is provided in the path W14. The N-type MOS transistor has a gate coupled to the power supply node of the power supply voltage VDD, a drain coupled to the node N1, and a source coupled to the drains of the transistors MN15 and MN16.

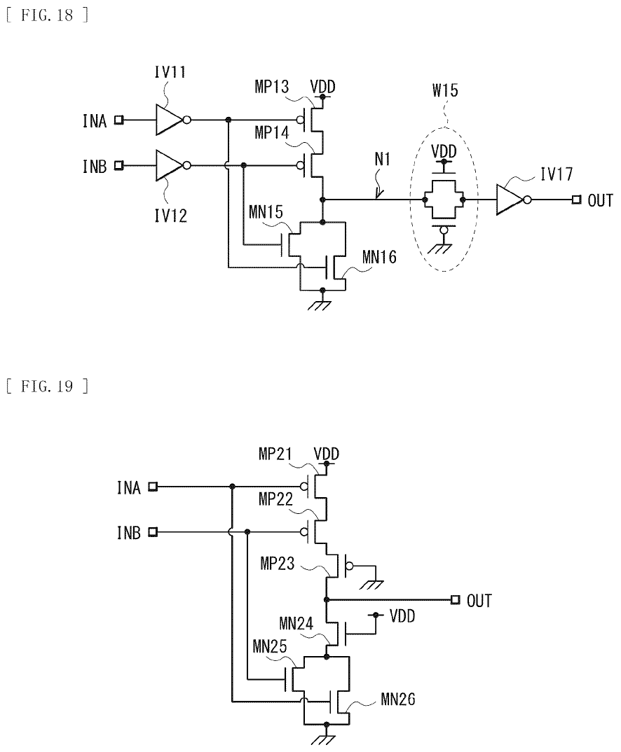

FIG. 18 is an example in which transistors are provided in the path W15. An N-type MOS transistor and a P-type MOS transistor are provided in the path W15. The N-type MOS transistor has a gate coupled to the power supply node of the power supply voltage VDD, and the P-type MOS transistor has a gate coupled to the ground node.

The transistors provided in the paths W11 to W15 function as resistor elements and also function as rectifier elements. This makes it possible to increase a delay amount and rectify a signal. As a result, it is possible for this NAND circuit to suppress glitches, as compared with a case where the transistors are not provided in the paths W11 to W15.

### (Glitch Suppression Cell of Negative OR (NOR) Circuit)

FIG. 19 illustrates an example of a glitch suppression cell of an NOR circuit. This circuit includes transistors MP21 to MP23 and MN24 to MN26. The transistors MP21 to MP23 are P-type MOS transistors, and the transistors MN24 to MN26 are N-type MOS transistors.

The transistor MP21 has a gate coupled to the input terminal INA, a source coupled to the power supply node of the power supply voltage VDD, and a drain coupled to a source of the transistor MP22. The transistor MP22 has a gate coupled to the input terminal INB, the source coupled to the drain of the transistor MP21, and a drain coupled to a source of the transistor MP23. The transistor MP23 has a gate grounded, the source coupled to the drain of the transistor MP22, and a drain coupled to the output terminal OUT. The transistor MN24 has a gate coupled to the power supply node of the power supply voltage VDD, a drain coupled to the output terminal OUT, and a source coupled to drains of the transistors MN25 and MN26. The transistor MN25 has a gate coupled to the input terminal INB, the drain coupled to the source of the transistor MN24 and the drain of the transistor MN26, and a source coupled to the ground node. The transistor MN26 has a gate coupled to the input terminal INA, the drain coupled to the source of the transistor MN24 and the drain of the transistor MN25, and a source coupled to the ground node.

In the NOR circuit illustrated in FIG. 19, the transistors MP23 and MN24 are provided. The transistors MP23 and MN24 function as resistor elements and also function as rectifier elements. This makes it possible to increase a delay amount and rectify a signal. As a result, it is possible for this NOR circuit to suppress glitches, as compared with a case where the transistors MP23 and MN24 are not provided.

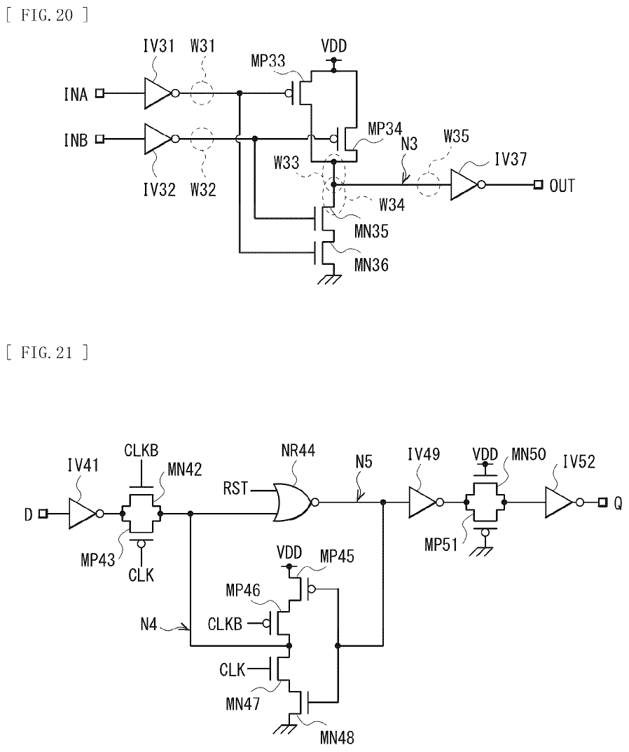

FIG. 20 illustrates another example of the glitch suppression cell of the NOR circuit. This circuit includes inverters IV31 and IV32, transistors MP33, MP34, MN35, and MN36, and an inverter IV37. The transistors MP33 and MP34 are P-type MOS transistors, and the transistors MN35 and MN36 are N-type MOS transistors.

The inverter IV31 has an input terminal coupled to the input terminal INA, and an output terminal led to gates of the transistors MP33 and MN36. The inverter IV32 has an input terminal coupled to the input terminal INB, and an output terminal led to gates of the transistors MP34 and MN35. The transistor MP33 has the gate led to the output terminal of the inverter IV31, a source coupled to the power supply node of the power supply voltage VDD, and a drain led to a node N3. The transistor MP34 has the gate led to the output terminal of the inverter IV32, a source coupled to the power supply node of the power supply voltage VDD, and a drain led to the node N3. The transistor MN35 has the gate led to the output terminal of the inverter IV32, a drain led to the node N3, and a source coupled to a drain of the transistor MN36. The transistor MN36 has the gate led to the output terminal of the inverter IV31, the drain coupled to the source of the transistor MN35, and a source coupled to the ground node. The inverter IV37 has an input terminal led to the node N3, and an output terminal coupled to the output terminal OUT.

In this NOR circuit, for example, it is possible to provide a transistor in one or more of a path (a path W31) coupling the output terminal of the inverter IV31 and the gates of the transistors MP33 and MN36, a path (a path W32) coupling the output terminal of the inverter IV32 and the gates of the transistors MP34 and MN35, a path (path W33) coupling the drains of the transistors MP33 and MP34 and the node N3, a path (a path W34) coupling the node N3 and the drain of the transistor MN35, and a path (a path W35) coupling the node N3 and the input terminal of the inverter IV37. An example in which transistors are provided in the paths W31 and W32 is similar to the example in FIG. 16. An example in which transistors are provided in the paths W33 and W34 is similar to the example in FIG. 17. An example in which transistors are provided in the path W35 is similar to the example in FIG. 18.

The transistors provided in the paths W31 to W35 function as resistor elements and also function as rectifier elements. This makes it possible to increase a delay amount and rectify a signal. As a result, it is possible for this NOR circuit to suppress glitches, as compared with a case where the transistors are not provided in the paths W31 to W35.

### (Glitch Suppression Cell of D-Type Latch Circuit)

FIG. 21 illustrates an example of a glitch suppression cell of a latch circuit. This circuit includes an inverter IV41, transistors MN42 and MP43, a NOR circuit NR44, transistors MP45, MP46, MN47, and MN48, an inverter IV49, transistors MN50 and MP51, and an inverter IV52. The transistors MP43, MP45, MP46, and MP51 are P-type MOS transistors, and the transistors MN42, MN47, MN48, and MN50 are N-type MOS transistors.

The inverter IV41 has an input terminal coupled to a terminal D, and an output terminal coupled to the transistors MN42 and MP43. The transistor MN42 is provided in a path coupling the output terminal of the inverter IV41 and a node N4, and has a gate to be supplied with a clock signal CLKB. The transistor MP43 is provided in the path coupling the output terminal of the inverter IV41 and the node N4, and has a gate to be supplied with a clock signal CLK. The NOR circuit NR44 has a first input terminal to be supplied with the reset signal RST, a second input terminal coupled to the node N4, and an output terminal coupled to a node N5. The transistor MP45 has a gate coupled to the node N5, a source coupled to the power supply node of the power supply voltage VDD, and a drain coupled to a source of the transistor MP46. The transistor MP46 has a gate to be supplied with the clock signal CLKB, the source coupled to the drain of the transistor MP45, and a drain coupled to the node N4. The transistor MN47 has agate to be supplied with the clock signal CLK, a drain coupled to the node N4, and a source coupled to a drain of the transistor MN48. The transistor MN48 has a gate coupled to the node N5, the drain coupled to the source of the transistor MN47, and a source coupled to the ground node. The inverter IV49 has an input terminal coupled to the node N5, and an output terminal coupled to the transistors MN50 and MP51. The transistor MN50 is provided in a path coupling the output terminal of the inverter IV49 and the input terminal of the inverter IV52, and has a gate coupled to the power supply node of the power supply voltage VDD. The transistor MP51 is provided in the path coupling the output terminal of the inverter IV49 and the input terminal of the inverter IV52, and has a gate coupled to the ground node. The inverter IV52 has an input terminal coupled to the transistors MN50 and MP51, and an output terminal coupled to a terminal Q. The clock signal CLKB is an inverted signal of the clock signal CLK.

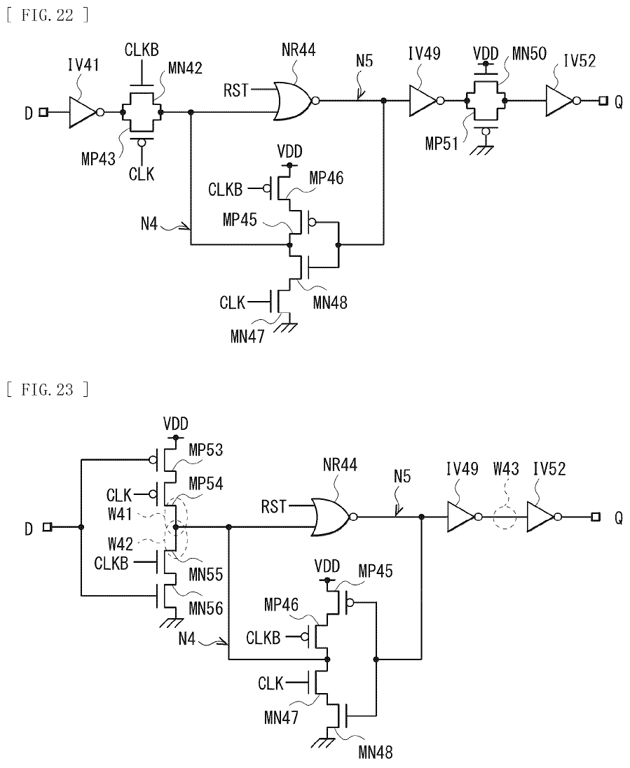

FIG. 22 illustrates another example of the glitch suppression cell of the latch circuit. This circuit in FIG. 22 corresponds to the circuit in FIG. 21 in which coupling of the transistors MP45, MP46, MN47, and MN48 is changed. The transistor MP46 has the gate to be supplied with the clock signal CLKB, the source coupled to the power supply node of the power supply voltage VDD, and the drain coupled to the source of the transistor MP45. The transistor MP45 has the gate coupled to the node N5, the source coupled to the drain of the transistor MP46, and the drain coupled to the node N4. The transistor MN48 has the gate coupled to the node N5, the drain coupled to the node N4, and the source coupled to the drain of the transistor MN47. The transistor MN47 has the gate to be supplied with the clock signal CLK, the drain coupled to the source of the transistor MN48, and the source coupled to the ground node.

In the latch circuit illustrated in FIGS. 21 and 22, the transistors MN50 and MP51 are provided. The transistors MN50 and MP51 function as resistor elements and also function as rectifier elements. This makes it possible to increase a delay amount and rectify a signal. As a result, it is possible for this latch circuit to suppress glitches, as compared with a case where the transistors MN50 and MP51 are not provided.

FIG. 23 illustrates another example of the glitch suppression cell of the latch circuit. This circuit in FIG. 23 corresponds to the circuit in FIG. 21 in which circuit portions of the inverter IV41 and the transistors MN42 and MP43 are changed. This latch circuit includes transistors MP53, MP54, MN55, and MN56. The transistors MP53 and MP54 are P-type MOS transistors, and the transistors MN55 and MN56 are N-type MOS transistors.

The transistor MP53 has a gate coupled to the terminal D, a source coupled to the power supply node of the power supply voltage VDD, and a drain coupled to a source of the transistor MP54. The transistor MP54 has a gate to be supplied with the clock signal CLK, the source coupled to the drain of the transistor MP53, and a drain led to the node N4. The transistor MN55 has a gate to be supplied with the clock signal CLKB, a drain led to the node N4, and a source coupled to a drain of the transistor MN56. The transistor MN56 has a gate coupled to the terminal D, the drain coupled to the source of the transistor MN55, and a source coupled to the ground node.

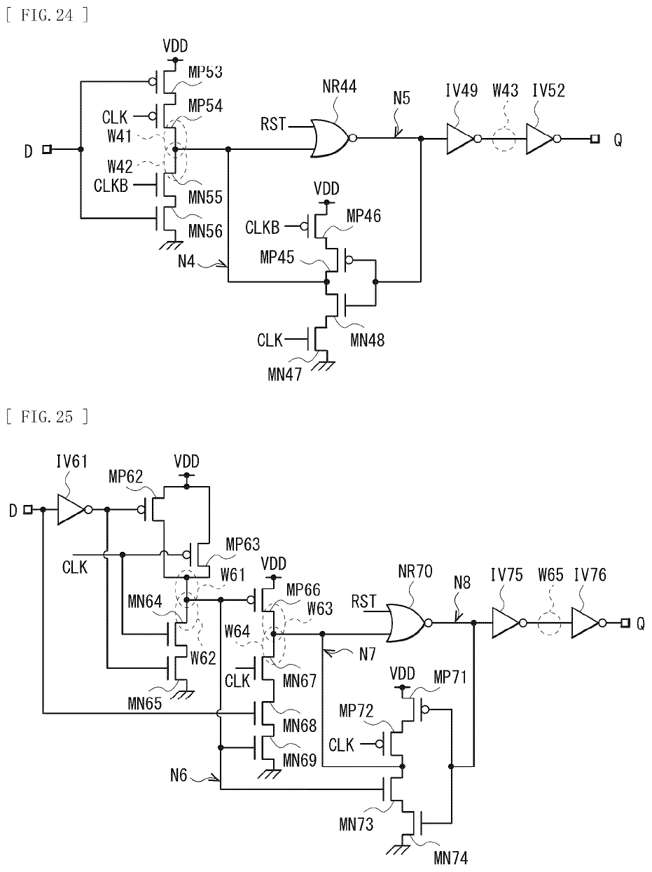

FIG. 24 illustrates another example of the glitch suppression cell of the latch circuit. This circuit in FIG. 24 corresponds to the circuit in FIG. 23 in which coupling of the transistors MP45, MP46, MN47, and MN48 is changed. The transistor MP46 has the gate to be supplied with the clock signal CLKB, the source coupled to the power supply node of the power supply voltage VDD, and the drain coupled to the source of the transistor MP45. The transistor MP45 has the gate coupled to the node N5, the source coupled to the drain of the transistor MP46, and the drain coupled to the node N4. The transistor MN48 has the gate coupled to the node N5, the drain coupled to the node N4, and the source coupled to the drain of the transistor MN47. The transistor MN47 has the gate to be supplied with the clock signal CLK, the drain coupled to the source of the transistor MN48, and the source coupled to the ground node.

In the latch circuit illustrated in FIGS. 23 and 24, for example, it is possible to provide a transistor in one or more of a path (a path W41) coupling the drain of the transistor MP54 and the node N4, a path (a path W42) coupling the node N4 and the drain of the transistor MN55, and a path (a path W43) coupling the output terminal of the inverter IV49 and the input terminal of the inverter IV52. An example in which transistors are provided in the paths W41 and W42 is similar to the example in FIG. 17. An example in which transistors are provided in the path W43 is similar to the example in FIG. 18.

The transistors provided in the paths W41 to W43 function as resistor elements and also function as rectifier elements. This makes it possible to increase a delay amount and rectify a signal. As a result, it is possible for this latch circuit to suppress glitches, as compared with a case where the transistors are not provided in the path W41 to W43.

FIG. 25 illustrates another example of the glitch suppression cell of the latch circuit. This circuit includes an inverter IV61, transistors MP62, MP63, MN64, MN65, MP66, and MN67 to MN69, a NOR circuit NR70, transistors MP71, MP72, MN73, and MN74, and inverters IV75 and IV76. The transistors MP62, MP63, MP66, MP71, and MP72 are P-type MOS transistors, and the transistors MN64, MN65, MN67 to MN69, MN73, and MN74 are N-type MOS transistors. This latch circuit is configured to operate on the basis of the clock signal CLK without using the clock signal CLKB.

The inverter IV61 has an input terminal coupled to the terminal D, and an output terminal coupled to gates of the transistors MP62 and MN65. The transistor MP62 has the gate coupled to the output terminal of the inverter IV61, a source coupled to the power supply node of the power supply voltage VDD, and a drain led to a node N6. The transistor MP63 has a gate to be supplied with the clock signal CLK, a source coupled to the power supply node of the power supply voltage VDD, and a drain led to the node N6. The transistor MN64 has a gate to be supplied with the clock signal CLK, a drain led to the node N6, and a source coupled to a drain of the transistor MN65. The transistor MN65 has the gate coupled to the output terminal of the inverter IV61, the drain coupled to the source of the transistor MN64, and a source coupled to the ground node. The transistor MP66 has a gate coupled to the node N6, a source coupled to the power supply node of the power supply voltage VDD, and a drain led to a node N7. The transistor MN67 has a gate to be supplied with the clock signal CLK, a drain led to the node N7, and a source coupled to a drain of the transistor MN68. The transistor MN68 has a gate coupled to the terminal D, the drain coupled to the source of the transistor MN67, and a source coupled to a drain of the transistor MN69. The transistor MN69 has a gate coupled to the node N6, the drain coupled to the source of the transistor MN68, and a source coupled to the ground node. The NOR circuit NR70 has a first input terminal to be supplied with the reset signal RST, a second input terminal coupled to the node N7, and an output terminal coupled to a node N8. The transistor MP71 has a gate coupled to the node N8, a source coupled to the power supply node of the power supply voltage VDD, and a drain coupled to a source of the transistor MP72. The transistor MP72 has a gate to be supplied with the clock signal CLK, the source coupled to the drain of the transistor MP71, and a drain coupled to the node N7. The transistor MN73 has a gate coupled to the node N6, a drain coupled to the node N7, and a source coupled to a drain of the transistor MN74. The transistor MN74 has a gate coupled to the node N8, the drain coupled to the source of the transistor MN73, and a source coupled to the ground node. The inverter IV75 has an input terminal coupled to the node N8, and an output terminal led to an input terminal of the inverter IV76. The inverter IV76 has the input terminal led to the output terminal of the inverter IV75, and an output terminal coupled to the terminal Q.

Here, the inverter IV61 corresponds to a specific example of a “first inverter” in an embodiment of the present disclosure. The inverter IV75 corresponds to a specific example of a “second inverter” in an embodiment of the present disclosure. The inverter IV76 corresponds to a specific example of a “third inverter” in an embodiment of the present disclosure. The NOR circuit NR70 corresponds to a specific example of a “NOR circuit” in an embodiment of the present disclosure. The transistor MP62 corresponds to a specific example of a “first transistor” in an embodiment of the present disclosure. The transistor MP63 corresponds to a specific example of a “second transistor” in an embodiment of the present disclosure. The transistor MN64 corresponds to a specific example of a “third transistor” in an embodiment of the present disclosure. The transistor MN65 corresponds to a specific example of a “fourth transistor” in an embodiment of the present disclosure. The transistor MP66 corresponds to a specific example of a “fifth transistor” in an embodiment of the present disclosure. The transistor MN67 corresponds to a specific example of a “sixth transistor” in an embodiment of the present disclosure. The transistor MN68 corresponds to a specific example of a “seventh transistor” in an embodiment of the present disclosure. The transistor MN69 corresponds to a specific example of an “eighth transistor” in an embodiment of the present disclosure. The transistor MP71 corresponds to a specific example of a “ninth transistor” in an embodiment of the present disclosure. The transistor MP72 corresponds to a specific example of a “tenth transistor” in an embodiment of the present disclosure. The transistor MN73 corresponds to a specific example of an “eleventh transistor” in an embodiment of the present disclosure. The transistor MN74 corresponds to a specific example of a “twelfth transistor” in an embodiment of the present disclosure.

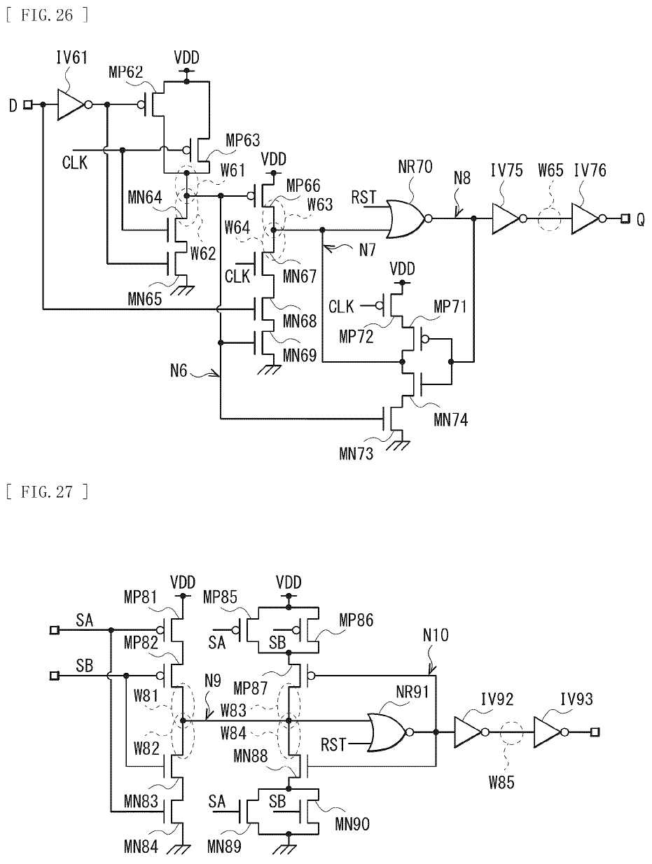

FIG. 26 illustrates another example of the glitch suppression cell of the latch circuit. This circuit in FIG. 26 corresponds to the circuit in FIG. 25 in which coupling of the transistor MP71, MP72, MN73, and MN74 is changed. The transistor MP72 has the gate to be supplied with the clock signal CLK, the source coupled to the power supply node of the power supply voltage VDD, and the drain coupled to the source of the transistor MP71. The transistor MP71 has the gate coupled to the node N8, the source coupled to the drain of the transistor MP72, and the drain coupled to the node N7. The transistor MN74 has the gate coupled to the node N8, the drain coupled to the node N7, and the source coupled to the drain of the transistor MN73. The transistor MN73 has the gate coupled to the node N6, the drain coupled to the source of the transistor MN74, and the source coupled to the ground node.

In the latch circuit illustrated in FIGS. 25 and 26, the transistors MN67 to MN69 are provided. For example, in a case where the clock signal CLK is at the low level, the transistor MP63 is turned on, which changes a voltage at the node N6 to the high level and turns on the transistor MN69. This makes it possible to prevent the drain of the transistor MN69 from being turned to a floating state. The transistor MN68 is turned off in a case where a signal at the terminal D is at the low level. This makes it possible to reduce a possibility that a leakage current flows from the power supply node to the ground node through the transistors MP66 and MN67 to MN69 upon transition of the clock signal. In addition, in this latch circuit, only the clock signal CLK is used, and the clock signal CLKB is not used; therefore, a glitch caused by a transition timing difference between the clock signal CLK and the clock signal CLKB does not occur. In addition, a signal is rectified in a MOS transistor to which the clock signal CLK is inputted. As a result, in this latch circuit, it is possible to hinder glitches from occurring.

In the latch circuit illustrated in FIGS. 25 and 26, for example, it is possible to provide a transistor in one or more of a path (a path W61) coupling the drains of the transistors MP62 and MP63 and the node N6, a path (a path W62) coupling the node N6 and the drain of the transistor MN64, a path (a path W63) coupling the drain of the transistor MP66 and the node N7, a path (a path W64) coupling the node N7 and the drain of the transistor MN67, and a path (a path W65) coupling the output terminal of the inverter IV75 and the input terminal of the inverter IV76. An example in which transistors are provided in the paths W61 and W62 is similar to the example in FIG. 17. An example in which transistors are provided in the paths W63 and W64 is similar to the example in FIG. 17. An example in which transistors are provided in the path W65 is similar to the example in FIG. 18.

### (Glitch Suppression Cell of C-Element)

It is possible to configure a C-element with use of, for example, the AND circuit 101, the OR circuit 102, the NAND circuit 103, and the latch circuit 104, as illustrated in FIG. 4. It is possible to configure this AND circuit 101 with use of, for example, a NAND circuit and an inverter; therefore, it is possible to configure this NAND circuit with sue of the glitch suppression cell illustrated in FIGS. 14 to 18. Likewise, it is possible to configure the OR circuit 102 with use of, for example, a NOR circuit and an inverter; therefore, it is possible to configure this NOR circuit with use of the glitch suppression cell illustrated in FIGS. 19 and 20. In addition, it is possible to configure the NAND circuit 103 with use of the glitch suppression cell illustrated in FIGS. 14 to 18. In addition, it is possible to configure the latch circuit 104 with use of the glitch suppression cell illustrated in FIGS. 21 to 26.

In addition, it is possible to configure the C-element with use of, for example, the AND circuits 111 to 113, the NOR circuit 114, and the AND circuit 115, as illustrated in FIG. 5. Also in this case, it is possible to configure each logic cell included in the C-element with use of the glitch suppression cell illustrated in FIGS. 14 to 26.

FIG. 27 illustrates another example of the glitch suppression cell of the C-element. This circuit includes transistors MP81, MP82, MN83, MN84, MP85 to MP87, and MN88 to MN90, a NOR circuit NR91, and inverters IV92 and IV93. The transistors MP81, MP82, and MP85 to MP87 are P-type MOS transistors, and the transistor MN88 to MN90 are N-type MOS transistors.

The transistor MP81 has agate to be supplied with a signal SA, a source coupled to the power supply node of the power supply voltage VDD, and a drain coupled to a source of the transistor MP82. The transistor MP82 has a gate to be supplied with a signal SB, a source coupled to the drain of the transistor MP81, and a drain led to a node N9. The transistor MN83 has a gate to be supplied with the signal SB, a drain led to the node N9, and a source coupled to a drain of the transistor MN84. The transistor MN84 has a gate to be supplied with the signal SA, the drain coupled to the source of the transistor MN83, and a source coupled to the ground node. The transistor MP85 has a gate to be supplied with the signal SA, a source coupled to the power supply node of the power supply voltage VDD, and a drain coupled to a drain of the transistor MP86 and a source of the transistor MP87. The transistor MP87 has agate coupled to anode N10, the source coupled to the drains of the transistors MP85 and MP86, and a drain led to the node N9. The transistor MN88 has a gate coupled to the node N10, a drain led to the node N9, and a source coupled to drains of the transistors MN89 and MN90. The transistor MN89 has a gate to be supplied with the signal SA, the drain coupled to the source of the transistor MN88 and the drain of the transistor MN90, and a source coupled to the ground node. The transistor MN90 has a gate to be supplied with the signal SB, the drain coupled to the source of the transistor MN88 and the drain of the transistor MN89, and a source coupled to the ground node. The NOR circuit NR91 has a first input terminal coupled to the node N9, a second input terminal to be supplied with the reset signal RST, and an output terminal coupled to the node N10. The inverter IV92 has an input terminal coupled to the node N10, and an output terminal led to an input terminal of the inverter IV93. The inverter IV93 has the input terminal led to the output terminal of the inverter IV92, and an output terminal coupled to an output terminal of the C-element.

Here, the transistor MP81 corresponds to a specific example of a “nineteenth transistor” in an embodiment of the present disclosure. The transistor MP82 corresponds to a specific example of a “twentieth transistor” in an embodiment of the present disclosure. The transistor MN83 corresponds to a specific example of a “twenty-first transistor” in an embodiment of the present disclosure. The transistor MN84 corresponds to a specific example of a “twenty-second transistor” in an embodiment of the present disclosure. The transistor MP86 corresponds to a specific example of a “twenty-third transistor” in an embodiment of the present disclosure. The transistor MP87 corresponds to a specific example of a “twenty-fourth transistor” in an embodiment of the present disclosure. The transistor MN88 corresponds to a specific example of a “twenty-fifth transistor” in an embodiment of the present disclosure. The transistor MN90 corresponds to a specific example of a “twenty-sixth transistor” in an embodiment of the present disclosure. The transistor MP85 corresponds to a specific example of a “twenty-seventh transistor” in an embodiment of the present disclosure. The transistor MN89 corresponds to a specific example of a “twenty-eighth transistor” in an embodiment of the present disclosure. The NOR circuit NR71 corresponds to a specific example of a “NOR circuit” in an embodiment of the present disclosure. The inverter IV92 corresponds to a specific example of a “fourth inverter” in an embodiment of the present disclosure. The inverter IV93 corresponds to a specific example of a “fifth inverter” in an embodiment of the present disclosure.

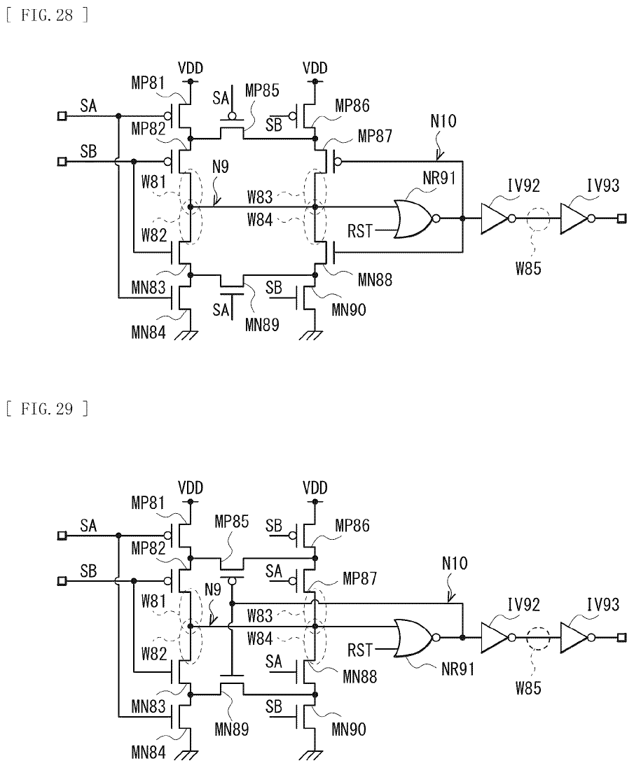

FIG. 28 illustrates another example of the glitch suppression cell of the C-element. This circuit in FIG. 28 corresponds to the circuit in FIG. 27 in which coupling of the transistors MP85 to MP87 and MN88 to MN90 is changed. The transistor MP85 is provided in a path coupling the drain of the transistor MP81 and the source of the transistor MP82 to the drain of the transistor MP86 and the source of the transistor MP87, and has the gate to be supplied with the signal SA. The transistor MP86 has the gate to be supplied with the signal SB, the source coupled to the power supply node of the power supply voltage VDD, and the drain coupled to the source of the transistor MP87 and the transistor MP85. The transistor MP87 has the gate coupled to the node N10, the source coupled to the drain of the transistor MP86 and the transistor MP85, and the drain led to the node N9. The transistor MN88 has the gate coupled to the node N10, the drain led to the node N9, and the source coupled to the drain of the transistor MN90 and the transistor MN89. The transistor MN89 is provided in a path coupling the source of the transistor MN83 and the drain of the transistor MN84 to the source of the transistor MN88 and the drain of the transistor MN90, and has the gate to be supplied with the signal SA. The transistor MN90 has the gate to be supplied with the signal SB, the drain coupled to the source of the transistor MN88 and the transistor MN89, and the source coupled to the ground node. Here, the transistor MP85 corresponds to a specific example of a “twenty-ninth transistor” in an embodiment of the present disclosure. The transistor MN89 corresponds to a specific example of a “thirtieth transistor” in an embodiment of the present disclosure.

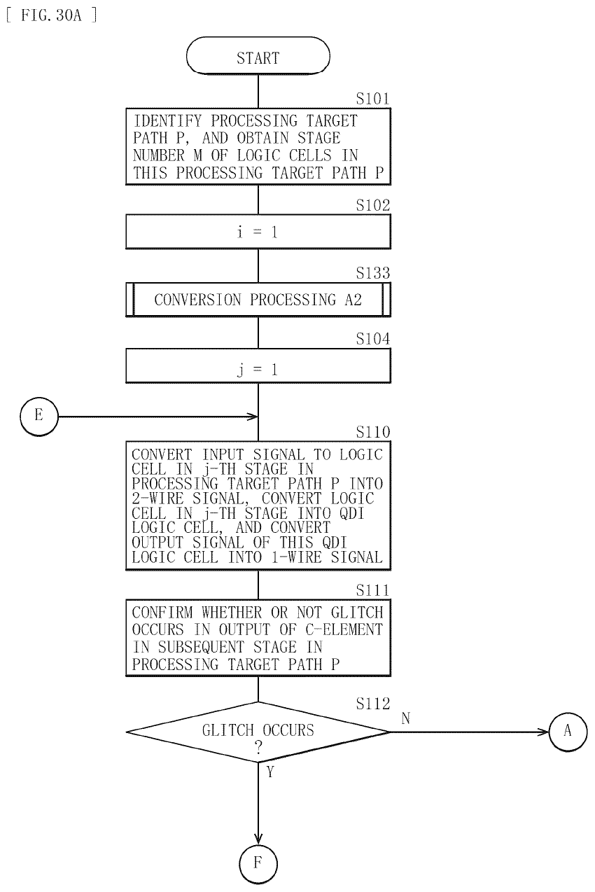

FIG. 29 illustrates another example of the glitch suppression cell of the C-element. This circuit in FIG. 29 corresponds to the circuit in FIGS. 27 and 28 in which coupling of the transistors MP85 to MP87 and MN88 to MN90 is changed. The transistor MP85 is provided in a path coupling the drain of the transistor MP81 and the source of the transistor MP82 to the drain of the transistor MP86 and the source of the transistor MP87, and has the gate coupled to the node N10. The transistor MP86 has the gate to be supplied with the signal SB, the source coupled to the power supply node of the power supply voltage VDD, and the drain coupled to the source of the transistor MP87 and the transistor MP85. The transistor MP87 has the gate to be supplied with the signal SA, the source coupled to the drain of the transistor MP86 and the transistor MP85, and the drain led to the node N9. The transistor MN88 has the gate to be supplied with the signal SA, the drain led to the node N9, and the source coupled to the drain of the transistor MN90 and the transistor MN89. The transistor MN89 is provided in a path coupling the source of the transistor MN83 and the drain of the transistor MN84 to the source of the transistor MN88 and the drain of the transistor MN90, and has the gate coupled to the node N10. The transistor MN90 has the gate to be supplied with the signal SB, the drain coupled to the source of the transistor MN88 and the transistor MN89, and the source coupled to the ground node. The transistor MP85 corresponds to a specific example of a “twenty-ninth transistor” in an embodiment of the present disclosure. The transistor MN89 corresponds to a specific example of a “thirtieth transistor” in an embodiment of the present disclosure.

In the C-element illustrated in FIGS. 27 to 29, for example, it is possible to provide a transistor in one or more of a path (a path W81) coupling the drain of the transistor MP82 and the node N9, a path (a path W82) coupling the node N9 and the drain of the transistor MN83, a path (a path W83) coupling the drain of the transistor MP87 and the node N9, a path (a path W84) coupling the node N9 and the drain of the transistor MN88, and a path (a path W85) coupling the output terminal of the inverter IV92 and the input terminal of the inverter IV93. An example in which transistors are provided in the paths W81 and W82 is similar to the example in FIG. 17. An example in which transistors are provided in the paths W83 and W84 is similar to the example in FIG. 17. An example in which transistors are provided in the path W85 is similar to the example in FIG. 18.

As described above, in the circuit conversion method, using such a glitch suppression cell makes it possible to suppress glitches.

As described above, in the circuit conversion method, for example, as illustrated in step S101, the computer sets the processing target path P in the asynchronous logic circuit 1. Thereafter, for example, as illustrated in step S152 of the conversion processing A1 in step S103, the computer performs first processing for determining whether or not a glitch occurs in each of a plurality of logic cells in the processing target path P. Thereafter, for example, as illustrated in steps S153 and S154 of the conversion processing A1 in step S103, the computer performs second processing including conversion processing for converting one or more logic cells in which a glitch is determined to occur in the first processing into one or more glitch suppression logic cells. The one or more glitch suppression logic cells are configured to suppress glitches, and perform the same logical operation as the one or more logic cells. Thereafter, as illustrated in steps S104 to S107, after this second processing, the computer performs third processing for determining whether or not a glitch occurs in a C-element that is a subsequent-stage circuit in the processing target path P. Accordingly, in this circuit conversion method, it is possible to convert a logic cell in which a glitch is determined to occur into a glitch suppression logic cell, which makes it possible to suppress glitches.

Thereafter, in this circuit conversion method, for example, as illustrated in step S108, in a case where a glitch is determined as occurring in the third processing, the computer performs fourth processing for changing the plurality of logic cells in the processing target path P to the initial state. Thereafter, for example, as illustrated in step S110, after this fourth processing, the computer performs fifth processing for sequentially selecting one of the plurality of logic cells in the processing target path P and converting the selected logic cell into a QDI logic cell. Thereafter, for example, as illustrated in steps S111 to S114, the computer performs sixth processing for determining whether or not a glitch occur in a C-element that is a subsequent-stage circuit every time one of the plurality of logic cells is selected in the fifth processing. Accordingly, in this circuit conversion method, it is possible to convert the logic cell into a QDI logic cell that makes it possible to suppress glitches. This makes it possible to suppress glitches. In addition, one of the plurality of logic cells is sequentially selected and the selected logic cell is converted into a QDI logic cell in such a manner. Accordingly, in this circuit conversion method, for example, the logic cells in the processing target path P are converted into QDI logic cells in order from the first stage. Thereafter, for example, in a case where a glitch is determined as not occurring in midstream, it is possible to end this processing. This makes it possible to suppress glitches while suppressing the number of QDI logic cells. The QDI logic cell is a 2-wire circuit, and includes various circuits for suppressing glitches; therefore, the QDI logic cell has a large circuit scale. Accordingly, reducing the number of QDI logic cells makes it possible to reduce a circuit area. As a result, in this circuit conversion method, it is possible to effectively suppress glitches while reducing the circuit area.

### Effects

As described above, in the present embodiment, the computer sets the processing target path in the asynchronous logic circuit. Thereafter, the computer performs the first processing for determining whether or not a glitch occurs in each of the plurality of logic cells in the processing target path. Thereafter, the computer performs the second processing including the conversion processing for converting one or more logic cells in which a glitch is determined to occur in the first processing into one or more glitch suppression logic cells. The one or more glitch suppression logic cells are configured to suppress glitches, and perform the same logical operation as the one or more logic cells. Thereafter, after this second processing, the computer performs the third processing for determining whether or not a glitch occurs in a C-element that is a subsequent-stage circuit in the processing target path. Thus, it is possible to suppress glitches.

### Modification Example 1-1

In the embodiment described above, as illustrated in FIGS. 12A to 12C, and 13, in step S103, all logic cells satisfying the glitch determination condition C are converted into one or a plurality of glitch suppression cells, and thereafter, in steps S104 and S106, it is confirmed whether or not a glitch occurs in an output of a C-element in a subsequent stage in the processing target path P. Likewise, in step S117, all logic cells satisfying the glitch determination condition C are converted into one or a plurality of glitch suppression cells, and thereafter, in steps S118 and S120, it is confirmed whether or not a glitch occurs in an output of a C-element in a subsequent stage in the processing target path P. However, this is not limitative. Instead of this, all logic cells satisfying the glitch determination condition C may be selected one by one, and the selected one logic cell may be converted into one or a plurality of glitch suppression cells, and for every conversion, it may be confirmed whether or not a glitch occurs in an output of a C-element in a subsequent stage in the processing target path P. A circuit conversion method according to the present modification example is described in detail below.

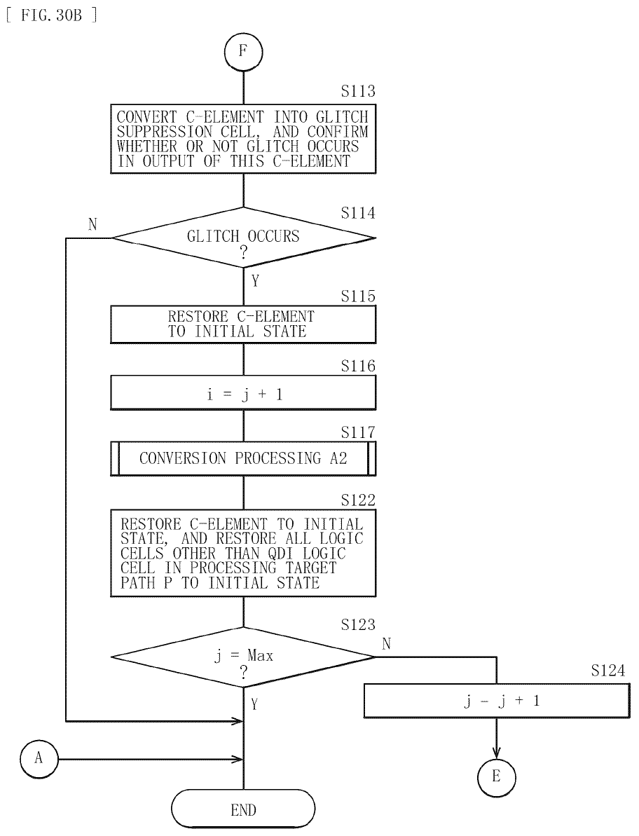

FIGS. 30A and 30B illustrate an example of the circuit conversion method according to the present modification example.

First, the computer identifies the processing target path P where circuit conversion is to be performed, and obtains the stage number M of logic cells in the processing target path P (step S101).

Next, the computer sets the variable i to “1” (i=1) (step S102), and performs conversion processing A2 (step S133). In this conversion processing A2, the computer sets all logic cells in i-th and subsequent stages in the processing target path P as processing targets. In this example, the variable i is set to “1” in step S102; therefore, the computer sets all logic cells in “1”st and subsequent stages in the processing target path P as processing targets of the conversion processing A2.

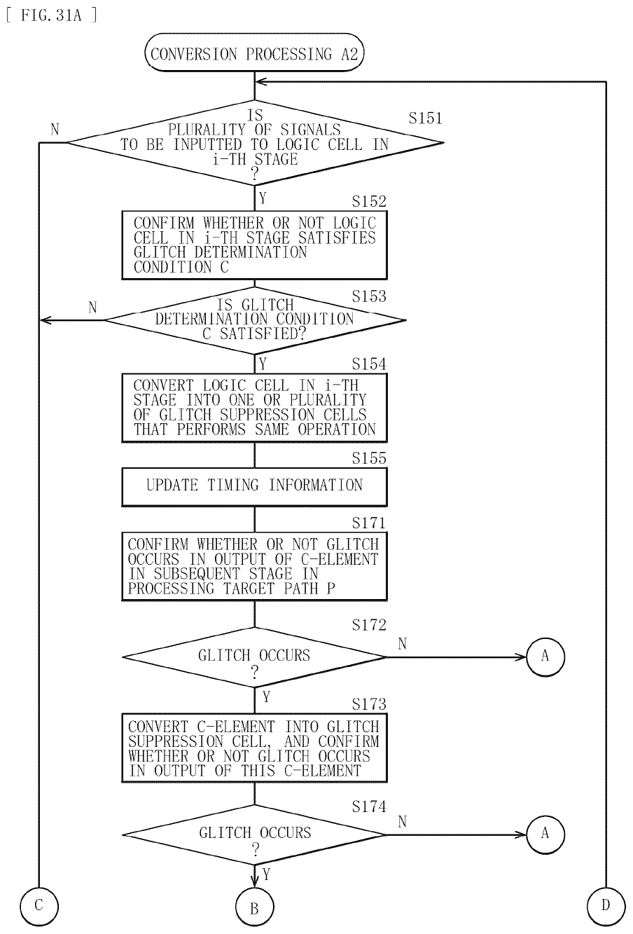

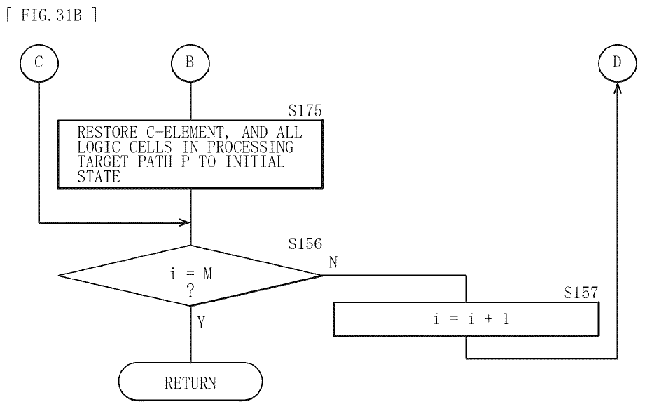

FIGS. 31A and 31B illustrate a subroutine of the conversion processing A2. In this conversion processing A2, the computer selects, one by one, all logic cells in which glitches possibly occurs out of all the logic cells in the i-th stage (the first stage in this example) and subsequent stages in the processing target path P, converts the selected one logic cell into one or a plurality of glitch suppression cells, and confirms whether or not a glitch occurs in an output of a C-element in a subsequent stage in the processing target path P. This operation is described in detail below.

The computer confirms whether or not a plurality of signals is to be inputted to the logic cell in the i-th stage in the processing target path P (step S151). In a case where one signal is to be inputted to the logic cell in the i-th stage (“N” in step S151), the processing proceeds to step S156.

In step S151, in a case where a plurality of signals is to be inputted to the logic cell in the i-th stage (step S151), the computer confirms whether or not the logic cell in the i-th stage satisfies the glitch determination condition C (step S152). In a case where this logic cell does not satisfy the glitch determination condition C (“N” in step S153), the computer determines that no glitch occurs in this logic cell, and the processing proceeds to step S156.

In a case where this logic cell satisfies the glitch determination condition C in step S152 (“Y” in step S153), the computer determines that a glitch possibly occurs in this logic cell, and converts this logic cell into one or a plurality of glitch suppression cells that performs the same operation (step S154). Thereafter, the computer updates the timing information in the design data (step S155).

Next, the computer confirms whether or not a glitch occurs in an output of a C-element in a subsequent stage in the processing target path P (step S171). In the example in FIG. 11, the computer confirms whether or not a glitch occurs in an output of a C-element in the control circuit 21H in a subsequent stage in the processing target path P. In a case where no glitch occurs (“N” in step S172), this processing ends.

In a case where a glitch occurs in step S171 (“Y” in step S172), the computer converts this C-element into a glitch suppression cell, and confirms whether or not a glitch occurs in an output of this C-element (step S173). In a case where no glitch occurs (“N” in step S174), this processing ends.

In a case where a glitch occurs in step S173 (“Y” in step S174), the computer restores the C-element converted in step S173, and all logic cells converted in step S154 in the processing target path P to the initial state (step S175). Thus, all the logic cells in the processing target path P are restored to the initial state.

Next, the computer confirms whether or not the variable i is equal to the stage number M (i=M) (step S156). In a case where the variable i is smaller than the stage number M (“N” in step S156), the computer increments the variable i (step S157), and the processing returns to step S151. Thus, one logic cell out of all the logic cells satisfying the glitch determination condition C is converted into one or a plurality of glitch suppression cells, and it is confirmed whether or not a glitch occurs in an output of a C-element in a subsequent stage in the processing target path P. Thereafter, this operation is repeated until no glitch occurs.

In a case where the variable i is equal to the stage number M in step S156 (“Y” in step S156), the computer ends the subroutine of the conversion processing A2.

In step S133, in a case where a glitch continuously occurs, the computer next sets the variable j to “1” (j=1) (step S109).

Next, the computer converts an input signal to the logic cell in the j-th stage in the processing target path P into a 2-wire signal, converts the logic cell in the j-th stage into a QDI logic cell, and converts an output signal of this QDI logic cell into a 1-wire signal (step S10).

Next, the computer confirms whether or not a glitch occurs in an output of a C-element in a subsequent stage in the processing target path P (step S111). In a case where no glitch occurs (“N” in step S112), this processing ends.

In a case where a glitch occurs in step S111 (“Y” in step S112), the computer converts this C-element into a glitch suppression cell, and confirms whether or not a glitch occurs in an output of this C-element (step S113). In a case where no glitch occurs (“N” in step S114), this processing ends.

In a case where a glitch occurs in step S113 (“Y” in step S114), the computer restores the C-element converted in step S113 to the initial state (step S115).

Next, the computer sets the variable i to “j+1” (i=j+1) (step S116), and performs the conversion processing A2 (step S137). In the conversion processing A2, as illustrated in FIGS. 31A and 31B, the computer converts one of all logic cells in which a glitch possibly occurs out of all logic cells in the i-th stage (the j+1-th stage in this example) and subsequent stages in the processing target path P into one or a plurality of glitch suppression cells, and confirms whether or not a glitch occurs in an output of a C-element in a subsequent stage in the processing target path P. Thereafter, this operation is repeated until no glitch occurs.

In step S137, in a case where a glitch continuously occurs, the computer next restores the C-element converted in step S120 to the initial state, and restores all logic cells other than the QDI logic cell in the processing target path P to the initial state (step S122).

Next, the computer confirms whether or not the variable j is equal to the stage number M (j=M) (step S123). In a case where the variable j is smaller than the stage number M (“N” in step S123), the computer increments the variable j (step S124), and the processing returns to step S110.

In a case where the variable j is equal to the stage number M in step S123 (“Y” in step S123), the computer ends this processing.

Thus, this flow ends.

### Modification Example 1-2

In the embodiment described above, as illustrated in FIG. 11, the port of the signal to be inputted from the combinational circuit 12 of the data-path circuit 10 to the handshake circuit 20 is identified, and a signal path from this port to the input terminal of the control circuit 21 in the handshake circuit 20 is identified as the processing target path P, but this is not limitative. Instead of this, for example, a longer signal path including this signal path may be identified as the processing target path P. Specifically, for example, in FIG. 11, a port of a signal to be inputted from the register 11E to the combinational circuit 12 is identified, and a signal path from this port to the input terminal of the control circuit 21H through a part of the combinational circuit 12, the inverters 37 and 38, and the AND circuits 43 and 47 may be identified as the processing target path P.

### Modification Example 1-3

In the embodiment described above, the circuit conversion method illustrated in FIGS. 12A to 12C and 13 is used, but the circuit conversion method is not limited thereto. For example, even in a case where it is not possible to completely suppress glitches, conversion processing may end without affecting the operation.

### Modification Example 1-4

In the embodiment described above, the glitch suppression cells illustrated in FIGS. 24 to 29 are examples, and the glitch suppression cell is not limited thereto. It is possible to use various glitch suppression cells that are configured to suppress glitches.

### Other Modification Examples

In addition, two or more of these modification examples may be combined.

### 2. Second Embodiment

Next, description is given of an asynchronous logic circuit 2 to which a circuit conversion method according to a second embodiment is applied. In the present embodiment, the circuit system itself of the asynchronous logic circuit is different from that of the asynchronous logic circuit according to the first embodiment. That is, in the first embodiment, the present technology is applied to what is called a bundled-data asynchronous logic circuit. Meanwhile, in the second embodiment, the present technology is applied to a 2-wire SDI (Scalable Delay Insensitive) circuit.

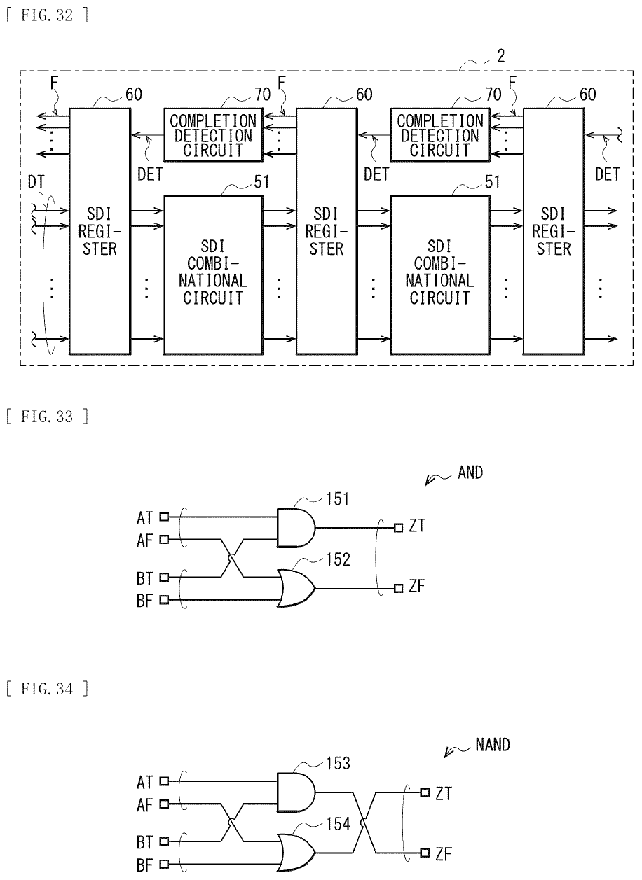

FIG. 32 illustrates a configuration example of the asynchronous logic circuit 2 to which the circuit conversion method according to the present embodiment is applied. The asynchronous logic circuit 2 is a 2-wire SDI circuit. The asynchronous logic circuit 2 illustrated in FIG. 32 is an example of a most basic configuration. In actuality, as described later, the asynchronous logic circuit 2 may be more complicated than this circuit configuration. The asynchronous logic circuit 2 includes a plurality of SDI combinational circuits 51, a plurality of SDI registers 60, and a plurality of completion detection circuits 70. In this example, the SDI registers 60, the SDI combinational circuit 51, and the completion detection circuits 70 are alternately disposed.

The SDI combinational circuit 51 is a 2-wire combinational circuit using a 2-wire SDI logic cell. The SDI combinational circuit 51 is configured to perform a logical operation on a piece of 2-wire data DT supplied from the SDI register 60 in a preceding stage and supply the obtained piece of 2-wire data DT to the SDI register 60 in a subsequent stage. A 2-wire signal includes two signals (signals ST and SF). The signals ST and SF possibly takes “0, 0”, “1, 0”, “0, 1”, and “0, 0”. The phase “0, 0” is also referred to as an idle phase, and is disposed before and after “1, 0” or “0, 1”. A 2-wire SDI logic cell is described below with reference to some examples.

FIG. 33 illustrates a configuration example of an SDI logic cell of a logical AND (AND) circuit. This circuit includes a 1-wire AND circuit 151 and a 1-wire OR circuit 152. Terminals A (terminals AT and AF) are supplied with a 2-wire signal, terminals B (terminals BT and BF) are supplied with a 2-wire signal, and terminals Z (ZT and ZF) outputs a 2-wire signal. The AND circuit 151 has a first input terminal coupled to the terminal AT, a second input terminal coupled to the terminal BT, and an output terminal coupled to the terminal ZT. The OR circuit 152 has a first input terminal coupled to the terminal AF, a second input terminal coupled to the terminal BF, and an output terminal coupled to the terminal ZF. For example, in a case where signals at the terminals AT and AF are “1, 0”, and signals at the terminals BT and BF are “1, 0”, signals at the terminals ZT and ZF become “1, 0”. In addition, for example, in a case where the signals at the terminals AT and AF are “1, 0”, and the signals at the terminals BT and BF are “0, 1”, the signals at the terminals ZT and ZF become “0, 1”. In addition, for example, in a case where the signals at the terminals AT and AF are “0, 1”, and the signals at the terminals BT and BF are “1, 0”, the signals at the terminals ZT and ZF become “0, 1”. In addition, for example, in a case where the signals at the terminals AT and AF are “0, 1”, and the signals at the terminals BT and BF are “0, 1”, the signals at the terminals ZT and ZF become “0, 1”. In addition, for example, in a case where the signals at the terminals AT and AF are “0, 0”, and the signals at the terminals BT and BF are “0, 0”, the signals at the terminals ZT and ZF become “0, 0”.

FIG. 34 illustrates a configuration example of an SDI logic cell of a negative AND (NAND) circuit. This circuit includes a 1-wire AND circuit 153 and a 1-wire OR circuit 154. The AND circuit 153 has a first input terminal coupled to the terminal AT, a second input terminal coupled to the terminal BT, and an output terminal coupled to the terminal ZF. The OR circuit 154 has a first input terminal coupled to the terminal AF, a second input terminal coupled to the terminal BF, and an output terminal coupled to the terminal ZT. For example, in a case where the signals at the terminals AT and AF are “1, 0”, and the signals at the terminals BT and BF are “1, 0”, the signals at the terminals ZT and ZF become “0, 1”. In addition, for example, in a case where the signals at the terminals AT and AF are “1, 0”, and the signals at the terminals BT and BF are “0, 1”, the signals at the terminals ZT and ZF become “1, 0”. In addition, for example, in a case where the signals at the terminals AT and AF are “0, 1”, and the signals at the terminals BT and BF are “1, 0”, the signals at the terminals ZT and ZF become “1, 0”. In addition, for example, in a case where the signals at the terminals AT and AF are “0, 1”, and the signals at the terminals BT and BF are “0, 1”, the signals at the terminals ZT and ZF become “1, 0”. In addition, for example, in a case where the signals at the terminals AT and AF are “0, 0”, and the signals at the terminals BT and BF are “0, 0”, the signals at the terminals ZT and ZF become “0, 0”.

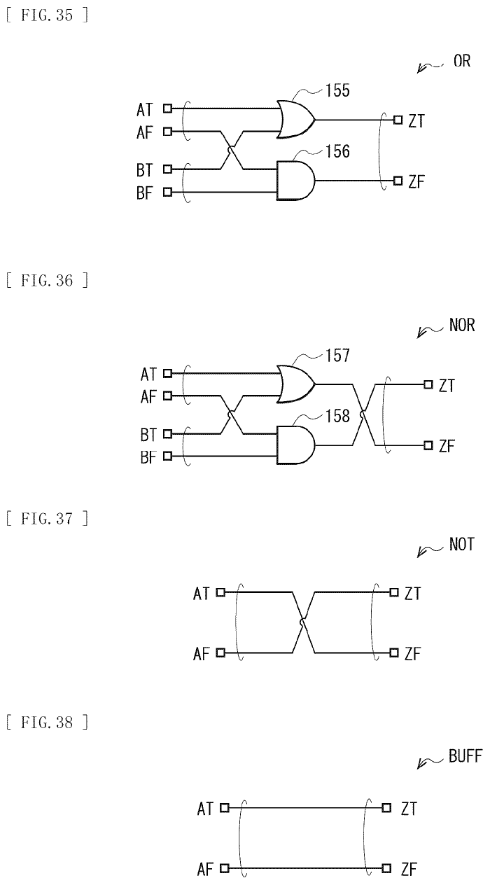

FIG. 35 illustrates a configuration example of an SDI logic cell of a logical OR (OR) circuit. This circuit includes a 1-wire OR circuit 155 and a 1-wire AND circuit 156. The OR circuit 155 has a first input terminal coupled to the terminal AT, a second input terminal coupled to the terminal BT, and an output terminal coupled to the terminal ZT. The AND circuit 156 has a first input terminal coupled to the terminal AF, a second input terminal coupled to the terminal BF, and an output terminal coupled to the terminal ZF. For example, in a case where the signals at the terminals AT and AF are “1, 0”, and the signals at the terminals BT and BF are “1, 0”, the signals at the terminals ZT and ZF become “1, 0”. In addition, for example, in a case where the signals at the terminals AT and AF are “1, 0”, and the signals at the terminals BT and BF are “0, 1”, the signals at the terminals ZT and ZF become “1, 0”. In addition, for example, in a case where the signals at the terminals AT and AF are “0, 1”, and the signals at the terminals BT and BF are “1, 0”, the signals at the terminals ZT and ZF become “1, 0”. In addition, for example, in a case where the signals at the terminals AT and AF are “0, 1”, and the signals at the terminals BT and BF are “0, 1”, the signals at the terminals ZT and ZF become “0, 1”. In addition, for example, in a case where the signals at the terminals AT and AF are “0, 0”, and the signals at the terminals BT and BF are “0, 0”, the signals at the terminals ZT and ZF become “0, 0”.

FIG. 36 illustrates a configuration example of an SDI logic cell of a negative OR (NOR) circuit. This circuit includes a 1-wire OR circuit 157 and a 1-wire AND circuit 158. The OR circuit 157 has a first input terminal coupled to the terminal AT, a second input terminal coupled to the terminal BT, and an output terminal coupled to the terminal ZF. The AND circuit 158 has a first input terminal coupled to the terminal AF, a second input terminal coupled to the terminal BF, and an output terminal coupled to the terminal ZT. For example, in a case where the signals at the terminals AT and AF are “1, 0”, and the signals at the terminals BT and BF are “1, 0”, the signals at the terminals ZT and ZF become “0, 1”. In addition, for example, in a case where the signals at the terminals AT and AF are “1, 0”, and the signals at the terminals BT and BF are “0, 1”, the signals at the terminals ZT and ZF become “0, 1”. In addition, for example, in a case where the signals at the terminals AT and AF are “0, 1”, and the signals at the terminals BT and BF are “1, 0”, the signals at the terminals ZT and ZF become “0, 1”. In addition, for example, in a case where the signals at the terminals AT and AF are “0, 1”, and the signals at the terminals BT and BF are “0, 1”, the signals at the terminals ZT and ZF become “1, 0”. In addition, for example, in a case where the signals at the terminals AT and AF are “0, 0”, and the signals at the terminals BT and BF are “0, 0”, the signals at the terminals ZT and ZF become “0, 0”.

FIG. 37 illustrates a configuration example of an SDI logic cell of a negative (NOT) circuit. In this circuit, the terminal AT is coupled to the terminal ZF, and the terminal AF is coupled to the terminal ZT. For example, in a case where the signals at the terminals AT and AF are “1, 0”, the signals at the terminals ZT and ZF become “0, 1”. In addition, for example, in a case where the signals at the terminals AT and AF are “0, 1”, the signals at the terminals ZT and ZF become “1, 0”. In addition, for example, in a case where the signals at the terminals AT and AF are “0, 0”, the signals at the terminals ZT and ZF become “0, 0”.

FIG. 38 illustrates a configuration example of an SDI logic cell of a buffer (BUFF) circuit. In this circuit, the terminal AT is coupled to the terminal ZT, and the terminal AF is coupled to the terminal ZF. For example, in a case where the signals at the terminals AT and AF are “1, 0”, the signals at the terminals ZT and ZF become “1, 0”. In addition, for example, in a case where the signals at the terminals AT and AF are “0, 1”, the signals at the terminals ZT and ZF become “0, 1”. In addition, for example, in a case where the signals at the terminals AT and AF are “0, 0”, the signals at the terminals ZT and ZF become “0, 0”.

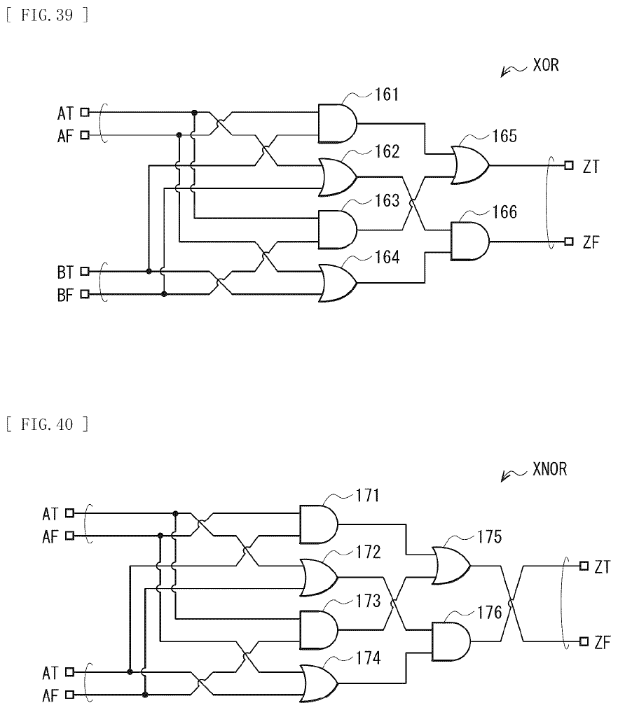

FIG. 39 illustrates a configuration example of an SDI logic cell of an exclusive-OR (XOR) circuit. This circuit includes 1-wire AND circuits 161, 163, and 166, and 1-wire OR circuits 162, 164, and 165. The AND circuit 161 has a first input terminal coupled to the terminal AF, a second input terminal coupled to the terminal BT, and an output terminal coupled to the OR circuit 165. The OR circuit 162 has a first input terminal coupled to the terminal AT, a second input terminal coupled to the terminal BF, and an output terminal coupled to the AND circuit 166. The AND circuit 163 has a first input terminal coupled to the terminal AT, a second input terminal coupled to the terminal BF, and an output terminal coupled to the OR circuit 165. The OR circuit 164 has a first input terminal coupled to the terminal AF, a second input terminal coupled to the terminal BT, and an output terminal coupled to the AND circuit 166. The OR circuit 165 has a first input terminal coupled to the output terminal of the AND circuit 161, a second input terminal coupled to the output terminal of the AND circuit 163, and an output terminal coupled to the terminal ZT. The AND circuit 166 has a first input terminal coupled to the output terminal of the OR circuit 162, a second input terminal coupled to the output terminal of the OR circuit 164, and an output terminal coupled to the terminal ZF. For example, in a case where the signals at the terminals AT and AF are “1, 0”, and the signals at the terminals BT and BF are “1, 0”, the signals at the terminals ZT and ZF become “0, 1”. In addition, for example, in a case where the signals at the terminals AT and AF are “1, 0”, and the signals at the terminals BT and BF are “0, 1”, the signals at the terminals ZT and ZF become “0, 1”. In addition, for example, in a case where the signals at the terminals AT and AF are “0, 1”, and the signals at the terminals BT and BF are “1, 0”, the signals at the terminals ZT and ZF become “1, 0”. In addition, for example, in a case where the signals at the terminals AT and AF are “0, 1”, and the signals at the terminals BT and BF are “0, 1”, the signals at the terminals ZT and ZF become “0, 1”. In addition, for example, in a case where the signals at the terminals AT and AF are “0, 0”, and the signals at the terminals BT and BF are “0, 0”, the signals at the terminals ZT and ZF become “0, 0”.

FIG. 40 illustrates a configuration example of an exclusive-NOR (XNOR) circuit. This circuit include 1-wire AND circuits 171, 173, and 17, and 1-wire OR circuits 172, 174, and 175. The AND circuit 171 has a first input terminal coupled to the terminal AF, a second input terminal coupled to the terminal BT, and an output terminal coupled to the OR circuit 175. The OR circuit 172 has a first input terminal coupled to the terminal AT, a second input terminal coupled to the terminal BF, and an output terminal coupled to the AND circuit 176. The AND circuit 173 has a first input terminal coupled to the terminal AT, a second input terminal coupled to the terminal BF, and an output terminal coupled to the OR circuit 175. The OR circuit 174 has a first input terminal coupled to the terminal AF, a second input terminal coupled to the terminal BT, and an output terminal coupled to the AND circuit 176. The OR circuit 175 has a first input terminal coupled to the output terminal of the AND circuit 171, a second input terminal coupled to the output terminal of the AND circuit 173, and an output terminal coupled to the terminal ZF. The AND circuit 176 has a first input terminal coupled to the output terminal of the OR circuit 172, a second input terminal coupled to the output terminal of the OR circuit 174, and an output terminal coupled to the terminal ZT. For example, in a case where the signals at the terminals AT and AF are “1, 0”, and the signals at the terminals BT and BF are “1, 0”, the signals at the terminals ZT and ZF become “1, 0”. In addition, for example, in a case where the signals at the terminals AT and AF are “1, 0”, and the signals at the terminals BT and BF are “0, 1”, the signals at the terminals ZT and ZF become “0, 1”. In addition, for example, in a case where the signals at the terminals AT and AF are “0, 1”, and the signals at the terminals BT and BF are “1, 0”, the signals at the terminals ZT and ZF become “0, 1”. In addition, for example, in a case where the signals at the terminals AT and AF are “0, 1”, and the signals at the terminals BT and BF are “0, 1”, the signals at the terminals ZT and ZF become “1, 0”. In addition, for example, in a case where the signals at the terminals AT and AF are “0, 0”, and the signals at the terminals BT and BF are “0, 0”, the signals at the terminals ZT and ZF become “0, 0”.

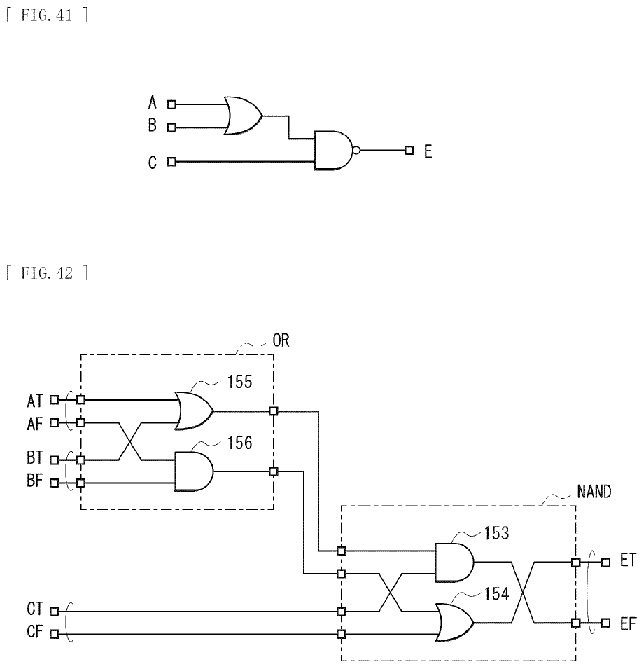

It is possible to convert, for example, a 1-wire logic circuit illustrated in FIG. 41 into, for example, a 2-wire logic circuit illustrated in FIG. 42 by using a 2-wire SDI circuit. The logic circuit illustrated in FIG. 41 includes an OR circuit and a NAND circuit. This OR circuit is converted into a 2-wire OR circuit illustrated in FIG. 35, and the NAND circuit is converted into a 2-wire NAND circuit illustrated in FIG. 34, thereby making it possible to obtain the 2-wire logic circuit illustrated in FIG. 42.

The SDI register 60 includes, for example, a plurality of SDI latch circuits 61 (to be described later), and is configured to latch a piece of data DT supplied from the combinational circuit 12 in a preceding stage. In addition, the SDI register 60 also has a function of generating a plurality of flag signals F and supplying the plurality of flag signals F to the completion detection circuit 70. The plurality of flag signals F each indicates whether or not a signal latched by each of the plurality of SDI latch circuits 61 is in the idle phase.

The completion detection circuit 70 is configured to generate a detection signal DET by detecting whether or not all signals latched by the plurality of SDI latch circuits 61 are in the idle phase, on the basis of the plurality of flag signals F supplied from the SDI register 60.

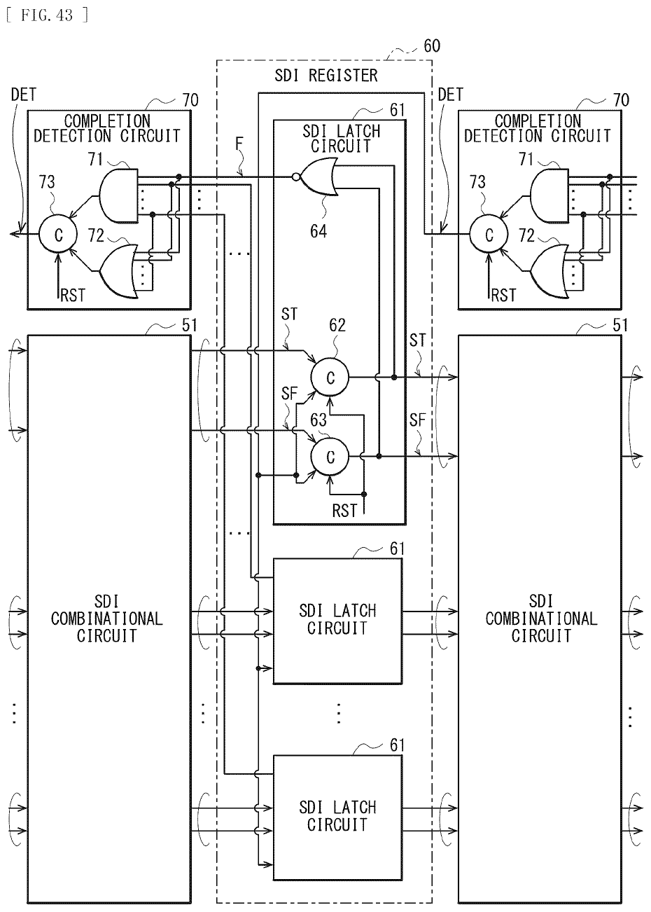

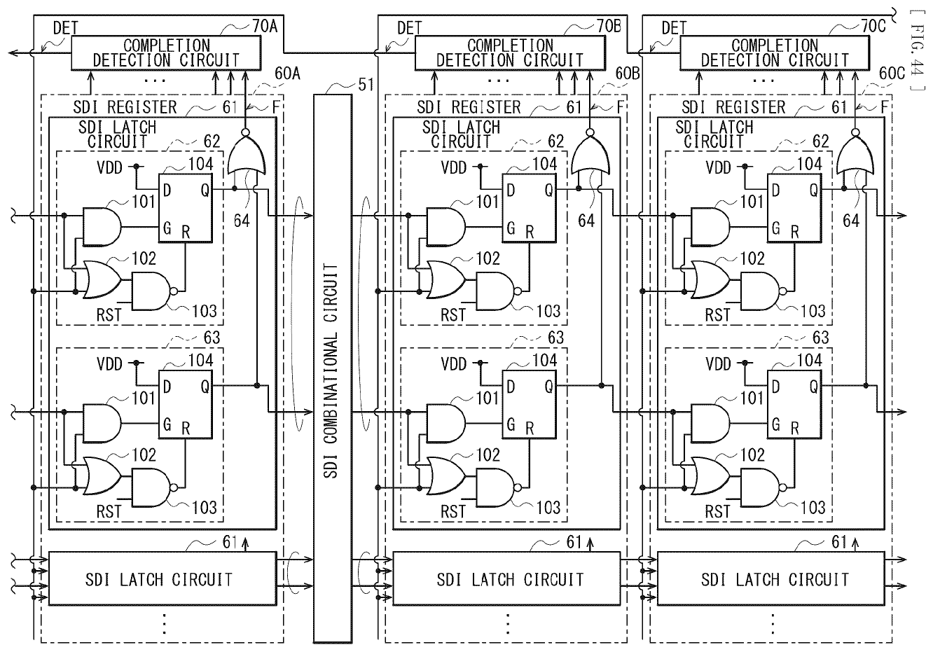

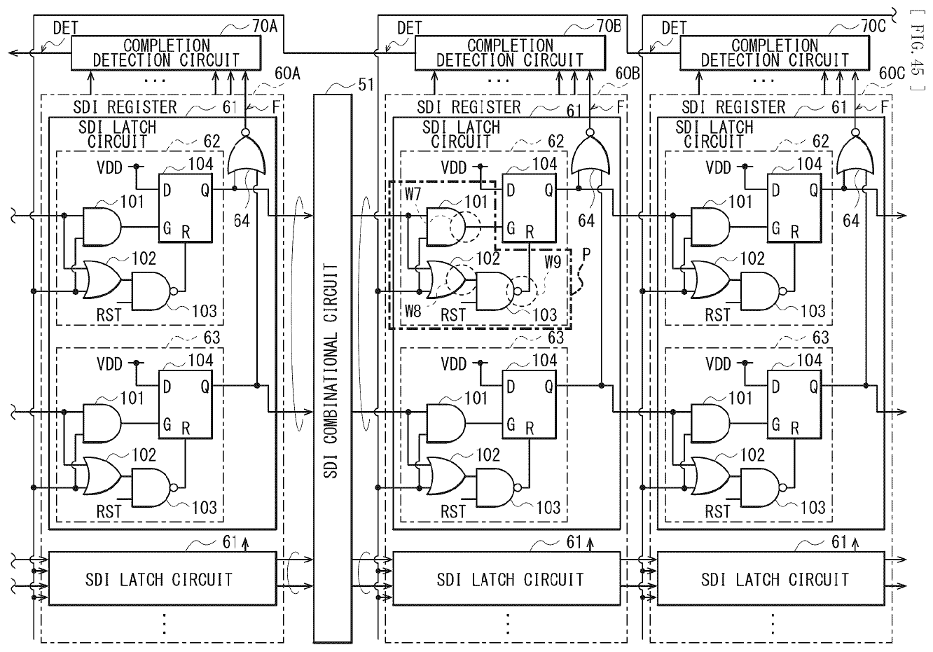

FIG. 43 illustrates a configuration example of the SDI register 60 and the completion detection circuit 70.

The SDI register 60 includes the plurality of SDI latch circuits 61. Each of the plurality of SDI latch circuits 61 includes C-elements 62 and 63 and a NOR circuit 64.

The C-element 62 has two input terminals, a reset terminal, and an output terminal. The signal ST of a 2-wire signal included in the piece of data DT supplied from the SDI combinational circuit in a preceding stage, and the detection signal DET supplied from the completion detection circuit 70 are inputted to the two input terminals. The reset signal RST is inputted to the reset terminal. The C-element 62 changes the signal ST at the output terminal to the high level in a case where both the signal ST and the detection signal DET are at the high level, changes the signal ST at the output terminal to the low level in a case where both the signal ST and the detection signal DET are at the low level, and maintains the signal ST at the output terminal in other cases. In addition, the C-element 62 changes the signal ST at the output terminal to the low level on the basis of the reset signal RST.

The C-element 63 has two input terminals, a reset terminal, and an output terminal. The signal SF of the 2-wire signal included in the piece of data DT supplied from the SDI combinational circuit in the preceding stage, and the detection signal DET supplied from the completion detection circuit 70 are inputted to the two input terminals. The reset signal RST is inputted to the reset terminal. The C-element 63 changes the signal SF at the output terminal to the high level in a case where both the signal SF and the detection signal DET are at the high level, changes the signal SF at the output terminal to the low level in a case where both the signal SF and the detection signal DET are at the low level, and maintains the signal SF at the output terminal in other cases. In addition, the C-element 63 changes the signal SF at the output terminal to the low level on the basis of the reset signal RST.

The NOR circuit 64 is configured to find NOR of the signal ST generated by the C-element 62 and the signal SF generated by the C-element 63 and output a thus-obtained result as the flag signal F. The NOR circuit 64 changes the flag signal F to the high level in a case where the signals ST and SF are “0, 0”.

The completion detection circuit 70 includes an AND circuit 71, an OR circuit 72, and a C-element 73. The AND circuit 71 is configured to find AND of the plurality of flag signals F supplied from the plurality of SDI latch circuits 61 in the SDI register 60. The OR circuit 72 is configured to find OR of the plurality of flag signals F supplied from the plurality of SDI latch circuits 61 in the SDI register 60. The C-element 73 has two input terminals, a reset terminal, and an output terminal. An output signal of the AND circuit 71 and an output signal of the OR circuit 72 are inputted to the two input terminals. The reset signal RST is inputted to the reset terminal. The C-element 73 changes the detection signal DET at the output terminal to the high level in a case where both the output signal of the AND circuit 71 and the output signal of the OR circuit 72 are at the high level, changes the detection signal DET at the output terminal to the low level in a case where both the output signal of the AND circuit 71 and the output signal of the OR circuit 72 are at the low level, and maintains the detection signal DET at the output terminal in other cases. In addition, the C-element 63 changes the detection signal DET at the output terminal to the low level on the basis of the reset signal RST. With this configuration, the completion detection circuit 70 changes the detection signal DET to the high level in a case where all the plurality of flag signals F is changed to the high level, and changes the detection signal DET to the low level in a case where all the plurality of flag signals F is changed to the low level. In other words, the completion detection circuit 70 changes the detection signal DET to the high level in a case where all signals latched by the plurality of SDI latch circuits 61 are in the idle phase.

FIG. 44 illustrates a configuration example of the asynchronous logic circuit 2. It is to be noted that this diagram illustrates each of the C-elements 62 and 63 using a circuit illustrated in FIG. 4. In this example, the SDI register 60 (an SDI register 60B) is provided in a stage subsequent to the SDI combinational circuit 51, and another SDI register 60 (an SDI register 60C) is provided in a stage subsequent to the SDI register 60B. That is, in this example, the SDI combinational circuit 51 is not provided between the SDI register 60B and the SDI register 60C, and the SDI register 60B and the SDI register 60C are directly coupled to each other. In addition, the SDI register 60C supplies a plurality of flag signals F to the completion detection circuit 70 (a completion detection circuit 70C), and the completion detection circuit 70C generates the detection signal DET on the basis of the plurality of flag signals F, and supplies the generated detection signal DET to the SDI register 60B. That is, the completion detection circuit 70C does not supply the detection signal DET to the SDI register 60C, but supplies the detection signal DET to the SDI register 60B. Likewise, the SDI register 60B supplies a plurality of flag signals F to the completion detection circuit 70 (a completion detection circuit 70B), and the completion detection circuit 70B generates the detection signal DET on the basis of the plurality of flag signals F, and supplies the generated detection signal DET to the SDI register 60 (a SDI register 60A) in a stage preceding to the SDI combinational circuit 51. The SDI register 60A supplies a plurality of flag signals F to the completion detection circuit 70 (a completion detection circuit 70A), and the completion detection circuit 70A generates the detection signal DET on the basis of the plurality of flag signals F.

Incidentally, in recent years, a semiconductor process size has been further reduced, and a power supply voltage has been further lowered. In such a situation, glitches easily occur. In the asynchronous logic circuit 2, using a 2-wire SDI circuit as illustrated in FIGS. 33 to 40 makes it possible to hinder glitches from occurring. However, when the semiconductor process size is further reduced and the power supply voltage is further lowered as described above, the variation tendency of a delay amount in a logic cell may become more complicated. For example, variations in delay amounts of a plurality of logic cells provided in one signal path in one semiconductor chip may vary differently from each other. Accordingly, even in a case where the SDI circuit as illustrated in FIGS. 33 to 40 is used, glitches may occur.

FIG. 45 illustrates an example of occurrence of glitches. This example focuses on a path (the processing target path P) including the AND circuit 101, the OR circuit 102, and the NAND circuit 103 of one SDI latch circuit 61 in the SDI register 60B. For example, in a case where, the delay amount of the SDI combinational circuit 51 is increased and the delay amounts of the SDI register 60C and the completion detection circuit 70C in a subsequent stage are decreased due to variations in delay amount, there is a possibility that glitches occur in an output signal (a reference sign W7) of the AND circuit 101, an output signal (a reference sign W8) of the OR circuit 102, and an output signal (a reference sign W9) of the NAND circuit 103. In this case, there is a possibility that the latch circuit 104 malfunctions, and as a result, there is a possibility that the SDI latch circuit 61 in the SDI register 60C that is a subsequent-stage circuit also malfunctions.

In a case where the glitches occur as described above, a circuit malfunction easily occurs. In addition, in a case where glitches occur, power consumption is increased by switching. Accordingly, it is desirable to suppress glitches.

A circuit conversion method that implements the asynchronous logic circuit 2 in which glitches are suppressed is described in detail below. In this circuit conversion method, a computer executes a program to thereby convert a circuit on the basis of design data of the asynchronous logic circuit 2 so as to hinder glitches from occurring.

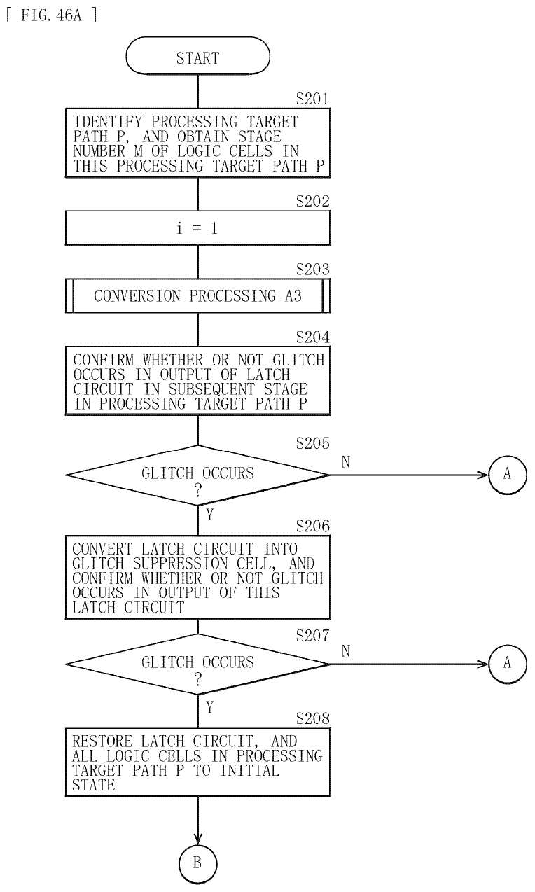

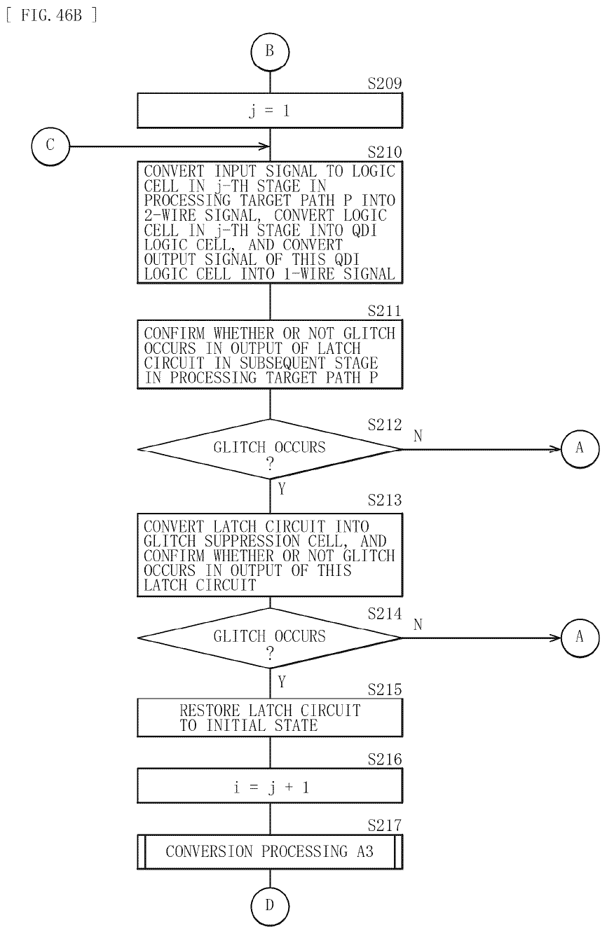

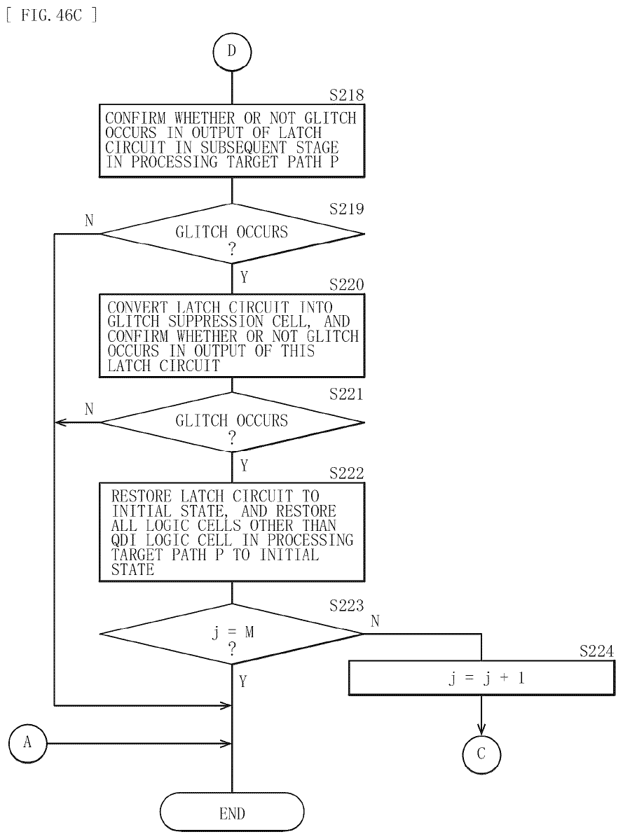

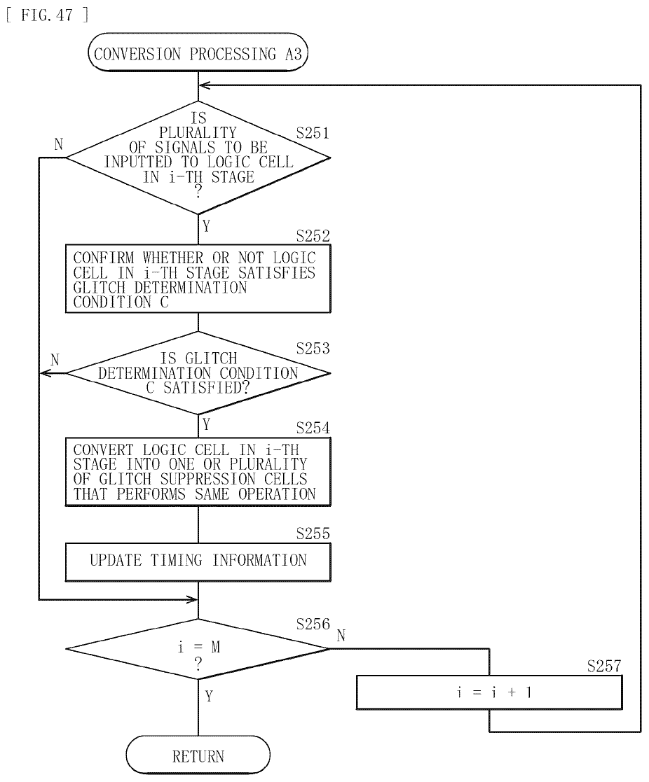

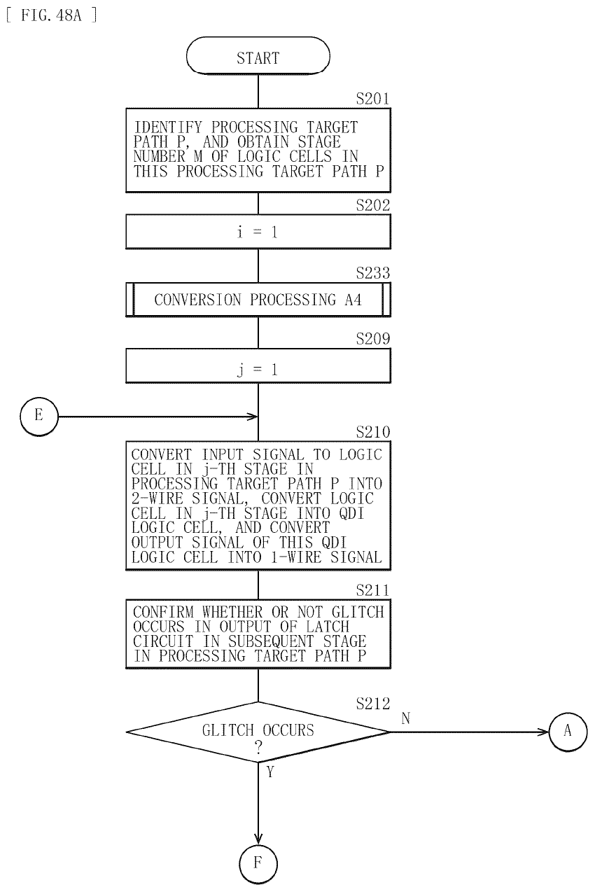

FIGS. 46A to 46C illustrate an example of the circuit conversion method by the computer.

First, the computer identifies the processing target path P where circuit conversion is to be performed, and obtains the stage number M of logic cells in the processing target path P (step S201). In the design data of the asynchronous logic circuit 2, the SDI combinational circuit 51, the SDI register 60, and the completion detection circuit 70 are defined as modules different from each other. The computer is able to identify a port of a signal to be inputted from the completion detection circuit 70 to the SDI register 60, on the basis of such design data, and is able to identify a signal path from this port to the input terminal of the latch circuit 104 in the SDI register 60. The computer identifies such a signal path as the processing target path P. In the example in FIG. 45, the computer identifies a path including the AND circuit 101, the OR circuit 102, and the NAND circuit 103 as the processing target path P. Thereafter, the computer obtains the stage number (stage number M) of logic cells in this processing target path P.

Next, the computer sets the variable i to “1” (i=1) (step S202), and performs conversion processing A3 (step S203). In this conversion processing A3, the computer sets all logic cells in i-th and subsequent stages in the processing target path P as processing targets. In this example, the variable i is set to “1” in step S102; therefore, the computer sets all logic cells in “1”st and subsequent stages in the processing target path P as processing targets of the conversion processing A3.

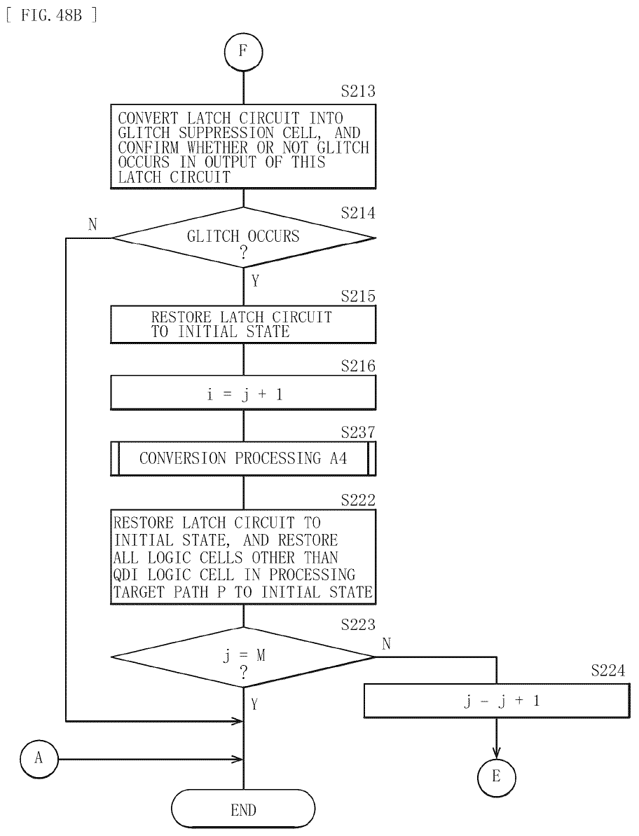

FIG. 47 illustrate an example of a subroutine of the conversion processing A3. In this conversion processing A3, the computer converts each of all logic cells in which glitches possibly occurs out of all the logic cells in the i-th stage (the first stage in this example) and subsequent stages in the processing target path P into one or a plurality of glitch suppression cells. This operation is described in detail below.

The computer confirms whether or not a plurality of signals is to be inputted to the logic cell in the i-th stage in the processing target path P (step S251). In a case where one signal is to be inputted to the logic cell in the i-th stage (“N” in step S251), the processing proceeds to step S256.

In step S251, in a case where a plurality of signals is inputted to the logic cell in the i-th stage (step S251), the computer confirms whether or not the logic cell in the i-th stage satisfies the glitch determination condition C (step S252). The glitch determination condition C is a condition for determining whether or not a glitch possibly occurs in the logic cell. Specifically, the glitch determination condition C is that a delay amount in the logic cell is less than or equal to a time difference between transition timings of the plurality of signals to be inputted. In a case where this logic cell does not satisfy the glitch determination condition C (“N” in step S253), the computer determines that no glitch occurs in this logic cell, and the processing proceeds to step S256.

In a case where this logic cell satisfies the glitch determination condition C in step S252 (“Y” in step S253), the computer determines that a glitch possibly occurs in this logic cell, and converts this logic cell into one or a plurality of glitch suppression cells (step S254).

Thereafter, the computer updates timing information in the design data (step S255). That is, the computer has converted the logic cell into one or a plurality of glitch suppression cells in step S254; therefore, the delay amount in this logic cell has been changed. Accordingly, the computer updates the timing information in the design data.

Next, the computer confirms whether or not the variable i is equal to the stage number M (i=M) (step S256). In a case where the variable i is smaller than the stage number M (“N” in step S256), the computer increments the variable i (step S257), and the processing returns to step S251. The computer repeats processing in steps S251 to S257 until the variable i becomes equal to the stage number M. Thus, out of all logic cells in the first and subsequent stages in the processing target path P, each of all logic cells in which glitches possibly occurs is converted into one or a plurality of glitch suppression cells.

In a case where the variable i is equal to the stage number M in step S256 (“Y” in step S256), the computer ends the subroutine of the conversion processing A3.

Next, the computer confirms whether or not a glitch occurs in an output of a latch circuit in a subsequent stage in the processing target path P (step S204). In the example in FIG. 45, the computer confirms whether or not a glitch occurs in an output of the latch circuit 104 in a subsequent stage in the processing target path P. In a case where no glitch occurs (“N” in step S205), this processing ends.

In a case where a glitch occurs in step S204 (“Y” in step S205), the computer converts this latch circuit into a glitch suppression cell, and confirms whether or not a glitch occurs in an output of this latch circuit (step S206). In a case where no glitch occurs (“N” in step S207), this processing ends.

In a case where a glitch occurs in step S206 (“Y” in step S207), the computer restores the latch circuit converted in step S206, and all logic cells converted in step S203 in the processing target path P to the initial state (step S208).

Next, the computer sets the variable j to “1” (j=1) (step S209).

Next, the computer converts an input signal to the logic cell in the j-th stage in the processing target path P into a 2-wire signal, converts the logic cell in the j-th stage into a QDI logic cell, and converts an output signal of this QDI logic cell into a 1-wire signal (step S210). This causes the output signal of this QDI logic cell to be inputted to the logic cell in a stage subsequent to the QDI logic cell (in the j+1-th stage). It is to be noted that in a case where the logic cell in a stage (the j−1-th stage) preceding to the logic cell in the j-th stage is a QDI logic cell, a 2-wire signal outputted from the logic cell in the j−1-th stage is supplied as it is to the logic cell in the j-th stage.

Next, the computer confirms whether or not a glitch occurs in an output of a latch circuit in a subsequent stage in the processing target path P (step S211). In a case where no glitch occurs (“N” in step S212), this processing ends.

In a case where a glitch occurs in step S211 (“Y” in step S212), the computer converts this latch circuit into a glitch suppression cell, and confirms whether or not a glitch occurs in an output of this latch circuit (step S213). In a case where no glitch occurs (“N” in step S214), this processing ends.

In a case where a glitch occurs in step S213 (“Y” in step S214), the computer restores the latch circuit converted in step S213 to the initial state (step S215).

Next, the computer sets the variable i to “j+1” (i=j+1) (step S216), and performs the conversion processing A3 (step S217). In the conversion processing A3, as illustrated in FIG. 47, the computer converts each of all logic cells in which a glitch possibly occurs out of all logic cells in the i-th stage (the j+1-th stage in this example) and subsequent stages in the processing target path P into one or a plurality of glitch suppression cells.

Next, the computer confirms whether or not a glitch occurs in an output of a latch circuit in a subsequent stage in the processing target path P (step S218). In a case where no glitch occurs (“N” in step S219), this processing ends.

In a case where a glitch occurs in step S218 (“Y” in step S219), the computer converts this latch circuit into a glitch suppression cell, and confirms whether or not a glitch occurs in an output of this latch circuit (step S220). In a case where no glitch occurs (“N” in step S221), this processing ends.

In a case where a glitch occurs in step S220 (“Y” in step S221), the computer restores the latch circuit converted in step S220 to the initial state, and restores all logic cells other than the QDI logic cell in the processing target path P to the initial state (step S222). Thus, all the logic cells converted in step S217 in the processing target path P are restored to the initial state.

Next, the computer confirms whether or not the variable j is equal to the stage number M (j=M) (step S223). In a case where the variable j is smaller than the stage number M (“N” in step S223), the computer increments the variable j (step S224), and the processing returns to step S110. Thus, the computer converts the logic cell in the j+1-th stage into a QDI logic cell in step S210. By this operation, the computer converts logic cells into QDI logic cells in order from the logic cell in the first stage, and the number of QDI logic cells is increased by one. The computer repeats operations in steps S210 to S224 until no glitch occurs.

In a case where the variable j is equal to the stage number M in step S223 (“Y” in step S223), the computer ends this processing.

Thus, this flow ends.

Using this circuit conversion method makes it possible to suppress glitches in one or more of the AND circuit 101 (the reference sign W7), the OR circuit 102 (the reference sign W8), the NAND circuit 103 in the processing target path P illustrated in FIG. 45, for example, and the latch circuit in the subsequent stage in the processing target path P. In this circuit conversion method, in the asynchronous logic circuit 2, various processing target paths P are set, and processing is performed on each of these processing target paths P. As a result, in the asynchronous logic circuit 2, it is possible to suppress glitches.

As described above, in the circuit conversion method, for example, as illustrated in step S201, the computer sets the processing target path P in the asynchronous logic circuit 2. Thereafter, as illustrated in step S252 of the conversion processing A3 in step S203, for example, the computer performs first processing for determining whether or not a glitch occurs in each of a plurality of logic cells in the processing target path P. Thereafter, for example, as illustrated in steps S253 and S254 of the conversion processing A3 in step S203, the computer performs second processing including conversion processing for converting one or more logic cells in which a glitch is determined to occur in the first processing into one or more glitch suppression logic cells. The one or more glitch suppression logic cells are configured to suppress glitches, and performs the same logical operation as the one or more logic cells. Thereafter, as illustrated in steps S204 to S207, after this second processing, the computer performs third processing for determining whether or not a glitch occurs in a latch circuit that is a subsequent-stage circuit in the processing target path P. Accordingly, in this circuit conversion method, it is possible to convert a logic cell in which a glitch is determined to occur into a glitch suppression logic cell, which makes it possible to suppress glitches.

Thereafter, in this circuit conversion method, for example, as illustrated in step S208, in a case where a glitch is determined as occurring in the third processing, the computer performs fourth processing for changing the plurality of logic cells in the processing target path P to the initial state. Thereafter, for example, as illustrated in step S210, after this fourth processing, the computer performs fifth processing for sequentially selecting one of the plurality of logic cells in the processing target path P and converting the selected logic cell into a QDI logic cell. Thereafter, for example, as illustrated in steps S211 to S214, the computer performs sixth processing for determining whether or not a glitch occur in a latch circuit that is a subsequent-stage circuit every time one of the plurality of logic cells is selected in the fifth processing. Accordingly, in this circuit conversion method, it is possible to effectively suppress glitches while reducing a circuit area.

As described above, in the present embodiment, the computer sets the processing target path in the asynchronous logic circuit. Thereafter, the computer performs the first processing for determining whether or not a glitch occurs in each of the plurality of logic cells in the processing target path. Thereafter, the computer performs the second processing including the conversion processing for converting one or more logic cells in which a glitch is determined to occur in the first processing into one or more glitch suppression logic cells. The one or more glitch suppression logic cells are configured to suppress glitches, and perform the same logical operation as the one or more logic cells. Thereafter, after this second processing, the computer performs the third processing for determining whether or not a glitch occurs in a latch circuit that is a subsequent-stage circuit in the processing target path. Thus, it is possible to suppress glitches.

### Modification Example 2-1

In the embodiment described above, as illustrated in FIGS. 46A to 46C and 13, in step S103, all logic cells satisfying the glitch determination condition C are converted into one or a plurality of glitch suppression cells, and thereafter, in steps S204 and S206, it is confirmed whether or not a glitch occurs in an output of a latch circuit in a subsequent stage in the processing target path P. Likewise, in step S117, all logic cells satisfying the glitch determination condition C are converted into one or a plurality of glitch suppression cells, and thereafter, in steps S218 and S220, it is confirmed whether or not a glitch occurs in an output of a latch circuit in a subsequent stage in the processing target path P. However, this is not limitative. Instead of this, all logic cells satisfying the glitch determination condition C may be selected one by one, and the selected one logic cell may be converted into one or a plurality of glitch suppression cells, and for every conversion, it may be confirmed whether or not a glitch occurs in an output of a latch circuit in a subsequent stage in the processing target path P. A circuit conversion method according to the present modification example is described in detail below.

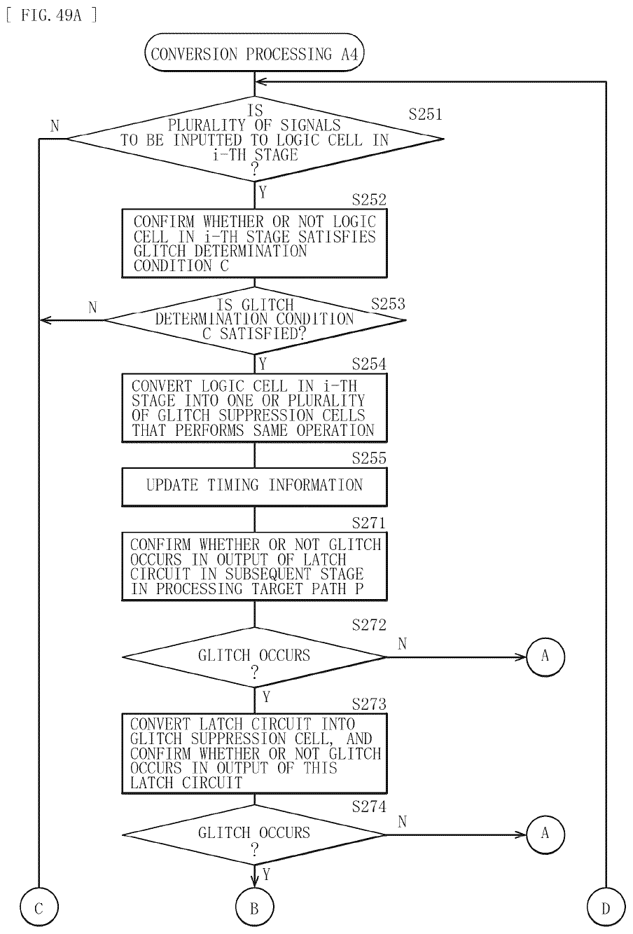

FIGS. 48A and 48B illustrate an example of the circuit conversion method according to the present modification example.

First, the computer identifies the processing target path P where circuit conversion is to be performed, and obtains the stage number M of logic cells in the processing target path P (step S201).

Next, the computer sets the variable i to “1” (i=1) (step S202), and performs conversion processing A4 (step S233). In this conversion processing A4, the computer sets all logic cells in i-th and subsequent stages in the processing target path P as processing targets. In this example, the variable i is set to “1” in step S102; therefore, the computer sets all logic cells in “1”st and subsequent stages in the processing target path P as processing targets of the conversion processing A4.

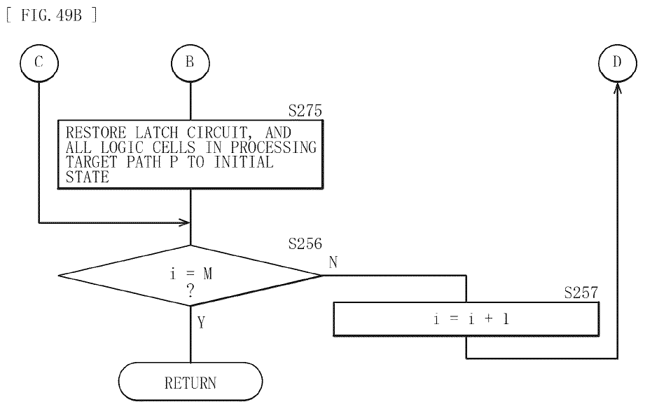

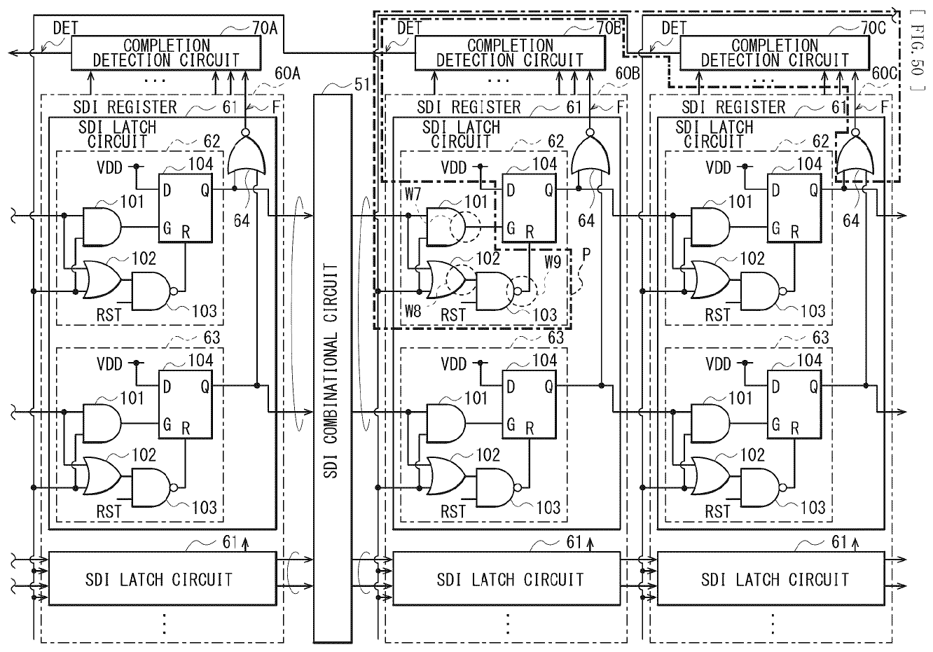

FIGS. 49A and 49B illustrate a subroutine of the conversion processing A4. In this conversion processing A3, the computer selects, one by one, all logic cells in which glitches possibly occurs out of all the logic cells in the i-th stage (the first stage in this example) and subsequent stages in the processing target path P, converts the selected one logic cell into one or a plurality of glitch suppression cells, and confirms whether or not a glitch occurs in an output of a latch circuit in a subsequent stage in the processing target path P. This operation is described in detail below.

The computer confirms whether or not a plurality of signals is to be inputted to the logic cell in the i-th stage in the processing target path P (step S251). In a case where one signal is to be inputted to the logic cell in the i-th stage (“N” in step S251), the processing proceeds to step S256.

In step S251, in a case where a plurality of signals is to be inputted to the logic cell in the i-th stage (step S251), the computer confirms whether or not the logic cell in the i-th stage satisfies the glitch determination condition C (step S252). In a case where this logic cell does not satisfy the glitch determination condition C (“N” in step S253), the computer determines that no glitch occurs in this logic cell, and the processing proceeds to step S256.

In a case where this logic cell satisfies the glitch determination condition C in step S252 (“Y” in step S253), the computer determines that a glitch possibly occurs in this logic cell, and converts this logic cell into one or a plurality of glitch suppression cells that performs the same operation (step S254). Thereafter, the computer updates the timing information in the design data (step S255).

Next, the computer confirms whether or not a glitch occurs in an output of a latch circuit in a subsequent stage in the processing target path P (step S271). In the example in FIG. 45, the computer confirms whether or not a glitch occurs in an output of the latch circuit 104 in a subsequent stage in the processing target path P. In a case where no glitch occurs (“N” in step S272), this processing ends.

In a case where a glitch occurs in step S271 (“Y” in step S272), the computer convert this latch circuit into a glitch suppression cell, and confirms whether or not a glitch occurs in an output of this latch circuit (step S273). In a case where no glitch occurs (“N” in step S274), this processing ends.

In a case where a glitch occurs in step S273 (“Y” in step S274), the computer restores the latch circuit converted in step S273, and all logic cells converted in step S254 in the processing target path P to the initial state (step S275). Thus, all the logic cells in the processing target path P are restored to the initial state.

Next, the computer confirms whether or not the variable i is equal to the stage number M (i=M) (step S256). In a case where the variable i is smaller than the stage number M (“N” in step S256), the computer increments the variable i (step S257), and the processing returns to step S251. Thus, one logic cell of all the logic cells satisfying the glitch determination condition C is converted into one or a plurality of glitch suppression cells, and it is confirmed whether a glitch occurs in an output of a latch circuit in a subsequent stage in the processing target path P. Thereafter, this operation is repeated until no glitch occurs.

In a case where the variable i is equal to the stage number M in step S256 (“Y” in step S256), the computer ends the subroutine of the conversion processing A4.

In step S233, in a case where glitches continuously occur, the computer next sets the variable j to “1” (j=1) (step S209).

Next, the computer converts an input signal to the logic cell in the j-th stage in the processing target path P into a 2-wire signal, converts the logic cell in the j-th stage into a QDI logic cell, and converts an output signal of this QDI logic cell into a 1-wire signal (step S210).

Next, the computer confirms whether or not a glitch occurs in an output of a latch circuit in a subsequent stage in the processing target path P (step S211). In a case where no glitch occurs (“N” in step S212), this processing ends.

In a case where a glitch occurs in step S211 (“Y” in step S212), the computer converts this latch circuit into a glitch suppression cell, and confirms whether or not a glitch occurs in an output of this latch circuit (step S213). In a case where no glitch occurs (“N” in step S214), this processing ends.

In a case where a glitch occurs in step S213 (“Y” in step S214), the computer restores the latch circuit converted in step S213 to the initial state (step S215).

Next, the computer sets the variable i to “j+1” (i=j+1) (step S216), and performs the conversion processing A4 (step S237). In the conversion processing A4, as illustrated in FIGS. 49A and 49B, the computer converts one of all logic cells in which a glitch possibly occurs out of all logic cells in the i-th stage (the j+1-th stage in this example) and subsequent stages in the processing target path P into one or a plurality of glitch suppression cells, and confirms whether or not a glitch occurs in an output of a latch circuit in a subsequent stage in the processing target path P. Thereafter, this operation is repeated until no glitch occurs.

In step S237, in a case where a glitch continuously occurs, the computer next restores the latch circuit converted in step S273 to the initial state, and restores all logic cells other than the QDI logic cell in the processing target path P to the initial state (step S222).

Next, the computer confirms whether or not the variable j is equal to the stage number M (j=M) (step S223). In a case where the variable j is smaller than the stage number M (“N” in step S223), the computer increments the variable j (step S224), and the processing returns to step S210.

In a case where the variable j is equal to the stage number M in step S223 (“Y” in step S223), the computer ends this processing.

Thus, this flow ends.

### Modification Example 2-2

In the embodiment described above, as illustrated in FIG. 45, the port of the signal to be inputted from the completion detection circuit 70 to the SDI register 60 is identified, and a signal path from this port to the input terminal of the latch circuit 104 in the SDI register 60 is identified as the processing target path P, but this is not limitative. Instead of this, for example, a longer signal path including this signal path may be identified as the processing target path P. Specifically, for example, in FIG. 50, a port of a signal to be inputted from the C-elements 62 and 63 of the SDI register 60C to the NOR circuit 64 is identified, and a signal path from this port to the input terminal of the latch circuit 104 through the NOR circuit 64, the completion detection circuit 70C, the AND circuit 101, the OR circuit 102, and the NAND circuit 103 may be identified as the processing target path P.

### Modification Example 2-3

In the embodiment described above, the circuit conversion method illustrated in FIGS. 46A to 46C and 47 is used, but the circuit conversion method is not limited thereto. For example, even in a case where it is not possible to completely suppress glitches, conversion processing may end without affecting the operation.

### Modification Example 2-4

In the embodiment described above, in FIGS. 46A to 46C, for example, as illustrated in steps S204, S206, S211, S213, S218, and S220, it is confirmed whether or not a glitch occurs in an output of a latch circuit in a subsequent stage in the processing target path P, but this is not limitative. Instead of this, for example, it may be confirmed whether or not a glitch occurs in an output of a C-element in a subsequent stage in the processing target path P. This C-element in the subsequent stage in the processing target path P may be, for example, the C-element 62 or 63 in the SDI latch circuit 61.

### Other Modification Examples

In addition, two or more of these modification examples may be combined.

The present technology has been described above with reference to some embodiments and the modification examples, but the present technology is not limited to the embodiments and the like, and may be modified in a variety of ways.

For example, in the embodiments described above, the present technology is applied to the bundled-data asynchronous logic circuit and the 2-wire SDI circuit, but the present technology is not limited thereto. The present technology may be applied to, for example, a 2-wire QDI circuit and an NCL (Null Convention Logic) circuit.

It is to be noted that the effects described herein are merely illustrative and non-limiting, and other effects may be provided.

It is to be noted that the present technology may have the following configurations. According to the present technology having the following configurations, it is possible to suppress glitches.

(1)

A circuit conversion method including:
causing a computer to set a processing target path in an asynchronous logic circuit;
causing the computer to perform first processing for determining whether or not a glitch occurs in each of a plurality of logic cells in the processing target path;
causing the computer to perform second processing including conversion processing for converting one or more logic cells in which a glitch is determined to occur in the first processing into one or more glitch suppression logic cells, the one or more glitch suppression logic cells that are configured to suppress glitches, and perform same logical operation as the one or more logic cells; and
causing the computer to perform, after the second processing, third processing for determining whether or not a glitch occurs in a subsequent-stage circuit in the processing target path.
   (2)

The circuit conversion method according to (1), in which the first processing including determining whether or not a glitch occurs in each of one or a plurality of logic cells to which a plurality of signals is to be inputted out of the plurality of logic cells by comparing a difference between transition timings of the plurality of signals to be inputted with a delay amount of a logic cell as a processing target.

(3)

The circuit conversion method according to (1) or (2), in which the second processing includes performing the conversion processing on all of the one or more logic cells in which a glitch is determined to occur in the first processing.

(4)

The circuit conversion method according to (1) or (2), in which
the second processing includes sequentially selecting one of the one or more logic cells in which a glitch is determined to occur in the first processing, performing the conversion processing on the selected logic cell, and changing one or more logic cells other than the selected logic cell out of the one or more logic cells to an initial state, and
the third processing includes confirming whether or not a glitch occurs in the subsequent-stage circuit every time one of the one or more logic cells is selected in the second processing, and determining that a glitch occurs in a case where a glitch occurs in the subsequent-stage circuit whichever logic cell is selected from the one or more logic cells.
   (5)

The circuit conversion method according to any one of (1) to (4), in which
the third processing includes
determining whether or not a glitch occurs in the subsequent-stage circuit,
converting the subsequent-stage circuit into a glitch suppression circuit in a case where a glitch is determined occur in the subsequent-stage circuit, the glitch suppression circuit that is configured to suppress glitches, and performs same logical operation as the subsequent-stage circuit, and
determining whether or not a glitch occurs in the subsequent-stage circuit converted into the glitch suppression circuit.
   (6)

The circuit conversion method according to any one of (1) to (5), further including:
causing the computer to perform fourth processing for changing the plurality of logic cells in the processing target path to an initial state in a case where a glitch is determined to occur in the third processing;
causing the computer to perform fifth processing for sequentially selecting one of the plurality of logic cells and converting the selected logic cell into a QDI logic cell; and
causing the computer to perform sixth processing for determining whether or not a glitch occurs in the subsequent-stage circuit every time one of the plurality of logic cells is selected in the fifth processing.
   (7)

The circuit conversion method according to (6), further including:
causing the computer to perform seventh processing for converting one or more logic cells subsequent to one or a plurality of logic cells converted into the QDI logic cell in the fifth processing into one or more glitch suppression logic cells in a case where a glitch is determined to occur in the sixth processing, the one or more glitch suppression logic cells that are configured to suppress glitches; and
causing the computer to perform, after the seventh processing, eighth processing for determining whether or not a glitch occurs in the subsequent-stage circuit.
   (8)

The circuit conversion method according to any one of (1) to (7), in which
the asynchronous logic circuit includes a bundled-data logic circuit, and
the subsequent-stage circuit includes a C-element.
   (9)

The circuit conversion method according to any one of (1) to (7), in which
the asynchronous logic circuit includes a 2-wire SDI circuit, and
the subsequent-stage circuit includes a latch circuit or a C-element.
   (10)

A latch circuit including:
a first inverter having an input terminal coupled to an input node, and an output terminal;
a first transistor of P-type having a gate coupled to the output terminal of the first inverter, a source coupled to a power supply node, and a drain led to an first node;
a second transistor of P-type having a gate to which a clock signal is to be inputted, a source coupled to the power supply node, and a drain led to the first node;
a third transistor of N-type having a gate to which the clock signal is to be inputted, a drain led to the first node, and a source;
a fourth transistor of N-type having a gate coupled to the output terminal of the first inverter, a drain coupled to the source of the third transistor, and a source coupled to a ground node;
a fifth transistor of P-type having a gate coupled to the first node, a source coupled to the power supply node, and a drain led to a second node;
a sixth transistor of N-type having a gate to which the clock signal is to be inputted, a drain led to the second node, and a source;
a seventh transistor of N-type having a gate coupled to the input node, a drain coupled to the source of the sixth transistor, and a source;
an eighth transistor of N-type having a gate coupled to the first node, a drain coupled to the source of the seventh transistor, and a source coupled to the ground node;
a NOR circuit having a first input terminal to which a reset signal is to be inputted, a second input terminal coupled to the second node, and an output terminal coupled to a third node;
a ninth transistor of P-type provided in a path coupling the power supply node and the second node, and having a gate coupled to the third node, a source, and a drain;
a tenth transistor of P-type provided in a path coupling the power supply node and the second node, and having a gate to which the clock signal is to be inputted, a source, and a drain;
an eleventh transistor of N-type provided in a path coupling the second node and the ground node, and having a gate coupled to the first node, a drain, and a source;
a twelfth transistor of N-type provided in a path coupling the second node and the ground node, and having a gate coupled to the third node, a drain, and a source;
a second inverter having an input terminal coupled to the third node, and an output terminal; and
a third inverter having an input terminal led to the output terminal of the second inverter, and an output terminal coupled to an output node.
   (11)

The latch circuit according to (10), further including one or more transistors provided in one or more of a first path, a second path, a third path, a fourth path, and a fifth path, the first path coupling the drain of the first transistor and the drain of the second transistor to the first node, the second path coupling the first node and the drain of the third transistor, the third path coupling the drain of the fifth transistor and the second node, the fourth path coupling the second node and the drain of the sixth transistor, and the fifth path coupling the output terminal of the second inverter and the input terminal of the third inverter.

(12)

The latch circuit according to (11), in which the one or more transistors include a thirteenth transistor of P-type provided in the first path, and having a gate coupled to the ground node, a source coupled to the drain of the first transistor and the drain of the second transistor, and a drain coupled to the first node.

(13)

The latch circuit according to (11) or (12), in which the one or more transistors include a fourteenth transistor of N-type provided in the second path, and having a gate coupled to the power supply node, a drain coupled to the first node, and a source coupled to the drain of the third transistor.

(14)

The latch circuit according to any one of (11) to (13), in which the one or more transistors include a fifteenth transistor of P-type provided in the third path, and having a gate coupled to the ground node, a source coupled to the drain of the fifth transistor, and a drain coupled to the second node.

(15)

The latch circuit according to any one of (11) to (14), in which the one or more transistors include a sixteenth transistor of N-type provided in the fourth path, and having a gate coupled to the power supply node, a drain coupled to the second node, and a source coupled to the drain of the sixth transistor.

(16)

The latch circuit according to any one of (1) to (15), in which
the one or more transistors include
a seventeenth transistor of P-type provided in the fifth path, and having a gate coupled to the ground node, and
an eighteenth transistor of N-type provided in the fifth path, and having a gate coupled to the power supply node.
   (17)

A C-element circuit including:
a nineteenth transistor of P-type having a gate coupled to a first input node, a source coupled to a power supply node, and a drain;
a twentieth transistor of P-type having a gate coupled to a second input node, a source coupled to the drain of the nineteenth transistor, and a drain led to a fourth node;
a twenty-first transistor of N-type having a gate coupled to the second input node, a drain coupled to the fourth node, and a source;
a twenty-second transistor of N-type having a gate coupled to the first input node, a drain coupled to the source of the twenty-first transistor, and a source coupled to a ground node;
a twenty-third transistor of P-type having a gate coupled to the second input node, a source coupled to the power supply node, and a drain;
a twenty-fourth transistor of P-type having a gate, a source coupled to the drain of the twenty-third transistor, a drain led to the fourth node;
a twenty-fifth transistor of N-type having a gate, a drain led to the fourth node, and a source;
a twenty-sixth transistor of N-type having a gate coupled to the second input node, a drain coupled to the source of the twenty-fifth transistor, and a source coupled to the ground node;
a NOR circuit having a first input terminal to which a reset signal is to be inputted, a second input terminal coupled to the fourth node, and an output terminal coupled to a fifth node;
a fourth inverter having an input terminal coupled to the fifth node, and an output terminal;
a fifth inverter having an input terminal led to the output terminal of the fourth inverter, and an output terminal coupled to an output node; and
one or more transistors provided in one or more of a sixth path, a seventh path, an eighth path, a ninth path, and a tenth path, the sixth path coupling the drain of the twentieth transistor and the fourth node, the seventh path coupling the fourth node and the drain of the twenty-first transistor, the eighth path coupling the drain of the twenty-fourth transistor and the fourth node, the ninth path coupling the fourth node and the drain of the twenty-fifth transistor, and the tenth path coupling the output terminal of the fourth inverter and the input terminal of the fifth inverter.
   (18)

The C-element circuit according to (17), further including:
a twenty-seventh transistor of P-type having a gate coupled to the first input node, a source coupled to the power supply node, and a drain coupled to the drain of the twenty-third transistor and the source of the twenty-fourth transistor; and
a twenty-eighth transistor of N-type having a gate coupled to the first input node, a drain coupled to the source of the twenty-fifth transistor and the drain of the twenty-sixth transistor, and a source coupled to the ground node, in which
the gate of the twenty-fourth transistor is coupled to the fifth node, and
the gate of the twenty-fifth transistor is coupled to the fifth node.
   (19)

The C-element circuit according to (17), further including:
a twenty-ninth transistor of P-type provided in a path coupling the drain of the nineteenth transistor and the source of the twentieth transistor to the drain of the twenty-third transistor and the source of the twenty-fourth transistor, and having a gate coupled to the first input node; and
a thirtieth transistor of N-type provided in a path coupling the source of the twenty-first transistor and the drain of the twenty-second transistor to the source of the twenty-fifth transistor and the drain of the twenty-sixth transistor, and having a gate coupled to the first input node, in which
the gate of the twenty-fourth transistor is coupled to the fifth node, and
the gate of the twenty-fifth transistor is coupled to the fifth node.
   (20)

The C-element circuit according to (17), further including:
a thirty-first transistor of P-type provided in a path coupling the drain of the nineteenth transistor and the source of the twentieth transistor to the drain of the twenty-third transistor and the source of the twenty-fourth transistor, and having a gate coupled to the fifth node; and
a thirty-second transistor of N-type provided in a path coupling the source of the twenty-first transistor and the drain of the twenty-second transistor to the source of the twenty-fifth transistor and the drain of the twenty-sixth transistor, and having a gate coupled to the fifth node, in which
the gate of the twenty-fourth transistor is coupled to the first input node, and
the gate of the twenty-fifth transistor is coupled to the first input node.
   (21)

The C-element circuit according to any one of (17) to (20), in which the one or more transistors include a thirty-third transistor of P-type provided in the sixth path, and having a gate coupled to the ground node, a source coupled to the drain of the twentieth transistor, and a drain coupled to the fourth node.

(22)

The C-element circuit according to any one of (17) to (21), in which the one or more transistors include a thirty-fourth transistor of N-type provided in the seventh path, and having a gate coupled to the power supply node, a drain coupled to the fourth node, and a source coupled to the drain of the twenty-first transistor.

(23)

The C-element circuit according to any one of (17) to (22), in which the one or more transistors include a thirty-fifth transistor of P-type provided in the eighth path, and having a gate coupled to the ground node, a source coupled to the drain of the twenty-fourth transistor, and a drain coupled to the fourth node.

(24)

The C-element circuit according to any one of (17) to (23), in which the one or more transistors include a thirty-sixth transistor of N-type provided in the ninth path, and having a gate coupled to the power supply node, a drain coupled to the fourth node, and a source coupled to the drain of the twenty-fifth transistor.

(25)

The C-element circuit according to any one of (17) to (24), in which
the one or more transistors include
a thirty-seventh transistor of P-type provided in the tenth path, and having a gate coupled to the ground node, and
a thirty-eighth transistor of N-type provided in the tenth path, and having a gate coupled to the power supply node.

This application claims the priority on the basis of Japanese Patent Application No. 2022-023217 filed on Feb. 17, 2022 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A circuit conversion method comprising:
causing a computer to set a processing target path in an asynchronous logic circuit;
causing the computer to perform first processing for determining whether or not a glitch occurs in each of a plurality of logic cells in the processing target path;
causing the computer to perform second processing including conversion processing for converting one or more logic cells in which a glitch is determined to occur in the first processing into one or more glitch suppression logic cells, the one or more glitch suppression logic cells that are configured to suppress glitches, and perform same logical operation as the one or more logic cells; and
causing the computer to perform, after the second processing, third processing for determining whether or not a glitch occurs in a subsequent-stage circuit in the processing target path.

2. The circuit conversion method according to claim 1, wherein the first processing including determining whether or not a glitch occurs in each of one or a plurality of logic cells to which a plurality of signals is to be inputted out of the plurality of logic cells by comparing a difference between transition timings of the plurality of signals to be inputted with a delay amount of a logic cell as a processing target.

3. The circuit conversion method according to claim 1, wherein the second processing includes performing the conversion processing on all of the one or more logic cells in which a glitch is determined to occur in the first processing.

4. The circuit conversion method according to claim 1, wherein
the second processing includes sequentially selecting one of the one or more logic cells in which a glitch is determined to occur in the first processing, performing the conversion processing on the selected logic cell, and changing one or more logic cells other than the selected logic cell out of the one or more logic cells to an initial state, and
the third processing includes confirming whether or not a glitch occurs in the subsequent-stage circuit every time one of the one or more logic cells is selected in the second processing, and determining that a glitch occurs in a case where a glitch occurs in the subsequent-stage circuit whichever logic cell is selected from the one or more logic cells.

5. The circuit conversion method according to claim 1, wherein
the third processing includes
determining whether or not a glitch occurs in the subsequent-stage circuit,
converting the subsequent-stage circuit into a glitch suppression circuit in a case where a glitch is determined occur in the subsequent-stage circuit, the glitch suppression circuit that is configured to suppress glitches, and performs same logical operation as the subsequent-stage circuit, and
determining whether or not a glitch occurs in the subsequent-stage circuit converted into the glitch suppression circuit.

6. The circuit conversion method according to claim 1, further comprising:
causing the computer to perform fourth processing for changing the plurality of logic cells in the processing target path to an initial state in a case where a glitch is determined to occur in the third processing;
causing the computer to perform fifth processing for sequentially selecting one of the plurality of logic cells and converting the selected logic cell into a QDI logic cell; and
causing the computer to perform sixth processing for determining whether or not a glitch occurs in the subsequent-stage circuit every time one of the plurality of logic cells is selected in the fifth processing.

7. The circuit conversion method according to claim 6, further comprising:
causing the computer to perform seventh processing for converting one or more logic cells subsequent to one or a plurality of logic cells converted into the QDI logic cell in the fifth processing into one or more glitch suppression logic cells in a case where a glitch is determined to occur in the sixth processing, the one or more glitch suppression logic cells that are configured to suppress glitches; and
causing the computer to perform, after the seventh processing, eighth processing for determining whether or not a glitch occurs in the subsequent-stage circuit.

8. The circuit conversion method according to claim 1, wherein
the asynchronous logic circuit comprises a bundled-data logic circuit, and
the subsequent-stage circuit comprises a C-element.

9. The circuit conversion method according to claim 1, wherein
the asynchronous logic circuit comprises a 2-wire SDI circuit, and
the subsequent-stage circuit comprises a latch circuit or a C-element.

10. A latch circuit comprising:
a first inverter having an input terminal coupled to an input node, and an output terminal;
a first transistor of P-type having a gate coupled to the output terminal of the first inverter, a source coupled to a power supply node, and a drain led to an first node;
a second transistor of P-type having a gate to which a clock signal is to be inputted, a source coupled to the power supply node, and a drain led to the first node;
a third transistor of N-type having a gate to which the clock signal is to be inputted, a drain led to the first node, and a source;
a fourth transistor of N-type having a gate coupled to the output terminal of the first inverter, a drain coupled to the source of the third transistor, and a source coupled to a ground node;
a fifth transistor of P-type having a gate coupled to the first node, a source coupled to the power supply node, and a drain led to a second node;
a sixth transistor of N-type having a gate to which the clock signal is to be inputted, a drain led to the second node, and a source;
a seventh transistor of N-type having a gate coupled to the input node, a drain coupled to the source of the sixth transistor, and a source;
an eighth transistor of N-type having a gate coupled to the first node, a drain coupled to the source of the seventh transistor, and a source coupled to the ground node;
a NOR circuit having a first input terminal to which a reset signal is to be inputted, a second input terminal coupled to the second node, and an output terminal coupled to a third node;
a ninth transistor of P-type provided in a path coupling the power supply node and the second node, and having a gate coupled to the third node, a source, and a drain;
a tenth transistor of P-type provided in a path coupling the power supply node and the second node, and having a gate to which the clock signal is to be inputted, a source, and a drain;
an eleventh transistor of N-type provided in a path coupling the second node and the ground node, and having a gate coupled to the first node, a drain, and a source;
a twelfth transistor of N-type provided in a path coupling the second node and the ground node, and having a gate coupled to the third node, a drain, and a source;
a second inverter having an input terminal coupled to the third node, and an output terminal; and
a third inverter having an input terminal led to the output terminal of the second inverter, and an output terminal coupled to an output node.

11. The latch circuit according to claim 10, further comprising one or more transistors provided in one or more of a first path, a second path, a third path, a fourth path, and a fifth path, the first path coupling the drain of the first transistor and the drain of the second transistor to the first node, the second path coupling the first node and the drain of the third transistor, the third path coupling the drain of the fifth transistor and the second node, the fourth path coupling the second node and the drain of the sixth transistor, and the fifth path coupling the output terminal of the second inverter and the input terminal of the third inverter.

12. The latch circuit according to claim 11, wherein the one or more transistors include a thirteenth transistor of P-type provided in the first path, and having a gate coupled to the ground node, a source coupled to the drain of the first transistor and the drain of the second transistor, and a drain coupled to the first node.

13. The latch circuit according to claim 11, wherein the one or more transistors include a fourteenth transistor of N-type provided in the second path, and having a gate coupled to the power supply node, a drain coupled to the first node, and a source coupled to the drain of the third transistor.

14. The latch circuit according to claim 11, wherein the one or more transistors include a fifteenth transistor of P-type provided in the third path, and having a gate coupled to the ground node, a source coupled to the drain of the fifth transistor, and a drain coupled to the second node.

15. The latch circuit according to claim 11, wherein the one or more transistors include a sixteenth transistor of N-type provided in the fourth path, and having a gate coupled to the power supply node, a drain coupled to the second node, and a source coupled to the drain of the sixth transistor.

16. The latch circuit according to claim 11, wherein
the one or more transistors include
a seventeenth transistor of P-type provided in the fifth path, and having a gate coupled to the ground node, and
an eighteenth transistor of N-type provided in the fifth path, and having a gate coupled to the power supply node.

17. A C-element circuit comprising:
a nineteenth transistor of P-type having a gate coupled to a first input node, a source coupled to a power supply node, and a drain;
a twentieth transistor of P-type having a gate coupled to a second input node, a source coupled to the drain of the nineteenth transistor, and a drain led to a fourth node;
a twenty-first transistor of N-type having a gate coupled to the second input node, a drain coupled to the fourth node, and a source;
a twenty-second transistor of N-type having a gate coupled to the first input node, a drain coupled to the source of the twenty-first transistor, and a source coupled to a ground node;
a twenty-third transistor of P-type having a gate coupled to the second input node, a source coupled to the power supply node, and a drain;
a twenty-fourth transistor of P-type having a gate, a source coupled to the drain of the twenty-third transistor, a drain led to the fourth node;
a twenty-fifth transistor of N-type having a gate, a drain led to the fourth node, and a source;
a twenty-sixth transistor of N-type having a gate coupled to the second input node, a drain coupled to the source of the twenty-fifth transistor, and a source coupled to the ground node;
a NOR circuit having a first input terminal to which a reset signal is to be inputted, a second input terminal coupled to the fourth node, and an output terminal coupled to a fifth node;
a fourth inverter having an input terminal coupled to the fifth node, and an output terminal;
a fifth inverter having an input terminal led to the output terminal of the fourth inverter, and an output terminal coupled to an output node; and
one or more transistors provided in one or more of a sixth path, a seventh path, an eighth path, a ninth path, and a tenth path, the sixth path coupling the drain of the twentieth transistor and the fourth node, the seventh path coupling the fourth node and the drain of the twenty-first transistor, the eighth path coupling the drain of the twenty-fourth transistor and the fourth node, the ninth path coupling the fourth node and the drain of the twenty-fifth transistor, and the tenth path coupling the output terminal of the fourth inverter and the input terminal of the fifth inverter.

18. The C-element circuit according to claim 17, further comprising:
a twenty-seventh transistor of P-type having a gate coupled to the first input node, a source coupled to the power supply node, and a drain coupled to the drain of the twenty-third transistor and the source of the twenty-fourth transistor; and
a twenty-eighth transistor of N-type having a gate coupled to the first input node, a drain coupled to the source of the twenty-fifth transistor and the drain of the twenty-sixth transistor, and a source coupled to the ground node, wherein
the gate of the twenty-fourth transistor is coupled to the fifth node, and
the gate of the twenty-fifth transistor is coupled to the fifth node.

19. The C-element circuit according to claim 17, further comprising:
a twenty-ninth transistor of P-type provided in a path coupling the drain of the nineteenth transistor and the source of the twentieth transistor to the drain of the twenty-third transistor and the source of the twenty-fourth transistor, and having a gate coupled to the first input node; and
a thirtieth transistor of N-type provided in a path coupling the source of the twenty-first transistor and the drain of the twenty-second transistor to the source of the twenty-fifth transistor and the drain of the twenty-sixth transistor, and having a gate coupled to the first input node, wherein
the gate of the twenty-fourth transistor is coupled to the fifth node, and
the gate of the twenty-fifth transistor is coupled to the fifth node.

20. The C-element circuit according to claim 17, further comprising:
a thirty-first transistor of P-type provided in a path coupling the drain of the nineteenth transistor and the source of the twentieth transistor to the drain of the twenty-third transistor and the source of the twenty-fourth transistor, and having a gate coupled to the fifth node; and
a thirty-second transistor of N-type provided in a path coupling the source of the twenty-first transistor and the drain of the twenty-second transistor to the source of the twenty-fifth transistor and the drain of the twenty-sixth transistor, and having a gate coupled to the fifth node, wherein
the gate of the twenty-fourth transistor is coupled to the first input node, and
the gate of the twenty-fifth transistor is coupled to the first input node.
